(19) United States
(12) Patent Application Publication
(10) Pub. No.: US 2025/0239532 A1
(43) Pub. Date: Jul. 24, 2025

(54) ELECTRONIC MODULE

(71) Applicant: SHINDENGEN ELECTRIC MANUFACTURING CO., LTD., Tokyo (JP)

(72) Inventors: Yuji MORINAGA, Saitama (JP); Shigeru HISADA, Saitama (JP)

(21) Appl. No.: 18/852,490

(22) PCT Filed: Mar. 30, 2023
(86) PCT No.: PCT/JP2023/013299

§ 371 Date: Sep. 29, 2024

(30) Foreign Application Priority Data
Mar. 31, 2022 (JP) 2022-061176
Mar. 31, 2022 (JP) 2022-061177
Mar. 31, 2022 (JP) 2022-061178
May 19, 2022 (JP) 2022-082466

(51) Int. Cl. H01L 23/538; H01L 23/00; H01L 25/18; H10D 1/68

(52) U.S. Cl. CPC H01L 23/5386; H01L 24/40; H01L 25/18; H01L 2224/40137; H01L 2224/40227; H10D 1/68

(57) ABSTRACT

An electronic module includes: first and second semiconductor elements having first and second electrodes, respectively; a capacitor; a circuit board having first and second wiring patterns on which the first and second semiconductor elements are mounted, respectively, and a third wiring pattern; and electrically connecting members. One portion of the first electrode and the other portion of the second electrode are connected to the first wiring pattern. One portion of the second electrode and one portion of the capacitor are connected to the second wiring pattern. The other portion of the first electrode and the other portion of the capacitor are connected to the third wiring pattern. Surfaces of the first and second electrodes are at different positions. One portion of the first electrode, the other portion of the second electrode, and the first wiring pattern are connected to each other by one of the electrically connecting members.

### RELATED APPLICATIONS

The present application is a National Phase of International Application No. PCT/JP2023/013299 filed Mar. 30, 2023, which claims priority to Japanese Application Nos. 2022-061176, filed Mar. 31, 2022, and 2022-061178, filed Mar. 31, 2022, 2022-061177, filed Mar. 31, 2022 and 2022-082466, filed May 19, 2022.

### TECHNICAL FIELD

The present invention relates to an electronic module.

### BACKGROUND ART

An electronic module on which power semiconductor is mounted is considered to contribute to downsizing of a convertor, an inverter or the like. In view of the above, there have been known proposals described in the following documents.

In patent document 1, there is disclosed a technique where, for reducing a parasitic inductance, input/output electrodes of direct current power are provided using a conductor pattern on an insulation substrate, the input/output electrodes of direct current power are configured such that a plurality of positive electrodes and a plurality of negative electrodes are disposed side by side along an end edge of one end portion, wherein the positive electrode is disposed between two negative electrodes, and the negative electrode is disposed between two positive electrodes.

In patent literature 2, there is disclosed a technique where two pairs of up and lower arms are provided, a positive electrode side direct current terminal and a negative electrode side direct current terminal are connected to the up and lower arms in one pair are arranged in mirror symmetry with respect to a positive electrode side direct current terminal and a negative electrode side direct current terminal connected to the other pair of up and lower arms in two pairs of up and lower arms and hence, inductance can be reduced.

Patent Literature 3 discloses a power conversion device that includes: first parasitic inductance; a first diode; a second parasitic inductance connected in series to a first diode; a second diode connected in parallel to the first diode; a third parasitic inductance connected in series to the second diode; a switching element; a gate circuit; and a load. In such power conversion device, by making an LC resonance frequency of a first circuit loop and an LC resonance frequency of a second circuit loop differ from each other thus suppressing high frequency oscillation. In the simulation described in patent literature 3, the first parasitic inductance is 30 nH, the second parasitic inductance is 10 nH, and the third parasitic inductance is 40 nH.

Patent literature 4 discloses a switching device on which a high side transistor and a low side transistor are mounted, wherein a specific numerical value example in a case where a parasitic inductance of a power source supply line on a high side is set to 40 nH is described.

In patent literature 5, there is a description that it is preferable that a loop inductance on which two switching MOSFETS are mounted is preferably be not more than 60 nano Henry (nH), for example.

### CITATION LIST

### Patent Literature

(Patent Literature 1): JP 2020-053622
(Patent Literature 2): JP 2017-011305
(Patent Literature 3): JP 2015-084636
(Patent Literature 4): JP 2018-093636
(Patent Literature 5): JP 2021-092463

### SUMMARY OF INVENTION

### Technical Problem

Recently, from a viewpoint of carbon neutral, the expectation rises for a compound semiconductor (GaN or the like) that enables a high-speed and a large-current operation. Along with a demand for increasing a switching frequency in switching power source system from a conventional several hundred kHz to several MHz band region and a demand for also increasing a turn-on/off speed to one digit or more, a demand for reducing a switching loss, a surge voltage and noises at the time of performing a circuit system operation.

However, even if an electronic module is constituted using a compound semiconductor capable of performing at a higher speed and a larger current than a conventional discrete part of electronic module, the acquisition of low inductance is difficult and hence, a surge voltage that largely exceeds a rated voltage of a switch element is generated at the time of performing a high speed switching operation and hence, a switching loss and noises cannot be reduced whereby it is difficult for the electronic module to satisfy such demands with respect to operational stability and reliability. That is, although it is obvious for those who are skilled in the art to take a measure of reducing a parasitic inductance as described in the above-mentioned patent literatures, in the case of the prior art as described in patent literature 3 to 5, a value of the inductance values approximately several tens nH. Accordingly, there has been a drawback that it is extremely difficult to satisfy the above-mentioned demands at this level.

In view of the above-mentioned circumstances, it is an object of the present invention to provide an electronic module that can satisfy demands with respect to operational stability and reliability also in a high-speed switching operation.

### Means for Solving the Problems

[1] An electronic module according to the present invention (mode 1) includes: a first semiconductor element having a plurality of first electrodes; a second semiconductor element having a plurality of second electrodes; a capacitor; a circuit board having a first wiring pattern on which the first semiconductor element is mounted, a second wiring pattern on which the second semiconductor element is mounted and a third wiring pattern; and a plurality of electrically connecting members, wherein the first wiring pattern is configured such that one portion of the first electrode and the other portion of the second electrode are connected to the first wiring pattern, the second wiring pattern is configured such that one portion of the second electrode and one portion of the capacitor are connected to the second wiring pattern, and the third wiring pattern is configured such that the other portion of the first electrode and the other portion of the capacitor are connected to the third wiring pattern, a surface of the first electrode and a surface of the second electrode are disposed at positions that differ in height from each other, and one portion of the first electrode, the other portion of the second electrode, and the first wiring pattern are connected to each other by one electrically connecting member out of the plurality of electrically connecting members.
[2] In the electronic module of the present invention (mode 1), it is preferable that, a position adjusting member that adjusts a height position of the surfaces of the second electrodes or the surfaces of the first electrodes be disposed between the second wiring pattern and the second semiconductor element or between the first wiring pattern and the first semiconductor element.
[3] In the electronic module of the present invention (mode 1), it is preferable that a height of the first semiconductor element and a height of the second conductor element differ from each other.
[4] In the electronic module of the present invention (mode 1), it is preferable that the surface of the first electrode is at a position lower than the surface of the second electrode, and the first wiring pattern is at a position lower than the surface of the first electrode.
[5] In the electronic module of the present invention (mode 1), it is preferable that a first semiconductor element mounting region on the first wiring pattern, a second semiconductor element mounting region on the second wiring pattern, and a portion of the third wiring pattern be formed parallel to each other.
[6] In the electronic module of the present invention (mode 1), it is preferable that the plurality of electrically connecting members be used for connection among the first semiconductor element, the second semiconductor element, the first wiring pattern, the second wiring pattern, and the third wiring pattern, and the first semiconductor element, the second semiconductor element, the first wiring pattern, the second wiring pattern, and the third wiring pattern be formed such that connection distances of the plurality of electrically connecting members respectively become the shortest.
[7] In the electronic module of the present invention (mode 1), it is preferable that the second wiring pattern have a first capacitor connecting portion to which one portion of the capacitor is connected, and the third wiring pattern have a second capacitor connecting portion to which the other portion of the capacitor is connected, and planar shapes of the second wiring pattern and the third wiring pattern, and a position at which the first capacitor connecting portion and the second capacitor connecting portion are defined such that a wiring route that starts from one portion of the second electrode and reaches the other portion of the first electrode via the second wiring pattern, the capacitor and the third wiring pattern becomes the shortest.
[8] In the electronic module of the present invention (mode 1), it is preferable that the electronic module further include a power source terminal, an output terminal and a ground terminal disposed on one side thereof, and a control signal-use terminal disposed on the other side thereof, and the capacitor is disposed on one side.
[9] In the electronic module of the present invention (mode 1), it is preferable that the plurality of electrically connecting members be each formed of an electrically connecting member having a line shape or a plate shape.
[10] In the electronic module of the present invention (mode 1), it is preferable that the plurality of electrically connecting members be each formed of an electrically connecting member having a line shape, and assuming a higher surface out of the surface of the first electrode and the surface of the second electrode as a first surface and a lower surface out of the surface of the first electrode and the surface of the second electrode as a second surface, a height position of a peak point of the electrically connecting member in a first loop portion that connects an electrode that corresponds to the first surface and an electrode that corresponds to the second surface to each other be higher than a height position of a peak point of the electrically connecting member in a second loop portion that connects the electrode that corresponds to the second surface and the first wiring pattern.
[11] In the electronic module of the present invention (mode 1), it is preferable that a flat surface position the of the peak point of electrically connecting member at the first loop portion is disposed at a position more offset toward an electrically-connecting-member mounting position side on the first surface than an intermediate position between an electrically-connecting-member mounting position on the first surface and an electrically-connecting-member mounting position on the second surface, and a flat surface position of the peak point of the electrically connecting member at the second loop portion is disposed at a position more offset toward an electrically-connecting-member mounting position side on the second surface than an intermediate position between the electrically-connecting-member mounting position on the second surface and the electrically-connecting-member mounting position on the first wiring pattern.
[12] In the electronic module of the present invention (mode 1), it is preferable that a parasitic inductance at a portion where the first semiconductor element and the second semiconductor element are connected to each other be smaller than a parasitic inductance at a portion where the first semiconductor element and the capacitor are connected to each other, and a parasitic inductance at a portion where the second semiconductor element and the capacitor are connected to each other.
[13] In the electronic module of the present invention (mode 1), it is preferable that the first semiconductor element and the second semiconductor element be each formed of a semiconductor made using silicon, gallium nitride, silicon carbide or gallium oxide as a material.
[14] In the electronic module of the present invention (mode 1), it is preferable that the first semiconductor element and the second semiconductor element be each formed of a transistor where a drain electrode is disposed on one side of a same surface of the transistor and a source electrode is formed on the other side of the same surface of the transistor, or, be formed of a diode where a cathode electrode is disposed on one side of a same surface of the diode and an anode electrode is disposed on the other side of the same surface of the diode.
[15] In the electronic module of the present invention (mode 1), it is preferable that the first semiconductor element and the second semiconductor element be used in a half bridge circuit.
[16] An electronic module according to the present invention (mode 1) includes: a first semiconductor element having a plurality of first electrodes; a second semiconductor element having a plurality of second electrodes; a circuit board having a first wiring pattern on which the first semiconductor element is mounted, a second wiring pattern on which a second semiconductor element is mounted and a third wiring pattern; and a plurality of electrically connecting members, wherein the first wiring pattern is configured such that one portion of the first electrode and the other portion of the second electrode are connected to the first wiring pattern, the second wiring pattern is configured such that one portion of the second electrode is connected to the second wiring pattern, and the third wiring pattern is configured such that the other portion of the first electrode is connected to the third wiring pattern, and a surface of the first electrode and a surface of the second electrode are disposed at positions that differ in height from each other, and one portion of the first electrode, the other portion of the second electrode, and the first wiring pattern are connected to each other by one electrically connecting member out of a plurality of electrically connecting members.

Also in the electronic module described in [16] described above, it is preferable that the electronic module have technical features that are applicable to the electronic module amongst the technical features described in [2] to [15] described above.
[17] An electronic module according to the present invention (mode 2) includes: a first semiconductor element having a plurality of first electrodes; a second semiconductor element having a plurality of second electrodes; a capacitor; a circuit board having a first wiring pattern on which the first semiconductor element is mounted, a second wiring pattern on which a second semiconductor element is mounted and a third wiring pattern; and a plurality of electrically connecting members, wherein the first wiring pattern is configured such that one portion of the first electrode and the other portion of the second electrode are connected to the first wiring pattern, the second wiring pattern is configured such that one portion of the second electrode and one portion of the capacitor are connected to the second wiring pattern, and the third wiring pattern is configured such that the other portion of the first electrode and the other portion of the capacitor are connected to the third wiring pattern, one portion of the first electrode, the other portion of the second electrode and the first wiring pattern are connected to each other by one electrically connecting member out of the plurality of electrically connecting members, and the first semiconductor element and the second semiconductor element are disposed such that an extending direction of one portion of the first electrode and an extending direction of the other portion of the second electrode are directed in the same direction.
[18] In the electronic module of the present invention (mode 2), it is preferable that a first semiconductor element mounting region of the first wiring pattern, a second semiconductor element mounting region of the second wiring pattern, and a portion of the third wiring pattern be disposed parallel to each other.
[19] In the electronic module of the present invention (mode 2), it is preferable that the second wiring pattern have a first capacitor connecting portion to which one portion of the capacitor is connected, and the third wiring pattern have a second capacitor connecting portion to which the other portion of the capacitor is connected, and planar shapes of the second wiring pattern and the third wiring pattern, a forming position of the first capacitor connecting portion and a forming position of the second capacitor connecting portion be defined such that a wiring route that starts from one portion of the second electrode and reaches the other portion of the first electrode via the second wiring pattern, the capacitor and the third wiring pattern becomes the shortest.
[20] In the electronic module of the present invention (mode 2), the electronic module include a power source terminal, an output terminal and a ground terminal on one side thereof and a control signal-use terminal on the other side thereof, and the capacitor be disposed on the one side.
[21] In the electronic module of the present invention (mode 2), it is preferable that the plurality of electrically connecting members be each formed of an electrically connecting member having a line shape or a plate shape.
[22] In the electronic module of the present invention (mode 2), it is preferable that the first semiconductor element and the second semiconductor element be each formed of a semiconductor made using silicon, gallium nitride, silicon carbide or gallium oxide as a material.
[23] In the electronic module of the present invention (mode 2), it is preferable that a parasitic inductance at a portion where the first semiconductor element and the second semiconductor element are connected to each other be smaller than a parasitic inductance at a portion where the first semiconductor element and the capacitor are connected to each other, and a parasitic inductance at a portion where the second semiconductor element and the capacitor are connected to each other.
[24] In the electronic module of the present invention (mode 2), it is preferable that the first semiconductor element and the second semiconductor element be each formed of a transistor where a drain electrode is disposed on one side of a same surface of the transistor and a source electrode is formed on the other side of the same surface of the transistor, or, be formed of a diode where a cathode electrode is disposed on one side of a same surface of the diode and an anode electrode is disposed on the other side of the same surface of the diode.
[25] In the electronic module of the present invention (mode 2), it is preferable that the first semiconductor element and the second semiconductor element be used in a half bridge circuit.
[26] An electronic module according to the present invention (mode 2) includes: a first semiconductor element having a plurality of first electrodes; a second semiconductor element having a plurality of second electrodes; a circuit board having a first wiring pattern on which the first semiconductor element is mounted, a second wiring pattern on which a second semiconductor element is mounted and a third wiring pattern; and a plurality of electrically connecting members, wherein the first wiring pattern is configured such that one portion of the first electrode and the other portion of the second electrode are connected to the first wiring pattern, the second wiring pattern is configured such that one portion of the second electrode is connected to the second wiring pattern, and the third wiring pattern is configured such that the other portion of the first electrode is connected to the third wiring pattern, one portion of the first electrode, the other portion of the second electrode, and the first wiring pattern are connected to each other by one electrically connecting member out of a plurality of electrically connecting members, and the first semiconductor element and the second semiconductor element are disposed such that an extending direction of one portion of the first electrode and an extending direction of the other portion of the second electrode are directed in the same direction.

Also in the electronic module described in [26] described above, it is preferable that the electronic module have technical features that are applicable to the electronic module amongst the technical features described in [18] to [25] described above.
[27] An electronic module according to the present invention (mode 3) includes: a first semiconductor element having a plurality of first electrodes; a second semiconductor element having a plurality of second electrodes; a capacitor; a circuit board having a first wiring pattern on which the first semiconductor element is mounted, a second wiring pattern on which a second semiconductor element is mounted and a third wiring pattern; a first electrically connecting member; a second electrically connecting member; a third electrically connecting member; and a fourth electrically connecting member, wherein the first wiring pattern is configured such that one portion of the first electrode is connected to the first wiring pattern via the first electrically connecting member, and the other portion of the second electrode is connected to the first wiring pattern via the fourth electrically connecting member, the second wiring pattern is configured such that one portion of the second electrode is connected to the second wiring pattern via the second electrically connecting member, and one portion of the capacitor is connected to the second wiring pattern, the third wiring pattern is configured such that the other portion of the first electrode is connected to the third wiring pattern via the third electrically connecting member, and the other portion of the capacitor is connected to the third wiring pattern, and the first semiconductor element and the second semiconductor element are disposed in different directions from each other.
[28] In the electronic module of the present invention (mode 3), it is preferable that the first wiring pattern have a shape based on a letter L, the second wiring pattern and a third wiring pattern have a shape based on a rectangle, and the third wiring pattern is formed so as to surround from three sides together with the first wiring pattern and the second wiring pattern.
[29] In the electronic module of the present invention (mode 3), it is preferable that the first semiconductor element be disposed in a region of the first wiring pattern adjacently to the second wiring pattern and the third wiring pattern, and the other portion of the first electrode be disposed close to and parallel to the third wiring pattern, the second semiconductor element be disposed in a region of the second wiring pattern adjacently to the first wiring pattern, and the other portion of the second electrode be disposed close to and parallel to the first wiring pattern, and the capacitor is disposed in a region close to the second semiconductor element in a state where the capacitor is connected to the second wiring pattern and the third wiring pattern.
[30] In the electronic module of the present invention (mode 3), it is preferable that the second wiring pattern have a capacitor connecting portion to which one portion of the capacitor is connected, and the third wiring pattern have a second capacitor connecting portion to which the other portion of the capacitor is connected, and planar shapes of the second wiring pattern and the third wiring pattern, a mounting position of the second semiconductor element, and forming positions of the first capacitor connecting portion and the second capacitor connecting portion be defined such that a wiring route that starts from one portion of the second electrode and reaches the other portion of the first electrode via the second electrically connecting member, the second wiring pattern, the capacitor, the third wiring pattern and the third electrically connecting member becomes the shortest.
[31] In the electronic module of the present invention (mode 3), it is preferable that the first electrically connecting member, the second electrically connecting member, the third electrically connecting member and the fourth electrically connecting member be each formed of an electrically connecting member having a line shape or having a plate shape.
[32] In the electronic module of the present invention (mode 3), it is preferable that the first semiconductor element and the second semiconductor element be each formed of a semiconductor made using silicon, gallium nitride, silicon carbide or gallium oxide as a material.
[33] In the electronic module of the present invention (mode 3), it is preferable that the first semiconductor element and the second semiconductor element be each formed of a transistor where a drain electrode is disposed on one side of a same surface of the transistor and a source electrode is formed on the other side of the same surface of the transistor, or, be formed of a diode where a cathode electrode is disposed on one side of a same surface of the diode and an anode electrode is disposed on the other side of the same surface of the diode.
[34] In the electronic module of the present invention (mode 3), it is preferable that the first semiconductor element and the second semiconductor element be used in a half bridge circuit.
[35] An electronic module according to the present invention (mode 3) includes: a first semiconductor element having a plurality of first electrodes; a second semiconductor element having a plurality of second electrodes; a circuit board having a first wiring pattern on which the first semiconductor element is mounted, a second wiring pattern on which a second semiconductor element is mounted and a third wiring pattern; a first electrically connecting member; a second electrically connecting member; a third electrically connecting member; and a fourth electrically connecting member, wherein the first wiring pattern is configured such that one portion of the first electrode is connected to the first wiring pattern via the first electrically connecting member, and the other portion of the second electrode is connected to the first wiring pattern via the fourth electrically connecting member, the second wiring pattern is configured such that one portion of the second electrode is connected to the second wiring pattern via the second electrically connecting member, the third wiring pattern is configured such that the other portion of the first electrode is connected to the third wiring pattern via the third electrically connecting member, and the first semiconductor element and the second semiconductor element are disposed in different directions from each other.

Also in the electronic module described in [35] described above, it is preferable that the electronic module have technical features that are applicable to the electronic module amongst the technical features described in [28] to [34] described above.

An electronic module according to the present invention (mode 4) includes: a first cascode switch element that is constituted of: a first switch element having a first drain electrode, a first source electrode and a first gate electrode and formed of a normally-on-type semiconductor element; and a second switch element having a second drain electrode, a second source electrode and a second gate electrode and formed of a normally-off-type semiconductor, wherein the second switch element is stacked on the first switch element in a state where the second drain electrode and the first source electrode are joined to each other by a conductive joining material so that the first gate electrode and the second source electrode are connected to each other; a second cascode switch element that is constituted of: a third switch element having a third drain electrode, a third source electrode and a third gate electrode and formed of a normally-on-type semiconductor element; and a fourth switch element having a fourth drain electrode, a fourth source electrode and a fourth gate electrode and formed of a normally-off-type semiconductor element, wherein the fourth switch element is stacked on the third switch element in a state where the fourth drain electrode and the third source electrode are joined to each other by a conductive joining material so that the third gate electrode and the fourth source electrode are connected to each other; a capacitor; a circuit board having a first wiring pattern on which the first cascode switch element is mounted, a second wiring pattern on which a second cascode switch element is mounted and a third wiring pattern; a first electrically connecting member; a second electrically connecting member; a third electrically connecting member; and a fourth electrically connecting member, wherein the first wiring pattern is configured such that the second source electrode is connected to the first wiring pattern via the first electrically connecting member, and the third drain electrode is connected to the first wiring pattern via the fourth electrically connecting member, the second wiring pattern is configured such that the fourth source electrode is connected to the second wiring pattern via the second electrically connecting member, and one portion of the capacitor is connected to the second wiring pattern, the third wiring pattern is configured such that the first drain electrode is connected to the third wiring pattern via the third electrically connecting member, and the other portion of the capacitor is connected to the third wiring pattern, and the first cascode switch element and the second cascode switch element are disposed in different directions from each other.
[37] In the electronic module of the present invention (mode 4), it is preferable that the first stitch element include the first drain electrode, the first source electrode and the first gate electrode and the first gate electrode on one surface thereof, and the first drain electrode and the first source electrode are disposed parallel to each other, the second stitch element include the second gate electrode and the second source electrode on one surface thereof, and includes the second drain electrode on the other surface thereof,
   the third switch element includes the third drain electrode, the third source electrode and the third gate electrode on one surface thereof, and the third drain electrode and the third source electrode are disposed parallel to each other, and the fourth switch element include the fourth gate electrode and the fourth source electrode on one surface thereof, and include the fourth drain electrode on the other surface thereof.
[38] In the electronic module of the present invention (mode 4), it is preferable that the first gate electrode and the first wiring pattern be connected to each other via a first cascode electrically connecting member, and the third gate electrode and the second wiring pattern be connected to each other via a second cascode electrically connecting member, the first cascode switch element be configured such that the first gate electrode and the second source electrode are connected to each other via the first cascode electrically connecting member, the first wiring pattern and the first electrically connecting member, and the second cascode switch element be configured such that the third gate electrode and the fourth source electrode are connected to each other via the second cascode electrically connecting member, the second wiring pattern and the second electrically connecting member.
[39] In the electronic module of the present invention (mode 4), it is preferable that the first wiring pattern have a shape based on a letter L, the second wiring pattern and the third wiring pattern have a shape based on a rectangle; and the third wiring pattern is disposed in a state where three sides are surrounded by the first wiring pattern and the second wiring pattern.
[40] In the electronic module of the present invention (mode 4), it is preferable that the first cascode switch element be disposed in a region adjacently to the second wiring pattern and the third wiring pattern in the first wiring pattern, and the first drain electrode and the third wiring pattern be disposed parallel to and close to each other, the second cascode switch element be disposed in a region of the second wiring pattern disposed adjacently to the first wiring pattern, and the third drain electrode be disposed adjacently to and parallel to the first wiring pattern, and the capacitor be disposed so as to connect the second wiring pattern and the third wiring pattern in a region disposed close to the second cascode switch element.
[41] In the electronic module of the present invention (mode 4), it is preferable that the second wiring pattern have a first capacitor connecting portion to which one portion of the capacitor is connected, and the third wiring pattern have a second capacitor connecting portion to which the other portion of the capacitor is connected, and planar shapes of the second wiring pattern and the third wiring pattern, a mounting position of the second cascode switch element, and forming positions of the first capacitor connecting portion and the second capacitor connecting portion be defined such that a wiring route that starts from the fourth source electrode and reaches the first drain electrode via the second electrically connecting member, the second wiring pattern, the capacitor, the third wiring pattern and the third electrically connecting member becomes the shortest.
[42] In the electronic module of the present invention (mode 4), it is preferable that the first electrically connecting member, the second electrically connecting member, the third electrically connecting member and the fourth electrically connecting member be each formed of an electrically connecting member having a line shape or having a plate shape.
[43] In the electronic module of the present invention (mode 4), it is preferable that the first switch element and the third switch element be formed using a wideband gap semiconductor material, and be each switch element having higher withstand voltage than the second switch element and the fourth switch element.
[44] In the electronic module of the present invention (mode 4), it is preferable that the wideband gap semiconductor material be gallium nitride, silicon carbide, gallium oxide or diamond.
[45] In the electronic module of the present invention (mode 4), it is preferable that a ground terminal, a power source terminal and an output terminal be arranged on one side of the electric module, and a control signal terminal be arranged on the other side of the electronic module, the capacitor is disposed in the vicinity of the ground terminal and the power source terminal, and the first cascode switch element and the second cascode switch element are disposed close to the capacitor.
[46] In the electronic module of the present invention (mode 4), it is preferable that the first cascode switch element and the second cascode switch element be used in a half bridge circuit.
[47] An electronic module according to the present invention (mode 4) includes: a first cascode switch element that is constituted of: a first switch element having a first drain electrode, a first source electrode and a first gate electrode and formed of a normally-on-type semiconductor element; and a second switch element having a second drain electrode, a second source electrode and a second gate electrode and formed of a normally-off-type semiconductor element, wherein the second switch element is stacked on the first switch element in a state where the second drain electrode and the first source electrode are joined to each other by a conductive joining material so that the first gate electrode and the second source electrode are connected to each other; a second cascode switch element that is constituted of: a third switch element having a third drain electrode, a third source electrode and a third gate electrode and formed of a normally-on-type semiconductor element; and a fourth switch element having a fourth drain electrode, a fourth source electrode and a fourth gate electrode and formed of a normally-off-type semiconductor element, wherein the fourth switch element is stacked on the third switch element in a state where the fourth drain electrode and the third source electrode are joined to each other by a conductive joining material so that the third gate electrode and the fourth source electrode are connected to each other; a circuit board having a first wiring pattern on which the first cascode switch element is mounted, a second wiring pattern on which a second cascode switch element is mounted and a third wiring pattern; a first electrically connecting member; a second electrically connecting member; a third electrically connecting member; and a fourth electrically connecting member, wherein the first wiring pattern is configured such that the second source electrode is connected to the first wiring pattern via the first electrically connecting member, and the third drain electrode is connected to the first wiring pattern via the fourth electrically connecting member, the second wiring pattern is configured such that the fourth source electrode is connected to the second wiring pattern via the second electrically connecting member, the third wiring pattern is configured such that the first drain electrode is connected to the third wiring pattern via the third electrically connecting member, and the first cascode switch element and the second cascode switch element are disposed in different directions from each other.

Also in the electronic module described in described above, it is preferable that the electronic module have technical features that are applicable to the electronic module amongst the technical features described in to described above.

### Advantageous Effect

In the electronic module of the present invention (mode 1), the respective semiconductor modules, the capacitor, the respective electrically connecting members and the respective wiring patterns are disposed as described above. Further, the surface of the first electrode and the surface of the second electrode are at the height positions different from each other, and one portion of the first electrode, the other portion of the second electrode and the first wiring pattern are connected to each other by one electrically connecting member out of the plurality of electrically connecting member. Accordingly, by optimizing a length, a width and a curvature of the wiring in a comprehensive manner, a parasitic inductance can be reduced, and further reduction of inductance in the electronic module including the electrically connecting members can be realized. Further in a case where the circuit system is constituted using the electronic module 100, the reduction of a switching loss, a surge voltage and noises can be realized. Accordingly, performances such as operational stability and reliability of the circuit system that uses the electronic module can be enhanced. With respect to such a case, in a case where the electrically connecting member 51 is an electrically connecting member having a curved portion (for example, a plate-shaped electrically connecting member having a curved portion, an electrically connecting member having a line shape (a wire shape)), the surface of the second electrode and the surface of the first electrode are at different height positions (so-called a terraced shape) and hence, a length of the electrically connecting member 51 can be shortened by decreasing the degree of curving of the curved portion and hence the further reduction of the parasitic inductance can be realized.

According to the electronic module of the present invention (mode 2), the respective semiconductor elements, the capacitor, the respective electrically connecting members, and the respective wiring patterns are disposed as described above and hence, the length of the electrically connecting member (particularly one electrically connecting member) can be shortened. Accordingly, the further reduction of inductance in the electronic module can be realized and hence, the reduction of a switching loss, a surge voltage and noises in a case where the circuit system is constituted using the electronic module can be realized. Accordingly, performances such as operational stability and reliability of the circuit system that uses the electronic module can be enhanced.

According to the electronic module of the present invention (mode 3), the respective semiconductor modules, the capacitor, the respective wiring patterns and the respective electrically connecting members are disposed as described above and hence, lengths of the respective electrically connecting members can be shortened. Further, the further reduction of inductance in the electronic module including portions other than the respective electrically connecting members can be realized. Accordingly, the further reduction of inductance in the electronic module can be realized and hence, the reduction of a switching loss, a surge voltage and noises in a case where the circuit system is constituted using the electronic module can be realized. Accordingly, performances such as operational stability and reliability of the circuit system that uses the electronic module can be enhanced.

The electronic module according to the present invention (mode 4) is an electronic module that includes: the first cascode switch element that is constituted of the first switch element formed of a normally-on type semiconductor element, and the second switch element formed of the normally-off type semiconductor element; the second cascode switch element that is constituted of the third switch element formed of normally-on type semiconductor element and the fourth switch element formed of the normally-off type semiconductor element. With such a configuration, according to the electronic module of the present invention (mode 4), by connecting the switch element (the first switch element, the third switch element) formed of the normally-on type semiconductor element (for example, the wideband gap semiconductor such as GaN) that possesses a high withstand voltage and can be driven with a high frequency together with the switch element (the second switch element, the fourth switch element) constituted of a conventional normally-off type semiconductor element (a semiconductor element such as silicon, for example) by cascode connection, the normally-off type switch element can be obtained whereby the switching frequency can be increased to a high speed at the order of several MHz, and a turn-on/off speed can be made high speed by one digit or more, and high frequency driving of the power source system can be realized.

Further, according to the electronic module of the present invention (mode 4), the respective semiconductor elements, the capacitor, the respective wiring patterns and the respective electrically connecting members are disposed as described above and hence, the lengths of the respective electrically connecting members can be shortened. Further, the further reduction of inductance in the electronic module including portions other than the respective electrically connecting members can be realized. Accordingly, the further reduction of inductance of the electronic module can be realized and hence, the reduction of a switching loss, a surge voltage and noises in a case where the circuit system is constituted using the electronic modules can be realized. As a result, as described above, by using the wideband gap semiconductor element (for example, GaN) as the first switch element and the third switch element, switching frequency is increased to a high speed at the order of several MHz, and the turn-off speed can be increased by one digit or more compared to a prior art and hence, even when the power source system is driven at a high frequency, the performances such as operational stability and reliability of the circuit system can be enhanced.

As a result, the electronic module (mode 4) of the present invention becomes an electronic module that satisfies demands with respect to operational stability and reliability even in a case where the electronic module of the present invention is used as an electronic module for high frequency driving that uses a wideband gap semiconductor element.

In this specification, “connected” means “electrically connected”.

### BRIEF DESCRIPTION OF DRAWINGS

FIG. 1A and FIG. 1B are conceptual views of an electronic module 100 according to the present invention (mode 1).

FIG. 2 is a cross-sectional view of the electronic module 110 according to the embodiment 1.

FIG. 3 is a view illustrating an example of a first electrode and a second electrode disposed on a surface of a first semiconductor element 10 and a second semiconductor element 20.

FIG. 4 is a view illustrating an equivalent circuit 120 of the electronic module 100 according to the present invention (mode 1), the electronic module 110 according to the embodiment 1, and the electronic module 130 according to an embodiment 2. The equivalent circuit 120 is also an equivalent circuit of an electronic module A100 according to the present invention (mode 2), an electronic module A130 according to an embodiment 3, and an electronic module A132 according to an embodiment 4. The equivalent circuit 120 is also an electronic circuit of an electronic module B100 according to the present invention (mode 3), an electronic module B130 according to an embodiment 5, an electronic module B132 according to an embodiment 6 and an electronic module B134 according to an embodiment 7. The equivalent circuit 120 is also an equivalent circuit according to an electronic module C100 of the present invention (mode 4), an electronic module C130 according to an embodiment 8, and an electronic module C132 according to an embodiment 9, and an electronic module C134 according to an embodiment 10, FIG. 4 being also a view illustrating an equivalent circuit 120 of an electronic module 130 according to the embodiment 2.

FIG. 5 is a view illustrating the electronic module 130 according to the embodiment 2.

FIG. 6 is a perspective view illustrating a stepped portion D in the embodiment 2.

FIG. 7A to FIG. 7C are views provided for illustrating a double pulse test.

FIG. 8 is a view illustrating a switching waveform of a drain-source voltage VDS and a switching waveform of a drain current ID of the second semiconductor element 20 in the electronic module 130 according to the embodiment 2 obtained by simulation. FIG. 9 is a view illustrating an equivalent circuit 150 of a conventional electronic module.

FIG. 10 is a view illustrating a switching waveform of a drain-source voltage VDS and a switching waveform of a drain current ID of the second semiconductor element 20 in the equivalent circuit 150 of the conventional electronic module obtained by simulation.

FIG. 11 is a conceptual view of the electronic module A100 of the present invention (mode 2).

FIG. 12 is a plan view illustrating the electronic module A130 according to the embodiment 3.

FIG. 13 is a perspective view of the electronic module A130 according to the embodiment 3 illustrating a main part in an enlarged manner.

FIG. 14 is a perspective view of the electronic module A132 according to the embodiment 4 illustrating a main part in an enlarged manner.

FIG. 15A to FIG. 15C are views for describing a double pulse test.

FIG. 16 is a view illustrating a switching of a drain-source voltage VDS and a waveform switching waveform of a drain current ID of the second semiconductor element 20 in the electronic module A130 according to the embodiment 3 obtained by simulation.

FIG. 17 is a view illustrating a switching waveform of a drain-source voltage VDS and a switching waveform of a drain current ID of the second semiconductor element 20 in the electronic module A132 according to the embodiment 4 obtained by simulation.

FIG. 18 is a conceptual view of the electronic module B100 according to the present invention (mode 3).

FIG. 19 is a view illustrating an example of a first electrode and a second electrode disposed on a surface of a first semiconductor element 10 and a surface of a second semiconductor element 20.

FIG. 20 is a plan view illustrating the electronic module B130 according to the embodiment 5.

FIG. 21 is a perspective view of the electronic module B132 according to the embodiment 6 with a main part illustrated in an enlarged manner.

FIG. 22 is a perspective view of the electronic module B134 according to the embodiment 7 with a main part illustrated in an enlarged manner.

FIG. 23A to FIG. 23C are views provided for describing a double pulse test.

FIG. 24 is a view illustrating a switching waveform of a drain-source voltage VDS and a switching waveform of a drain current ID of the second semiconductor element 20 in the electronic module B130 according to the embodiment 5 obtained by simulation.

FIG. 25 is a view illustrating a switching waveform of a drain-source voltage VDS and a switching waveform of a drain current ID of the second semiconductor element 20 in the electronic module B132 according to the embodiment 6 obtained by simulation.

FIG. 26 is a view illustrating a switching waveform of a drain-source voltage VDS and a switching waveform of a drain current ID of the second semiconductor element 20 in the electronic module B134 according to the embodiment 7 obtained by simulation.

FIG. 27 is a conceptual view of an electronic module 500 according to the present invention (mode 4).

FIG. 28A to FIG. 28C are views illustrating an electrode structure of a first switch element 310 and an electrode structure of a second switch element 320.

FIG. 29A to FIG. 29C are views illustrating an electrode structure of a third switch element 410 and an electrode structure of a fourth switch element 420.

FIG. 30A and FIG. 30B are views provided for describing a first cascode switch element 300.

FIG. 31A and FIG. 31B are views provided for describing a second cascode switch element 400.

FIG. 32 is a view illustrating an equivalent circuit 510 of the electronic module 500.

FIG. 33 is a plan view illustrating the electronic module 530 according to the embodiment 8.

FIG. 34 is a perspective view of the electronic module 532 according to the embodiment 9 illustrating a main part in an enlarged manner.

FIG. 35 is a perspective view of the electronic module 534 according to the embodiment 10 illustrating a main part in an enlarged manner.

FIG. 36A to FIG. 36C are views provided for describing a double pulse test.

FIG. 37 is a view illustrating a switching waveform of a drain-source voltage VDS and a switching waveform of a drain current ID of the second cascode switch element 400 that functions as a transistor in the electronic module 530 according to the embodiment 1.

### MODE FOR CARRYING OUT THE INVENTION

Hereinafter, an electronic module for carrying out the present invention is described with reference to drawings. The respective drawings are schematic views and it is not always a case that these drawings strictly reflect actual sizes. Further, the respective embodiments described hereinafter are not intended to limit the inventions called for in Claims. Further, it is not always the case that all of various constitutional elements and the combination of these elements described in the respective embodiments are indispensable as means for solving the problems according to the present invention. Further, in the respective embodiments, with respect to the basic configurations and the constitutional elements (including constitutional elements that do not have completely the same shapes or the like) that have substantially the same configuration, technical features, functions or the like, the same symbols may be used throughout all embodiments, and the repeated description of these configurations and constitutional elements is omitted.

### The Present Invention (Mode 1)

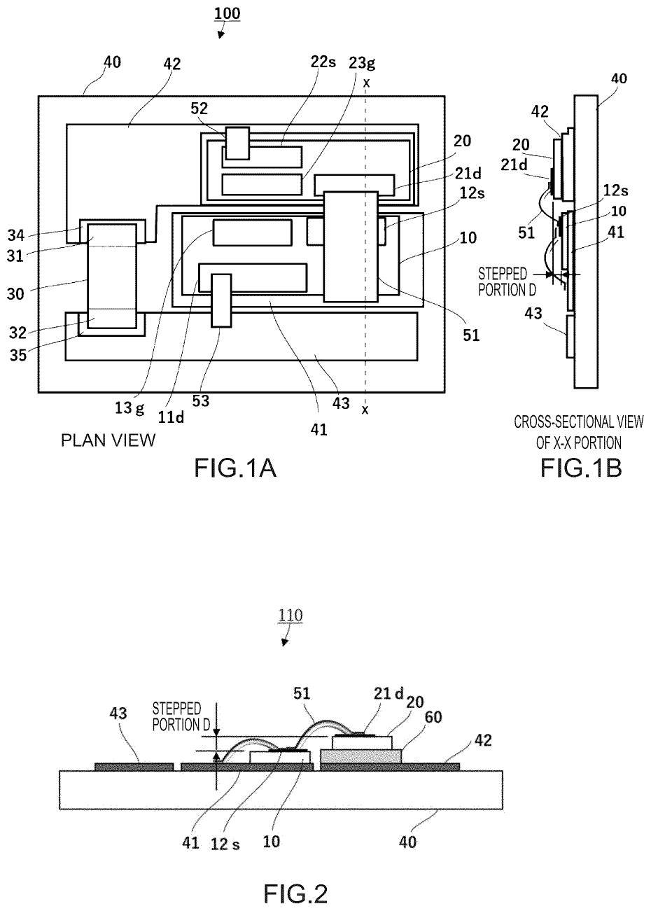

FIG. 1A and FIG. 1B are conceptual views of an electronic module 100 according to the present invention (mode 1). FIG. 1A is a plan view, and FIG. 1B is a cross-sectional view of portion taken along X-X in FIG. 1A.

The electronic module 100 according to the present invention (mode 1) is a resin-sealed-type electronic module. As illustrated in FIG. 1A, the electronic module 100 includes: a first semiconductor element 10 having a plurality of first electrodes 11d, 12s, 13g; a second semiconductor element 20 having a plurality of second electrodes 21d, 22s, 23g; a capacitor 30; a circuit board 40 having a first wiring pattern 41 on which the first semiconductor element 10 is mounted, a second wiring pattern 42 on which a second semiconductor element 20 is mounted, and a third wiring pattern 43; and a plurality of electrically connecting members 51, 52, 53.

In the electronic module 100 according to the present invention (mode 1), the first wiring pattern 41 is configured such that one portion 12s of the first electrode and the other portion of the second electrode 21d are connected to the first wiring pattern 41, the second wiring pattern 42 is configured such that one portion 22s of the second electrode and one portion 31 of the capacitor 30 are connected to the second wiring pattern 42, and the third wiring pattern 43 is configured such that the other portion 11d of the first electrode and the other portion 32 of the capacitor 30 are connected to the third wiring pattern 43.

In the electronic module 100 according to the present invention (mode 1), as illustrated in FIG. 1B, a surface of the first electrode and a surface of the second electrode are disposed at positions that differ from each other. One portion 12s of the first electrode, the other portion 21d of the second electrode, and the first wiring pattern 41 are connected to each other by one electrically connecting member (electrically connecting member 51) out of a plurality of electrically connecting members.

In the electronic module 100 according to the present invention (mode 1), as can be clearly understood from FIG. 1B, the second electrode 21d, the first electrode 12s and the first wiring pattern 41 that differ in height from each other are sequentially connected by the electrically connecting member 51 sequentially. Surfaces of the second electrodes 21d, 22s, 23g of the second semiconductor element 20 are set higher than surfaces of the first electrodes 11d, 12s, 13g of the first semiconductor element 10. It is sufficient that either one of the surfaces of the first electrodes 11d, 12s, 13g or the surfaces of the second electrodes 21d, 22s, 23g are higher than the other surfaces.

With such a configuration, a parasitic inductance can be reduced by optimizing lengths, widths and curvatures of the wires in a comprehensive manner and hence, the further reduction of inductance in the electronic module 100 including the electrically connecting member 51 can be realized. Further, in a case where a circuit system is constituted using the electronic module 100, it is possible to reduce a switching loss, a surge voltage and noises. Further, in such circumstance, in a case where the electrically connecting member 51 is an electrically connecting member having a curved portion (for example, a plate-shaped electrically connecting member having a curved shape, an electrically connecting member having a line shape (a wire shape)), since the surface of the second electrode and the surface of the first electrode are different in high position (in a so-called terraced shape), a length of the electrically connecting member 51 can be shortened by reducing the degree of curving of the curved portion whereby the parasitic inductance can be further reduced.

Particularly, in the electronic module 100, it is possible to reduce the inductance at a connecting portion between the first semiconductor element 10 and the second semiconductor element 20. The connecting portion between the first semiconductor element 10 and the second semiconductor element 20 is, in a circuit system having the bridge structure such as a half bridge circuit, for example, an extremely important potential portion from a viewpoint of operational stability. Accordingly, the reduction of inductance at the above-mentioned connecting portions (the first electrode 12s, the second electrode 21d, the electrically connecting member 51, the first wiring pattern 41) exhibits an outstanding effect in the reduction of a switching loss, a surge voltage and noises in a circuit system having a bridge structure such as a half bridge circuit, for example.

The first semiconductor element 10 corresponds to the first semiconductor element according to the present invention (mode 1). The second semiconductor element 20 corresponds to the second semiconductor element according to the present invention (mode 1). The capacitor 30 corresponds to the capacitor according to the present invention (mode 1). The circuit board 40 corresponds to the circuit board according to the present invention (mode 1). The electrically connecting member 51 corresponds to the electrically connecting member according to the present invention (mode 1). The plurality of first electrodes 11d, 12s, 13g correspond to the plurality of first electrodes according to the present invention (mode 1). The plurality of second electrodes 21d, 22s, 23g correspond to the plurality of second electrodes according to the present invention (mode 1).

The first wiring pattern 41 corresponds to the first wiring pattern according to the present invention (mode 1). One portion 12s of the first electrode corresponds to one portion of the first electrode according to the present invention (mode 1). The other portion 21d of the second electrode corresponds to the other portion of the second electrode according to the present invention (mode 1). The second wiring pattern 42 corresponds to the second wiring pattern according to the present invention (mode 1). One portion 22s of the second electrode corresponds to one portion of the second electrode according to the present invention (mode 1). One portion 31 of the capacitor corresponds to one portion of the capacitor according to the present invention (mode 1). The third wiring pattern 43 corresponds to the third wiring pattern according to the present invention (mode 1). The other portion 11d of the first electrode corresponds to the other portion of the first electrode according to the present invention (mode 1). The other portion 32 of the capacitor corresponds to the other portion of the capacitor according to the present invention (mode 1).

### Embodiment 1

FIG. 2 is cross-sectional view of the electronic module 110 according to the embodiment 1. FIG. 2 is a cross-sectional view taken along a line X-X in FIG. 1A and FIG. 1B.

In the electronic module 110, between the second wiring pattern 42 and the second semiconductor element 20 (see FIG. 2) or between the first wiring pattern 41 and the first semiconductor element 10, a position adjusting member 60 that adjusts the height position of the surfaces of the second electrodes 21d, 22s, 23g or the surfaces of the first electrodes 11d, 12s, 13g is disposed. By adjusting the height position of the surfaces of the second electrodes 21d, 22s, 23g or the surfaces of the first electrodes 11d, 12s, 13g by the position adjusting member 60, an adjusting operation of a length, a width and a curvature of the wire can be performed easily and hence, a parasitic inductance between the second electrode 21d and the first electrode 12s can be reduced.

In FIG. 2, the first electrode 12s and the second electrode 21d may be connected to each other using a conductor having a line shape, for example, as the electrically connecting member 51 (wire bonding). However, the electrically connecting member 51 is not limited to a conductive member having a line shape, and may be formed of a conductive member having a plate shape. The electrically connecting member 51 may be formed using a suitable material such as aluminum, copper or gold, for example.

The parasitic inductance is an inductive component that parasites a wire, and affects a length, a width, a curvature and the like of the wire. Higher a circuit operation frequency, the more it is necessary to reduce the parasitic inductance. With the use of the position adjusting member 60 illustrated in FIG. 2, the electronic module 110 can acquire an effect of reducing the above-mentioned parasitic inductance.

In the electronic module 110 according to the embodiment 1, the position adjusting member 60 is disposed between the second wiring pattern 42 and the second semiconductor element 20. By adjusting the surface height position of the second electrode 21d using the position adjusting member 60, a parasitic inductance between the first electrode 12s and the second electrode 21d can be reduced.

In the electronic module 110 according to the embodiment 1, as described above, the electronic module 110 is set or configured such that a parasitic inductance of the portion where the first semiconductor element 10, the second semiconductor element 20 and the first wiring pattern 41 are connected becomes small. Accordingly, the further reduction of an inductance in the electronic module 100 including the electrically connecting member 51 can be realized.

The connecting portion between the first semiconductor element 10 and the second semiconductor element 20 is, for example, in a circuit system having a bridge structure such as a half bridge structure, an extremely important potential portion from a viewpoint of operation stability. The reduction of an inductance of the above-mentioned connecting points (the first electrode 12s, the second electrode 21d, the electrically connecting member 51, the first wiring pattern 41) acquires an outstanding effect in reducing a switching loss, a surge voltage and noises.

Particularly, in a case where the electrically connecting member 51 (for example, a wire) that is easily bendable as illustrated in the configurational example in FIG. 2 is used, in general, a parasitic inductance is likely to become high compared to a plate-shaped electrically connecting member. However, by adopting the configuration illustrated in FIG. 2, a length, a width and a curvature of the electrically connecting member 51 is optimized in a comprehensive manner, as a result, a parasitic inductance between the first electrode 12s and the second electrode 21d can be reduced.

In the electronic module 110, a height position of a peak point of the electrically connecting member 51 at a first loop portion that connects the other portion 21d of the second electrode and one portion of the first electrode is higher than a height position of a peak point of the electrically connecting member 51 at a second loop portion that connects one portion 12s of the first electrode and the first wiring pattern 41. Further, a flat surface position of the peak point of the electrically connecting member 51 at the above-mentioned first loop portion is disposed at a position more offset toward an electrically-connecting-member-51 mounting position side at the other portion 21d of the second electrode than an intermediate position between the electrically-connecting-member-51 mounting position at the other end portion 21d of the second electrode and the electrically-connecting-member-51 mounting position at one end portion 12s of the first electrode. On the other hand, a flat surface position of the peak point of the electrically connecting member 51 at the second loop portion is disposed at a position more offset toward an electrically-connecting-member-51 mounting position side at one portion 12s of the first electrode than an intermediate position between the electrically-connecting-member-51 mounting position at one portion 12s of the first electrode and the electrically-connecting-member-51 mounting position at the wiring pattern 41. With such a configuration, the length of the electrically connecting member 51 can be shortened and hence, a parasitic inductance between the second electrode 21d and the first electrode 12s and a parasitic inductance between the first electrode 12s and the wiring pattern 41 can be reduced.

In FIG. 2, the case is exemplified where the position adjusting member 60 adjusts the surface of the second electrode 21d in the vertical direction with respect to the surface of the first electrode 12s. However, the position adjusting member 60 may be configured to adjust the surface of the second electrode 21d in the horizontal direction. By performing the adjustment not only in the vertical direction but also in the horizontal direction, depending on the length, the wide and the curvature of the wire, a parasitic inductance between the first electrode 12s and the second electrode 21d can be further reduced.

Further, in FIG. 2, the position adjusting member 60 is disposed between the second wiring pattern 42 and the second semiconductor element 20, and adjusts the surface height position of the second electrode 21d. However, the position adjusting member 60 may be disposed between the first wiring pattern 41 and the first semiconductor element 10, and adjusts the surface height position of the first electrode 12s. The position adjusting member 60 corresponds to the position adjusting member of the present invention (mode 1).

The first semiconductor element 10 and the second semiconductor element 20 may be formed of a semiconductor using silicon, gallium nitride, silicon carbide or gallium oxide as a material. The first semiconductor element 10 and the second semiconductor element 20 may be semiconductors formed using the same material or different materials respectively.

With such a configuration, the electronic module according to the embodiment 1 is constituted of a semiconductor element having a function selectively suitable for a circuit application (a half bridge circuit, a totem-pole-type power factor improving circuit or the like). Accordingly, in a case where the circuit system is constituted using such an electronic module, a switching loss, a surge voltage and noises can be reduced and hence, operational stability and the reliability of the circuit system that uses the electronic module can be enhanced.

Particularly, in a switching power source system that uses a compound semiconductor capable of being operated at a high speed and with a large current, for example, gallium nitride, a silicon carbide or gallium oxide, the electronic module 110 according to the embodiment 1 can acquire a particularly outstanding effect with respect to a demand for increasing a switching frequency into a high-speed band of several MHz, a demand for also increasing a turn on/off speed by 1 digit or more, and a demand for reducing a switching loss, a surge voltage and noises.

Next, the electrodes disposed on the surface of the first semiconductor element 10 and the surface of the second semiconductor element 20 are described.

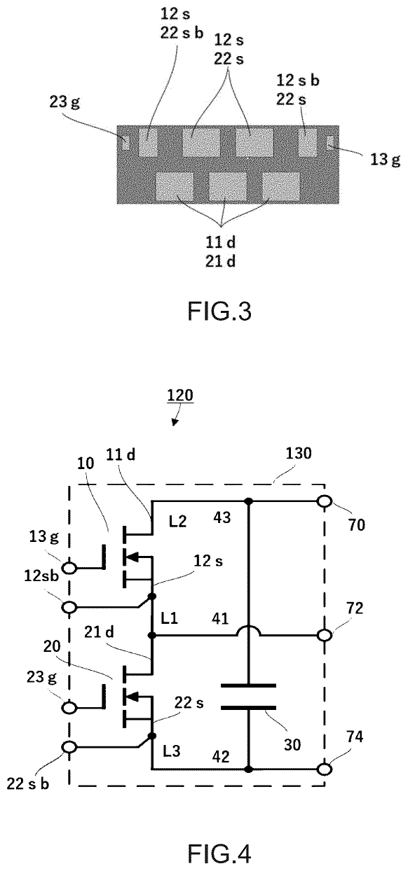

FIG. 3 illustrates an example of the first electrodes and the second electrodes disposed on the surface of the first semiconductor element 10 and the surface of the second semiconductor element 20.

The first semiconductor element 10 and the second semiconductor element 20 are formed of a transistor or a diode. In a case where the first semiconductor element 10 and the second semiconductor element 20 are formed of a transistor, it is preferable that the drain electrodes 11d, 21d be disposed on one side of the same surfaces of the first semiconductor element 10 or the second semiconductor element 20, and the source electrodes 12s, 22s be disposed on the other side of the same surfaces of the first semiconductor element 10 or the second semiconductor element 20. FIG. 3 illustrates the example where the first semiconductor element 10 and the second semiconductor element 20 are formed of a transistor, and the drain electrodes 11d, 21d and the source electrodes 12s, 22s are respectively formed of a plurality of electrodes. For example, in the example illustrated in FIG. 3, the number of drain electrodes 11d, 21d is three and the number of the source electrodes 12s, 22s is three. The gate electrodes 13g, 23g are respectively disposed on a right side or a left side of the source electrodes 12s, 22s, and the detection-use source electrodes 12sb, 22sb are respectively disposed between the gate electrodes 13g, 23g and the source electrodes 12s, 22s.

In a case where the first semiconductor element 10 and the second semiconductor element 20 are formed of a diode respectively, it is preferable that the cathode electrode be disposed on one side of the same surfaces of the first semiconductor element 10 or the second semiconductor element 20, and the anode electrode be disposed on the other side of the same surfaces of the first semiconductor element 10 or the second semiconductor element 20.

With the provision of such lateral configuration, the electronic module is constituted of the semiconductor element having a function selectively suitable for the circuit application (a half bridge circuit, a totem-pole-type power factor improvement circuit, or the like) and hence, a switching loss, a surge voltage and noises that are generated in a case where the circuit system is constituted by using the electronic module can be reduced whereby performances such as the operational stability, the reliability and the like of the circuit system that uses the electronic module can be enhanced.

In the case where the first semiconductor element 10 and the second semiconductor element 20 are formed of a transistor, as illustrated in FIG. 3, the gate electrodes 13g, 23g and the detection-use source electrodes 12sb, 22sb are formed in the vicinity of the source electrodes 12s, 22s. Accordingly, a parasitic inductance of a gate-source wiring loop can be reduced and hence, performances such as the operational stability, the reliability and the like of the circuit system can be enhanced.

As a specific example of the lateral configuration, a case where GaN transistors are formed on a silicon substrate, a case where GaN transistors are formed on a sapphire substrate and the like are named.

It is preferable that the first semiconductor element 10 and the second semiconductor element 20 be used in the half bridge circuit. With such a configuration, an inductance of the half bridge circuit can be reduced and hence, it is possible to provide the electronic module 110 having the stable half bridge circuit. Next, the electronic module that uses the half bridge circuit is described.

### Embodiment 2

FIG. 4 is a view illustrating an equivalent circuit 120 of the electronic module 100, 110 and an electronic module 130 illustrated in the embodiment 2. A first semiconductor element 10 and a second semiconductor element 20 constitute a half bridge circuit. A drain electrode 11d of the first semiconductor element 10 is connected to a power source terminal 70 via a third wiring pattern 43. A source electrode 12s of the first semiconductor element 10 is connected to a drain electrode 21d of the second semiconductor element 20 and a first wiring pattern 41 by an electrically connecting member 51, and is connected to an output terminal 72 via a first wiring pattern 41.

A source electrode 22s of the second semiconductor element 20 is connected to a ground terminal 74 via a second wiring pattern 42. A capacitor 30 is connected to the power source terminal 70 and the ground terminal 74 via the third wiring pattern 43 and a second wiring pattern 42. That is, the circuit is provided where the capacitor 30 is connected in parallel to the first semiconductor element 10 and the second semiconductor element 20 that are connected in series. A control signal is inputted to a gate electrode 13g and a gate electrode 23g so that a switching operation of the first semiconductor element 10 and the second semiconductor element 20 that constitute the half bridge is performed. The equivalent circuit 120 also includes detection-use source electrodes 12sb, 12sb.

In the equivalent circuit 120 illustrated in FIG. 4, a portion where the source electrode 12s of the first semiconductor element 10 and the drain electrode 21d of the second semiconductor element 20 are connected is a portion where a parasitic inductance L1 is set, a portion that connects a drain electrode 11d of the first semiconductor element 10 and a capacitor 30 is a portion where a parasitic inductance L2 is set, a portion that connects the source electrode 22s of the second semiconductor element 20 and the capacitor 30 is a portion where a parasitic inductance L3 is set.

To describe the present invention (mode 1) with reference to the equivalent circuit 120 illustrated in FIG. 4, the parasitic inductance L1 at the portion that connects the first semiconductor element 10 and the second semiconductor element 20 is set smaller than the parasitic inductance L2 at the portion that connects the first semiconductor element 10 and the capacitor 30 and the parasitic inductance L3 at the portion that connects the second semiconductor element 20 and the capacitor 30. With such a configuration, the inductance in the electronic module 100 that includes the electrically connecting member 51 can be further reduced.

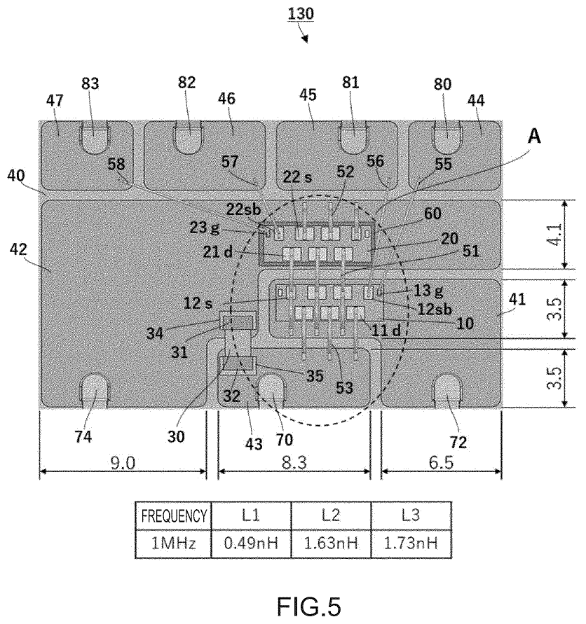

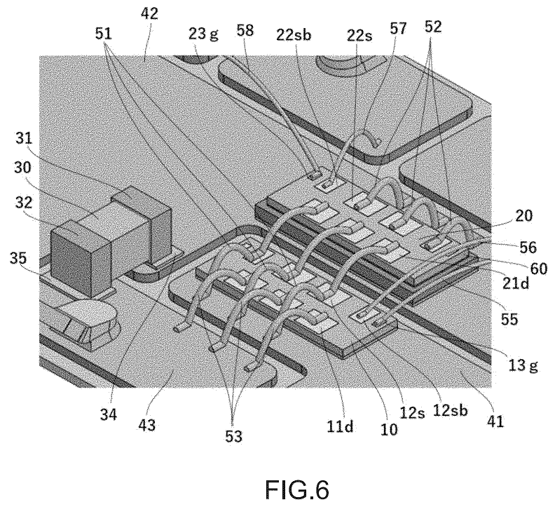

FIG. 5 is a view illustrating the electronic module 130 according to an embodiment 2. FIG. 6 is a perspective view for describing a stepped portion D in the embodiment 2. FIG. 6 illustrates a region A surrounded by a broken line in FIG. 5 in an enlarged manner.

As illustrated in FIG. 5, the electronic module 130 according to the embodiment 2 includes: a first semiconductor element 10 having a plurality of first electrodes 11d, 12s, 13g; a second semiconductor element 20 having a plurality of second electrodes 21d, 22s, 23g; a capacitor 30; a circuit board 40 that has a first wiring pattern 41 on which the first semiconductor element 10 is mounted, a second wiring pattern 42 on which the second semiconductor element 20 is mounted and a third wiring pattern 43; and a plurality of electrically connecting members 51, 52, 53. As the circuit board 40, for example, a DCB circuit board formed by directly joining a copper circuit board on a ceramic board, for example, is used.

In the electronic module 130 according to the embodiment 2, one portion 12s of the first electrode and the other portion of the second electrode 21d are connected to the first wiring pattern 41 and one portion 22s of the second electrode and one portion 31 of the capacitor 30 are connected to the second wiring pattern 42, and the other portion 11d of the first electrode and the other portion 32 of the capacitor 30 are connected to the third wiring pattern 43.

In the electronic module 130 according to the embodiment 2, as illustrated in FIG. 6, surfaces of first electrodes 11d, 12s, 12sb, 13g and surfaces of the second electrodes 21d, 22s, 22sb, 23g are disposed at height positions that differ from each other. One portion 12s of the first electrode, the other portion 21d of the second electrode, and the first wiring pattern 41 are connected to each other by one electrically connecting member (electrically 51) out of a plurality of connecting member electrically connecting members. The electrically connecting member 52 connects one portion 22s of the second electrode and the second wiring pattern 42, and an electrically connecting member 53 connects the other portion 11d of the first electrode and the third wiring pattern 43.

The surfaces of the first electrodes 11d, 12s, 12sb, 13g are set at low positions compared to the surfaces of the second electrodes 21d, 22s, 22sb, 23g. A surface of the first wiring pattern 41 is lower than the surfaces of the first electrodes 11d, 12s, 12sb, 13g. With such a configuration, a parasitic inductance can be reduced by optimizing lengths, widths and curvatures of the wires in a comprehensive manner and hence, the further reduction of inductance in the electronic module including the electrically connecting member 51 can be realized. Further, in a case where a circuit system is constituted using the electronic module 130, it is possible to reduce a switching loss, a surge voltage and noises. Accordingly, performances such as the operational stability, the reliability and the like of the circuit system that uses the electronic module can be enhanced.

The electronically connecting members 51, 52, 53 are used for the connection of the first semiconductor element 10, the second semiconductor element 20, the first wiring pattern 41, the second wiring pattern 42, and the third wiring pattern 43. The semiconductor element 10, the semiconductor element 20, the first wiring pattern 41, the second wiring pattern 42, and the third wiring pattern 43 are constituted such that connection distances of the electronically connecting members 51, 52, 53 become the shortest respectively. With such a configuration, the further reduction of inductance in the electronic module 130 can be realized.

In the electronic module 130 according to the embodiment 2, a portion where the second electrode 21d, the first electrode 12s and the first wiring pattern 41 are connected to each other, a portion where the drain electrode 11d of the first semiconductor element 10 and the third wiring pattern 43 are connected to each other, the portion where the source electrode 22s of the second semiconductor element 20 and the second wiring pattern 42 are connected to each other become the shortest distances respectively. With such a configuration, the further reduction of inductance in the electronic module 130 can be realized.

The electronically connecting member 51 corresponds to an electronically connecting member “that is used for connection of the second electrode 21d, the first electrode 12s, and the first wiring pattern 41” in the present invention (mode 1). The electronically connecting member 52 corresponds to an electronically connecting member “that is used for connecting the source electrode 22s of the second semiconductor element 20 and the second wiring pattern 42” in the present invention (mode 1). The electronically connecting member 51 corresponds to an electronically connecting member “that is used for connecting the drain electrode 11d of the first semiconductor element 10 and the third wiring pattern 43” in the present invention (mode 1).

In the electronic module 130 according to the embodiment 2, a parasitic inductance L1 at the portion where the first semiconductor element 10 and the second semiconductor element 20 are connected to each other is smaller than a parasitic inductance L2 at the portion where the first semiconductor element 10 and the capacitor 30 are connected to each other and a parasitic inductance L3 at the portion where the second semiconductor element 20 and the capacitor 30 are connected to each other.

The connecting portion where the first semiconductor element 10 and the second semiconductor element 20 are connected to each other is, in the circuit system having the bridge structure such as a half bridge circuit, for example, a potential portion extremely important from a viewpoint of operation stability. That is, the reduction of inductance at the above-mentioned connecting portions (the first electrode 12s, the second electrode 21d, the electronically connecting member 51, the first wiring pattern 41) exhibits an outstanding effect in reducing a switching loss, a surge voltage, and noises.

In the region A surrounded by a broken line in FIG. 5, a first semiconductor element 10 mounting region in the first wiring pattern 41, a second semiconductor element 20 mounting region in the second wiring pattern 42, and a portion of the third wiring pattern 43 are formed parallel to each other. With such a configuration, the electronic module 130 is configured such that the connection distances of the electronically connecting members 51, 52, 53 between the first semiconductor element 10, the second semiconductor element 20, the first wiring pattern 41, the second wiring pattern 42, and the third wiring pattern 43 become shortest respectively and hence, the further lowing of inductance in the electronic module 130 can be realized.

The second wiring pattern 42 has a first capacitor connecting portion 34 to which the portion 31 of the capacitor is connected, the third wiring pattern 43 has a second capacitor connecting portion 35 to which the other portion 32 of the capacitor is connected. Further, flat surface shapes of the second wiring pattern 42 and the third wiring pattern 43, and positions where the first capacitor connecting portion 34 and the second capacitor connecting portion 35 are formed are defined such that a wiring route that starts from one portion 22s of the second electrode and reaches the other portion 11d of the first electrode via the second wiring pattern 42, the capacitor 30, and the third wiring pattern 43 becomes the shortest. A resist is formed around the first capacitor connecting portion 34 and the second capacitor connecting portion 35 respectively.

At the portions surrounded by these resists, the portion 31 of the capacitor and the first capacitor connecting portion 34 are connected to each other, and the other portion 32 of the capacitor and the second capacitor connecting portion 35 are connected to each other. That is, by adopting the configuration described in the embodiment 2, the wiring route that starts from one portion 22s of the second electrode and reaches the other portion 11d of the first electrode via the second wiring pattern 42, the capacitor 30, and the third wiring pattern 43 becomes the shortest. In a case where the electronic module 130 is applied to the circuit system having the bridge structure such as the half bridge circuit, for example, the electronic module 130 exhibits a snubber effect at maximum and hence, it is possible to acquire an outstanding effect of reducing a switching loss, a surge voltage and noises.

The first capacitor connecting portion 34 corresponds to a first capacitor connecting portion of the present invention (mode 1). The second capacitor connecting portion 35 corresponds to a second capacitor connecting portion of the present invention (mode 1).

To describe the configuration of a position adjusting member 60 with reference to FIG. 6, the position adjusting member 60 has a thickness of 0.4 mm, for example, is disposed between the second wiring pattern 42 and the second semiconductor element 20. The first semiconductor element 10 is directly mounted on the first wiring pattern 41. Accordingly, the configuration is provided where the surfaces of the second electrodes 21d, 22s, 22sb, 23g become higher than the surfaces of the first electrodes 11d, 12s, 12sb, 13g by a stepped portion D formed by the thickness 0.4 mm of the position adjusting member 60. The surfaces of the first electrodes 11d, 12s, 12sb, 13g are higher than a surface of the first wiring pattern 41 and a surface of the third wiring pattern 43.

The first semiconductor element 10 and the second semiconductor element 20 are disposed in the same direction and hence, the second electrode 21d and the first electrode 12s are disposed adjacently to each other and hence, the second electrode 21d and the first electrode 12s can be connected to each other with the shortest distance. Accordingly, the reduction of a parasitic inductance can be realized. That is, a parasitic inductance is an inductive component that parasites a wire, and is affected by a length, a width, a curvature and the like of the wire. By adopting the configuration illustrated in FIG. 6, the parasitic inductance can be reduced. In such a configuration, “the same direction” means that the arrangement directions of a plurality of source electrodes, a plurality of drain electrodes in the first semiconductor element 10 and the second semiconductor element 20 are the same direction respectively. In a case where the source electrode or the drain electrode each is formed of one laterally elongated electrode, “the same direction” may also mean that the respective extending directions of the source electrode and the drain electrode in the first semiconductor element 10 and in the second semiconductor element 20 are the same direction. Further, “same direction” also means that the longitudinal direction of the first semiconductor element 10 and the longitudinal direction of the second semiconductor element 20 are the same direction.

As illustrated in FIG. 5, a power source terminal 70, an output terminal 72, and a ground terminal 74 are disposed on one side of the electronic module 130, and a first control-use signal terminal 80, a first detection-use signal terminal 81, a second detection-use signal terminal 82, a second control-use signal terminal 83 are disposed on the other side of the electronic module 130. The first control-use signal terminal 80 is connected to a fourth wiring pattern 44 formed on the surface of a circuit board 40, and the first detection-use signal terminal 81 is connected to a fifth wiring pattern 45 formed on the surface of the circuit board 40. The second detection-use signal terminal 82 is connected to the sixth wiring pattern 46 formed on the surface of the circuit board 40. The second control-use signal terminal 83 is connected to the seventh wiring pattern 47 formed on the surface of the circuit board 40.

The first gate electrode 13g is connected to the fourth wiring pattern 44 via the fifth electrically connecting member 55, and the first detection-use source electrode 12sb is connected to the fifth wiring pattern 45 via a sixth electrically connecting member 56. The second detection-use source electrode 22sb is connected to the sixth wiring pattern 46 via a seventh electrically connecting member 57. The second gate electrode 23g is connected to the seventh wiring pattern 47 via an eighth electrically connecting member 58.

In the electronic module 130 according to the embodiment 2, the parasitic inductances L1, L2, L3 at the respective portions indicated in the equivalent circuit 120 illustrated in FIG. 4 depend on the electrically connecting members and the structures of the wiring patterns illustrated in FIG. 5, and are obtained by simulation. As a result of the simulation performed by taking into account the electrically connecting members and the structures, L1 was 0.49 nH, L2 was 1.63 nH, and L3 is 1.73 nH. It is understood that these values are lower by one digit or more compared to the above-mentioned prior art (patent literatures 3, 4, 5 and the like).

As illustrated in FIG. 5, the shape of the first wiring pattern 41 is a shape based on the letter L, a width of a mounting region of the first semiconductor element 10 is 3.5 mm and the width of an output terminal connecting region is 6.5 mm. The shape of the second wiring pattern 42 is a shape based on the letter L, a width of a mounting region of the second semiconductor element 20 is 4.1 mm and the width of a ground terminal connecting region is 9.0 mm. The third wiring pattern 43 has a rectangle with a size where a lateral length is 8.3 mm and the longitudinal length is 3.5 mm. Further, a wire diameter is ϕ 200 μm.

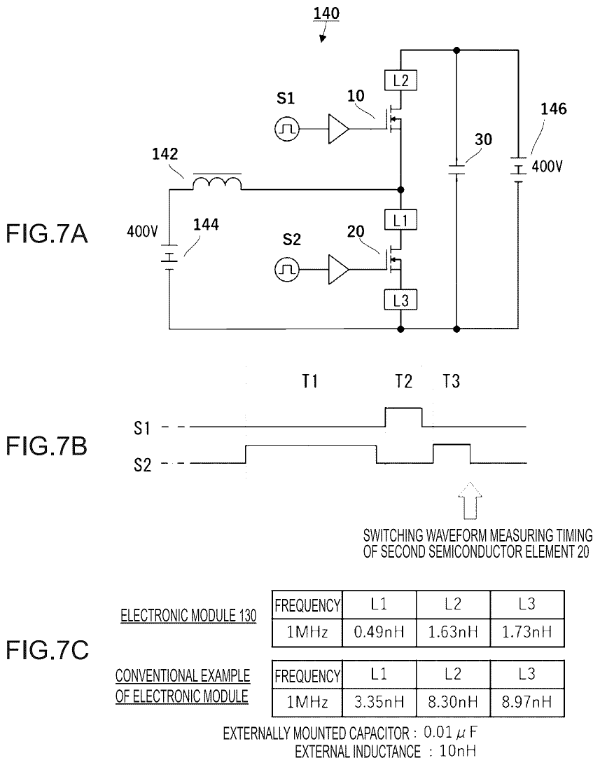

FIG. 7A to FIG. 7C are views provided for describing a double pulse test. FIG. 7A is a view illustrating a simulation block 140 of a double pulse test circuit in a case where the first semiconductor element 10 and the second semiconductor element 20 are formed of a transistor (for example, the GaNHEMT). In the double pulse test, a drain-source voltage VDS and a drain current ID are simulated after a current having a switching waveform is turned off.

The configuration of a half bridge boosting circuit is adopted as the circuit configuration where the first semiconductor element 10 and the second semiconductor element 20 are connected in series, and the capacitor 30 is connected in parallel to a series circuit consisting of the first semiconductor element 10 and the second semiconductor element 20. A choke coil 142 is connected to an input power source 144 of 400 V, and the other end of the choke coil 142 is connected to an intermediate point between the first semiconductor element 10 and the second semiconductor element 20. The boosted Voltage is clumped by an output power source 146 of 400 V.

In the double pulse test, a first control-use signal S1 and a second control-use signal S2 as illustrated in FIG. 7B are applied between a gate and a source in the first semiconductor element 10 that functions as a transistor and the second semiconductor element 20 that functions as a transistor. First, the second semiconductor element 20 is turned on in response to the second control-use signal S2, and the second semiconductor element 20 is turned off after a laps of time T1. After the predetermined dead time elapses from this timing, the first semiconductor element 10 is turned on in response to the first control-use signal S1, the first semiconductor element 10 is turned off after a laps of time T2.

After a laps of predetermined dead time from this timing, the second semiconductor element 20 is turned on in response to the second control-use signal S2, and the second semiconductor element 20 is turned off after a laps of time T3. This point of time becomes a switching waveform measuring timing at which waveforms of a drain-source voltage VDS and a drain current ID of the second semiconductor element 20 that functions as a transistor are measured.

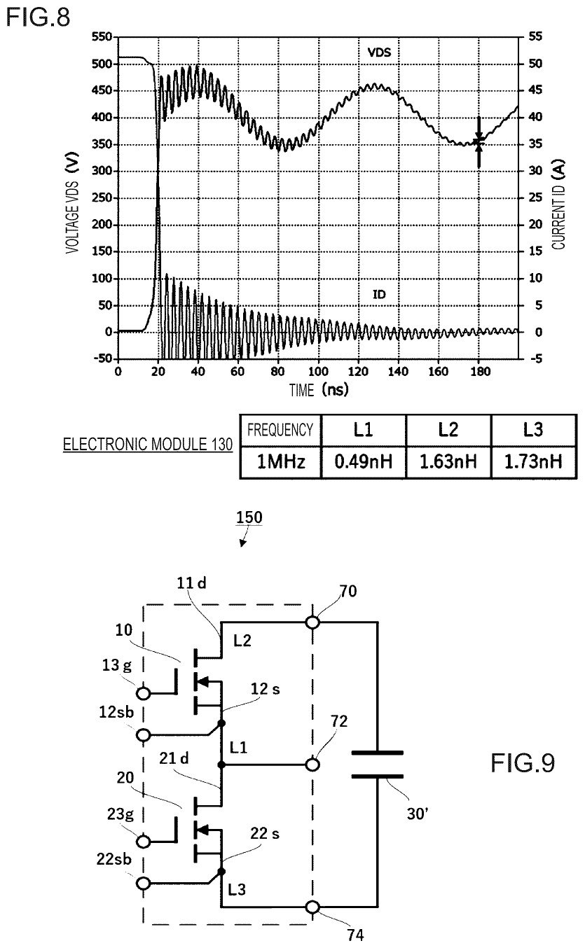

FIG. 8 is a graph where switching waveforms of the drain-source voltage VDS and the drain current ID of the second semiconductor element 20 in the electronic module 130 according to the embodiment 2 are obtained by simulation. In FIG. 8, the inductances L1, L2, L3 (see FIG. 4) in the electronic module 130 according to the embodiment 2 are obtained by simulation, the drain source voltage VDS and the drain current ID of the second semiconductor element 20 that functions as a transistor are simulated by the simulation block 140 of the double pulse test circuit, and switching waveforms are measured at the switching waveform measuring timing.

Parasitic inductances L1, L2, L3 at the connecting portions indicate parasitic inductances of the wiring pattern of the equivalent circuit illustrated in FIG. 4, and as the parasitic inductances L1, L2, L3 of the electronic module 130, L1 of 0.49 nH, L2 of 1.63 nH, and L3 of 1.73 nH are obtained by simulation. Further, with respect to parasitic inductances of a conventional electronic module described later, L1 of 3.35 nH, L2 of 8.30 nH and L3 of 8.97 nH are obtained.

The parasitic inductances of the electronic module 130 are low by one digit or more compared to the parasitic inductances in the above-mentioned prior art (patent literatures 3, 4, 5 and the like). A capacitance of the capacitor 30 mounted in the electronic module 130 is set to 0.01 μF, and an inductance of the choke coil 142 connected to the outside of the electronic module 130 is set to 50 μH.

As illustrated in FIG. 8, in the double pulse test performed using the electronic module 130 according to the embodiment 2, the maximum drain-source voltage is 490 V. Accordingly, in a case where the drain-source absolute maximum rated voltage is 650 V, it is understood that a sufficient margin is secured as the first semiconductor element 10 and the second semiconductor element 20 with respect to a specification rated voltage. Further, a surge voltage is attenuated to approximately 10 Vp-p after a lapse of 180 ns from switching waveform measuring timing, for example and hence, it was understood that the electronic module 130 was operationally stable. This was also apparent from the waveform of the drain current ID.

As a comparison example, the result obtained by performing a double pulse test evaluation using a conventional-type electronic module is described. The conventional-type electronic module used here is an electronic module that includes none of the characteristic configuration of the present invention (the mode 1: the configuration where the surface of the first electrode and the surface of the second electrode are disposed at different height positions from each other, a mode 2 described later: the configuration where the first semiconductor element and the second semiconductor element are disposed such that the extending direction of one portion of the first electrode and the extending direction of the other portion of the second electrode are same direction, a mode 3 described later: the configuration where the first semiconductor element and the second semiconductor element are disposed in different directions, and a mode 4 described later: a first cascode switch element and a second cascode switch element are disposed in different directions). Although the above-mentioned conventional electronic modules are the electronic modules that do not possess the characteristic configuration of the present invention, these electronic modules have the configuration that reduces a parasitic inductance as much as possible (the parasitic inductance being reduced by 10 to 20% compared to the electronic modules described in patent literatures 3, 4, 5). By using such comparison examples, it is proved that that the present invention possesses an outstanding parasitic inductance reducing effect.

FIG. 9 is an equivalent circuit 150 of the conventional-type electronic module. A first semiconductor element 10 and a second semiconductor element 20 constitute a half bridge circuit. A drain electrode 11d of the first semiconductor element 10 is connected to a power source terminal 70. A source electrode 12s of the first semiconductor element 10 is connected to a drain electrode 21d of the second semiconductor element 20 and an output terminal 72.

A source electrode 22s of the second semiconductor element 20 is connected to a ground terminal 74. A capacitor is an externally mounted capacitor 30′ that is externally mounted, and is connected to the power source terminal 70 and the ground terminal 74. The above-mentioned circuit is a circuit where the externally mounted capacitor 30′ is connected in parallel to the first semiconductor element 10 and the second semiconductor element 20 that are connected in series. The above-mentioned circuit also includes detection-use source electrodes 12sb, 12sb.

In the equivalent circuit 150 of the conventional-type electronic module illustrated in FIG. 9, a parasitic inductance includes: a parasitic inductance L1 generated at a portion where the source electrode 12s of the first semiconductor element 10 and the drain electrode 21d of the second semiconductor element 20 are connected to each other, a parasitic inductance L2 generated at a portion where the drain electrode 11d f the first semiconductor element 10 and the externally mounted capacitor 30′ are connected to each other; and a parasitic inductance L3 generated at a portion where the source electrode 22s of the second semiconductor element 20 and the externally mounted capacitor 30′ are connected to each other.

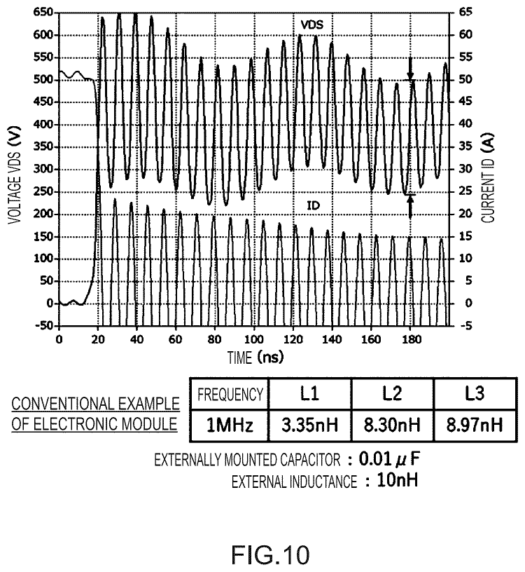

FIG. 10 is a graph where switching waveforms of the drain-source voltage VDS and the drain current ID of the second semiconductor element 20 in the equivalent circuit 150 of the conventional-type electronic module are obtained by simulation. In FIG. 10, the inductances L1, L2, L3 in the equivalent circuit 150 of the conventional-type electronic module are obtained by simulation, a drain source voltage VDS and a drain current ID of the second semiconductor element 20 that functions as a transistor are simulated by the simulation block 140 of the double pulse test circuit illustrated in FIG. 7A, and switching waveforms are measured at the switching waveform measuring timing.

In a case where the first semiconductor element 10 and the second semiconductor element 20 are constituted of a transistor (for example, GaNHEMT), inductances L1, L2, L3 in the configuration of the equivalent circuit 150 of the conventional-type electronic module are respectively, by simulation, L1 of 3.35 nH, L2 of 8.30 nH, and L3 of 8.97 nH are obtained and these values are higher than the corresponding values of the example in the embodiment 2. The evaluation of the double pulse test circuit is performed by the simulation block 140 illustrated in FIG. 7A, and an inductance of the externally mounted capacitor 30′ is set to 0.01 μF and an external inductance is set to 10 nH. An inductance of the choke coil 142 is set to 50 μH.

As illustrated in FIG. 10, in the double pulse test performed using the electronic module according to the comparison example, the maximum drain-source voltage VDS is 650 V. Accordingly, in a case where the drain-source absolute maximum rated voltage is 650 V, it is understood that no margin is secured with respect to the drain-source absolute maximum rated voltage of 650V as the first semiconductor element 10 and the second semiconductor element 20 and hence, it is understood that the electronic module according to the comparison example cannot be used at the specification rated voltage. Further, a surge voltage is, for example, approximately 250 Vp-p even after a lapse of 180 ns from the switching waveform measuring timing and hence, the sufficient attenuation of the surge voltage is not observed whereby it is understood that the electronic module according to the comparison example is operationally unstable. This result is also apparent from the waveform of the drain current ID.

As has been described above, according to the present invention (mode 1), the further reduction of the inductance in the electronic module can be realized, and a switching loss, a surge voltage and noises generated in a case where the circuit system is constituted by using such an electronic module can be reduced. Accordingly, performances such as operation stability and reliability of the circuit system that uses the electronic module can be realized.

Although the embodiment of the present invention (mode 1) has been described, the present invention (mode 1) is not limited to the above-mentioned embodiment, and is applicable to an electronic module on which a plurality of semiconductor chips are mounted, and various modifications and applications are possible without departing from the gist of the present invention (mode 1).
(1) In the above-mentioned respective embodiments, the present invention (mode 1) has been described with reference to the electronic module that includes the capacitor. However, the present invention is not limited to such a configuration. For example, an electronic module that does not include a capacitor (for example, an electronic module where a capacitor is eliminated from the electronic module 130 according to the embodiment 2, and a mold resin is partially removed at a capacitor mounting portion) can be used. In this case, it is possible to constitute an electronic module substantially equal to the electronic module according to the embodiment 2 by mounting an externally mounting capacitor at a capacitor mounting position.
(2) In the above-mentioned respective embodiments, the height position of the surfaces of the second electrodes or the height position of the surfaces of the first electrodes is adjusted by providing the position adjusting member 60 between the second wiring pattern 42 and the second semiconductor element 20 or between the first wiring pattern 41 and the first semiconductor element 10. However, the present invention (mode 1) is not limited to such a configuration. In the present invention (mode 1), the height position of the surfaces of the second electrodes or the surfaces of the first electrodes can be adjusted by using the first semiconductor element and the second semiconductor element that differ in height from each other.

### Present Invention (Mode 2)

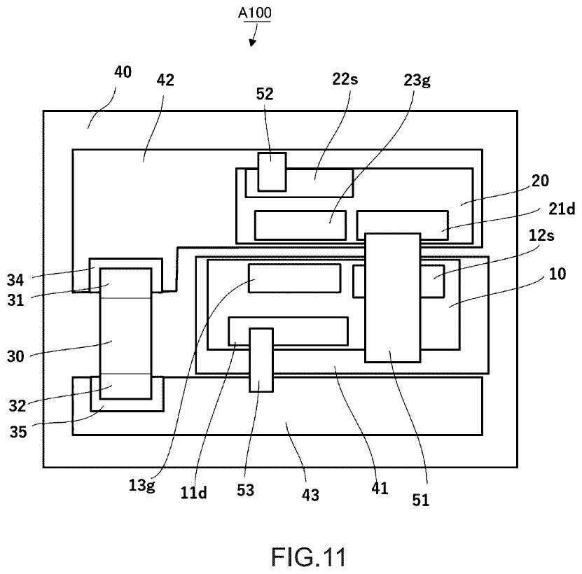

FIG. 11 is a conceptual view of an electronic module A100 according to the present invention (mode 2). The electronic module A100 according to the present invention (mode 2) is a resin-sealed-type electronic module. As illustrated in FIG. 1A and FIG. 1B, the electronic module A100 according to the present invention (mode 2) includes: a first semiconductor element 10 having a plurality of first electrodes 11d, 12s, 13g; a second semiconductor element 20 having a plurality of second electrodes 21d, 22s, 23g; a capacitor 30; a circuit board 40 having a first wiring pattern 41 on which the first semiconductor element 10 is mounted, a second wiring pattern 42 on which a second semiconductor element 20 is mounted, and a third wiring pattern 43; and a plurality of electrically connecting members 51, 52, 53.

In the electronic module A100 according to the present invention (mode 2), one portion 12s of the first electrode and the other portion 21d of the second electrode 21d are connected to the first wiring pattern 41, one portion 22s of the second electrode and one portion 31 of the capacitor 30 are connected to the second wiring pattern 42, and the other portion 11d of the first electrode and the other portion 32 of the capacitor 30 are connected to the third wiring pattern 43.

With respect to the electronic module A100 according to the present invention (mode 2), one portion 12s of the first electrode, the other portion 21d of the second electrode and the first wiring pattern 41 are connected to each other by one electrically connecting member (the electrically connecting member 51) out of the plurality of electrically connecting members, and the first semiconductor element 10 and the second semiconductor element 20 are disposed such that the extending direction of one portion 12s of the first electrode and the extending direction of the other portion 21d of the second electrode are the same direction. In this embodiment, “the extending direction of the electrode” is used as a concept that includes “the arrangement direction of individual electrodes” in a case where the electrodes are constitute of individual electrodes.

According to the electronic module A100 according to the present invention (mode 2), the respective wiring patterns, the respective semiconductor elements and the respective electrically connecting members are disposed above and hence, a length of the electrically connecting member (particularly the above-mentioned one electrically connecting member 51) can be shortened and, in addition, the further reduction of inductance in the electronic module A100 that includes portion other than the first electrically connecting member 51 can be enhanced. In a case where the circuit system is constituted using the electronic module A100, the reduction of a switching loss, a surge voltage and noises can be realized. Accordingly, performances such as operational stability and reliability of the circuit system that uses the electronic module can be enhanced.

The connecting portion between the first semiconductor element 10 and the second semiconductor element 20 is, for example, in a circuit system having a bridge structure such as a half bridge circuit, an extremely important potential portion from a viewpoint of operation stability. The reduction of an inductance of the above-mentioned connecting points (the first electrode 12s, the second electrode 21d, the electrically connecting member 51, the first wiring pattern 41) acquires an outstanding effect in reducing a switching loss, a surge voltage and noises.

The first semiconductor element 10 corresponds to the first semiconductor element according to the present invention (mode 2). The second semiconductor element 20 corresponds to the second semiconductor element according to the present invention (mode 2). The capacitor 30 corresponds to the capacitor according to the present invention (mode 2). The circuit board 40 corresponds to the circuit board according to the present invention (mode 2). The electrically connecting members 51, the electrically connecting member 52 and the electrically connecting member 53 correspond to the electrically connecting members according to the present invention (mode 2). Among these electrically connecting members, the electrically connecting member 51 corresponds to one electrically connecting member according to the present invention (mode 2). The plurality of first electrodes 11d, 12s, 13g correspond to the plurality of first electrodes according to the present invention (mode 2). The plurality of second electrodes 21d, 22s, 23g correspond to the plurality of second electrodes according to the present invention (mode 2).

The first wiring pattern 41 corresponds to the first wiring pattern according to the present invention (mode 2). The second wiring pattern 42 corresponds to the second wiring pattern according to the present invention (mode 2). The third wiring pattern 43 corresponds to the third wiring pattern according to the present invention (mode 2). One portion 12s of the first electrode corresponds to one portion of the first electrode according to the present invention (mode 2). The other portion 11d of the first electrode corresponds to the other portion of the first electrode according to the present invention (mode 2). One portion 22s of the second electrode corresponds to one portion of the second electrode according to the present invention (mode 2). The other portion 21d of the second electrode corresponds to the other portion of the second electrode according to the present invention (mode 2). One portion 31 of the capacitor corresponds to the one portion of the capacitor according to the present invention (mode 2). The other portion 32 of the capacitor corresponds to the other portion of the capacitor according to the present invention (mode 2).

A demand for increasing a switching frequency from a conventional several hundred kHz to several MHz band region and a demand for also increasing a turn-on/off speed to one digit or more are increasing. Accordingly, the expectation rises for a compound semiconductor that enables a high-speed and a large-current operation. It is necessary to form the first semiconductor element 10 and the second semiconductor element 20 using materials that can cope with such a high speed frequency and a high speed turn on/off speed.

The first semiconductor element 10 and the second semiconductor element 20 may be formed of a semiconductor using silicon, gallium nitride, silicon carbide or gallium oxide as a material. The first semiconductor element 10 and the second semiconductor element 20 may be semiconductors formed using the same material or different materials respectively.

With such a configuration, the electronic module according to the embodiment 2 is constituted of a semiconductor element having a function selectively suitable for a circuit application (a half bridge circuit, a totem-pole-type power factor improving circuit or the like). Accordingly, in a case where the circuit system is constituted using such an electronic module, a switching loss, a surge voltage and noises can be reduced and hence, operational stability and the reliability of the circuit system that uses the electronic module can be enhanced.

Particularly, in a switching power source system that uses a compound semiconductor capable of being operated at a high speed and with a large current, for example, gallium nitride, a silicon carbide or gallium oxide, the electronic module A100 according to the embodiment of the present invention (mode 2) can acquire a particularly outstanding effect with respect to a demand for increasing a switching frequency into a high-speed band of several MHz, a demand for also increasing a turn on/off speed by 1 digit or more, and a demand for reducing a switching loss, a surge voltage and noises at the time of operating the circuit system.

Next, with respect to the electrodes disposed on the surface of the first semiconductor element 10 and the surface of the second semiconductor element 20, these electrodes exactly have the same configuration as the corresponding electrodes described in the present invention (model) and hence, the description of these electrodes is omitted. For reference, see the above-mentioned example of the first electrode and the second electrode illustrated in FIG. 2.

In this case, the drain electrodes 11d, 21d correspond to the drain electrodes in the present invention (mode 2). The source electrodes 12s, 22s correspond to the source electrodes in the present invention (mode 2). The gate electrodes 13g, 23g correspond to the gate electrodes in the present invention (mode 2).

The equivalent circuit of the electronic module A100 is exactly the same as the equivalent circuit described in the present invention (mode 1) and hence, the description of equivalent circuit is omitted (refer to the above-mentioned equivalent circuit 120 illustrated in FIG. 4). The same goes for equivalent circuits of electronic modules A130, A132 described later.

To describe the present invention (mode 2) with reference to the equivalent circuit 120 illustrated in FIG. 4, the parasitic inductance L1 at the portion that connects the first semiconductor element 10 and the second semiconductor element 20 is set smaller than the parasitic inductance L2 at the portion that connects the first semiconductor element 10 and the capacitor 30 and the parasitic inductance L3 at the portion that connects the second semiconductor element 20 and the capacitor 30. With such a configuration, the inductance in the electronic module 100 that includes the electrically connecting member 51 can be further reduced.

### Embodiment 3

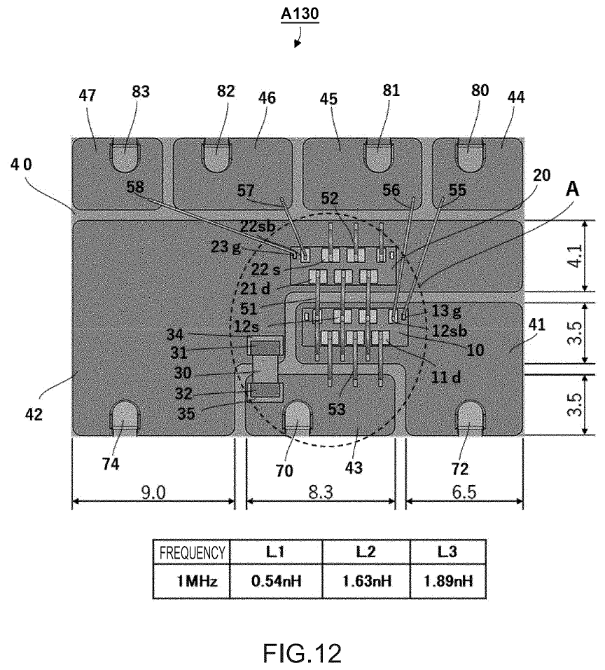

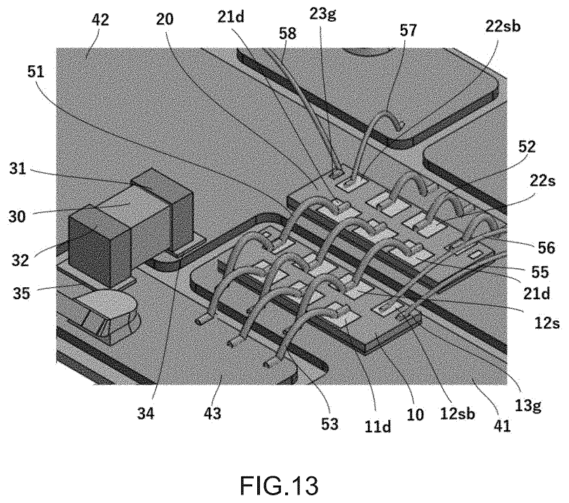

FIG. 12 is a plan view illustrating the electronic module A130 according to the embodiment 3. FIG. 13 is a perspective view of the electronic module A130 according to the embodiment 3 illustrating a main part in an enlarged manner. FIG. 13 illustrates a region A surrounded by a broken line in FIG. 12. The embodiment 3 is a specific embodiment of the equivalent circuit 120 illustrated in the above-mentioned FIG. 4.

As illustrated in FIG. 12, the electronic module A130 according to the embodiment 3 includes: a first semiconductor element 10 having a plurality of first electrodes 11d, 12s, 13g; a second semiconductor element 20 having a plurality of second electrodes 21d, 22s, 23g; a capacitor 30; a circuit board 40 having a first wiring pattern 41 on which the first semiconductor element 10 is mounted, a second wiring pattern 42 on which the second semiconductor element 20 is mounted, and a third wiring pattern 43; and a plurality of electrically connecting members 51, 52, 53. As the circuit board 40, for example, a DCB circuit board where a copper circuit board is directly joined to a ceramic substrate is used.

In the electronic module A130 according to the embodiment 3, one portion 12s of the first electrode and the other portion 21d of the second electrode are connected to the first wiring pattern 41, one portion 22s of the second electrode and one portion 31 of the capacitor 30 are connected to the second wiring pattern 42, and the other portion 11d of the first electrode and the other portion 32 of the capacitor 30 are connected to the third wiring pattern 43.

With respect to the electronic module A130 according to the embodiment 3, one portion 12s (source electrode 12s) of the first electrode, the other portion 21d (drain electrode 21d) of the second electrode and the first wiring pattern 41 are connected to each other by one electrically connecting member 51 out of the plurality of electrically connecting members 51, 52, 53, and the first semiconductor element 10 and the second semiconductor element 20 are disposed such that the extending direction (arrangement direction) of one portion 12s of the first electrode and the extending direction (arrangement direction) of the other portion 21d of the second electrode are the same direction.

In the electronic module A130 according to the embodiment 3, a state where the first semiconductor element 10 and the second semiconductor element 20 are disposed in the same direction means that the electrode arrangement direction of the drain electrodes 11d formed of a plurality of individual electrodes and the source electrodes 12s formed of a plurality of individual electrodes of the first semiconductor element 10, and the electrode arrangement direction of the drain electrodes 21d formed of a plurality of electrodes of the second semiconductor element 20 and the source electrodes 22s formed of a plurality of electrodes of the second semiconductor element 20 are the same direction as illustrated in FIG. 12.

According to the electronic module A130 according to the embodiment 3, the respective wiring patterns, the respective semiconductor elements and the respective electrically connecting members are disposed as described above. Accordingly, a length of the first electrically connecting member 51 that connects the other portion 21d of the second electrode, one portion 12s of the first electrode, and the first wiring pattern 41 can be shortened. Accordingly, the further reduction of inductance in the electronic module A130 can be realized. Further, in a case where the circuit system is formed using the electronic module A130, the reduction of a switching loss, a surge voltage and noises can be realized. Accordingly, performances such as operational stability and reliability of the circuit system that uses the electronic module can be enhanced.

In the electronic module A130 according to the embodiment 3, a first semiconductor element mounting region in the first wiring pattern 41, a second semiconductor element mounting region in the second wiring pattern 42, and a portion of the third wiring pattern 43 are formed parallel to each other. With such a configuration, the further lowing of inductance in the electronic module A130 can be realized.

In the electronic module A130 according to the embodiment 3, the second wiring pattern 42 has a first capacitor connecting portion 34 to which one portion 31 of the capacitor 30 is connected, the third wiring pattern 43 has a second capacitor connecting portion 35 to which the other portion 32 of the capacitor 30 is connected. Further, flat surface shapes of the second wiring pattern 42 and the third wiring pattern 43, and positions where the first capacitor connecting portion 34 and the second capacitor connecting portion 35 are formed are defined such that a wiring route that stars from one portion 22s of the second electrode and reaches the other portion 11d of the first electrode via the second wiring pattern 42, the capacitor 30, and the third wiring pattern 43 becomes the shortest. A resist is formed around the first capacitor connecting portion 34 and the second capacitor connecting portion 35 respectively.

At the portions surrounded by these resists, the portion 31 of the capacitor and the first capacitor connecting portion 34 are connected to each other, the other portion 32 of the capacitor and the second capacitor connecting portion 35 are connected to each other. That is, by adopting the configuration described in the embodiment 3, the wiring route that starts from one portion 22s of the second electrode and reaches the other portion 11d of the first electrode via the second wiring pattern 42, the capacitor 30, and the third wiring pattern 43 becomes the shortest. In a case where the electronic module 130 is applied to the circuit system having the bridge structure such as the half bridge circuit, for example, the electronic module 130 exhibits a snubber effect at maximum and hence, it is possible to acquire an outstanding effect of reducing a switching loss, a surge voltage and noises.

The first capacitor connecting portion 34 corresponds to a first capacitor connecting portion of the present invention (mode 2). The second capacitor connecting portion 35 corresponds to a second capacitor connecting portion of the present invention (mode 2).

As illustrated in FIG. 12, a power source terminal 70, an output terminal 72, and a ground terminal 74 are disposed on one side of the electronic module A130, and a first control-use signal terminal 80, a first detection-use signal terminal 81, a second detection-use signal terminal 82, a second control-use signal terminal 83 are disposed on the other side of the electronic module A130. The first control-use signal terminal 80 is connected to a fourth wiring pattern 44 formed on a surface of a circuit board 40, the first detection-use signal terminal 81 is connected to the fifth wiring pattern 45 formed on the surface of the circuit board 40. The second detection-use signal terminal 82 is connected to the sixth wiring pattern 46 formed on the surface of the circuit board 40. The second control-use signal terminal 83 is connected to the seventh wiring pattern 47 formed on the surface of the circuit board 40.

The first gate electrode 13g is connected to the fourth wiring pattern 44 via a fifth electrically connecting member 55, the first detection-use source electrode 12sb is connected to the fifth wiring pattern 45 via a sixth electrically connecting member 56. The second detection-use source electrode 22sb is connected to the sixth wiring pattern 46 via a seventh electrically connecting member 57. The second gate electrode 23g is connected to the seventh wiring pattern 47 via an eighth electrically connecting member 58.

In the electronic module A130 according to the embodiment 3, the parasitic inductances L1, L2, L3 at the respective portions indicated in the equivalent circuit 120 illustrated in FIG. 4 described above depend on the electrically connecting members and the structures of the wiring patterns illustrated in FIG. 12, and are obtained by simulation. As a result of the simulation performed by taking into account the electrically connecting members and the structures, L1 was 0.54 nH, L2 was 1.63 nH, and L3 was 1.89 nH. It is understood that these values are lower by one digit or more compared to the above-mentioned prior art (patent literatures 3, 4, 5 and the like).

As illustrated in FIG. 12, the shape of the first wiring pattern 41 is a shape based on the letter L, a width of a mounting region of the first semiconductor element 10 is 3.5 mm and the width of an output terminal connecting region is 6.5 mm. The shape of the second wiring pattern 42 is a shape based on the letter L, a width of a mounting region of the second semiconductor element 20 is 4.1 mm and the width of a ground terminal connecting region is 9.0 mm. The third wiring pattern 43 has a rectangle with a size where a lateral length is 8.3 mm and the longitudinal length is 3.5 mm. Further, a wire diameter is ϕ 200 μm.

In the electronic module A130 according to the embodiment 3, a parasitic inductance at the portion where the first semiconductor element 10 and the second semiconductor element 20 are connected to each other is smaller than a parasitic inductance at the portion where the first semiconductor element 10 and the capacitor 30 are connected to each other and a parasitic inductance at the portion where the second semiconductor element 20 and the capacitor 30 are connected to each other.

The reduction of inductance at the connecting portion between the first semiconductor element 10 and the second semiconductor element 20 is, for example, in a circuit t system having a bridge structure such as a half bridge circuit, an extremely important potential portion from a viewpoint of operation stability. This reduction of inductance at the above-mentioned connecting points (the first electrode 12s, the second electrode 21d, the electrically connecting member 51, the first wiring pattern 41) acquires an outstanding effect in reducing a switching loss, a surge voltage and noises.

Accordingly, the electronic module A130 according to the embodiment 3 can realize the enhancement of performances of the circuit system such as operational stability and the reliability.

The ground terminal 74, the power source terminal 70 and the output terminal 72 are disposed on one side of the electronic module A130 according to the embodiment 3, the control-use signal terminal is disposed on the other side of the electronic module A130, and the first semiconductor element 10 and the second semiconductor element 20 are disposed parallel to or perpendicular to the arrangement direction of the ground terminal 74, the power source terminal 70 and the output terminal 72. With such a configuration, the wiring pattern through which a large current flows at a high voltage and is connected to the power source terminal 70, the ground terminal 74 and the output terminal 72 can be separated from the control-signal-use wiring pattern and hence, an effect of noises can be made small.

In the electronic module A130, the first semiconductor element 10 and the second semiconductor element 20 are disposed parallel to the ground terminal 74, the power source terminal 70 and the output terminal 72. The power source terminal 70, the output terminal 72 and the ground terminal 74 are disposed on one side of the electronic module A130, and the first control-use signal terminal 80, the first detection-use signal terminal 81, the second detection-use signal terminal 82 and the second control-use signal terminal 83 are disposed on the other side of the electronic module A130.

The first control-use signal terminal 80 is connected to a fourth wiring pattern 44 formed on a surface of a circuit board 40, and the first detection-use signal terminal 81 is connected to the fifth wiring pattern 45 formed on the surface of the circuit board 40. The second detection-use signal terminal 82 is connected to the sixth wiring pattern 46 formed on the surface of the circuit board 40. The second control-use signal terminal 83 is connected to the seventh wiring pattern 47 formed on the surface of the circuit board 40.

The first gate electrode 13g is connected to the fourth wiring pattern 44 via the fifth electrically connecting member 55, and the first detection-use source electrode 12sb is connected to the fifth wiring pattern 45 via a sixth electrically connecting member 56. The second detection-use source electrode 22sb is connected to the sixth wiring pattern 46 via a seventh electrically connecting member 57. The second gate electrode 23g is connected to the seventh wiring pattern 47 via an eighth electrically connecting member 58.

The first semiconductor element 10 and the second semiconductor element 20 may be disposed perpendicular to the arrangement direction of the ground terminal 74, the power source terminal 70 and the output terminal 72. Also in this case, in the same manner as the region A surrounded by a broken line in FIG. 12, a first semiconductor element 10 mounting region in the first wiring pattern 41, a second semiconductor element 20 mounting region in the second wiring pattern 42, a portion of the third wiring pattern 43 are formed parallel to each other.

With such a configuration, the connection distances of the first semiconductor element 10, the second semiconductor element 20, the first wiring pattern 41, the second wiring pattern 42, and the third wiring pattern 43 can be disposed such that the respective connection distances of the electrically connecting members become shortest and hence, the further reduction of inductance in the electronic module 130 can be realized.

It is preferable that the first electrically connecting member 51, the second electrically connecting member 52 and the third electrically connecting member 53 are each formed of a line-shaped or plate-shaped member. With such a configuration, an electrically connecting member having a small parasitic inductance is applicable and hence, the reduction of parasitic inductance can be realized. In the embodiment 3, the case is described where the electrically connecting members are each formed of a line-shaped member. Next, the description is made with respect to an embodiment relating to a case where some electrically connecting members are each formed of a line-shaped member, and some other electrically connecting members are each formed of a plate-shaped member.

### Embodiment 4

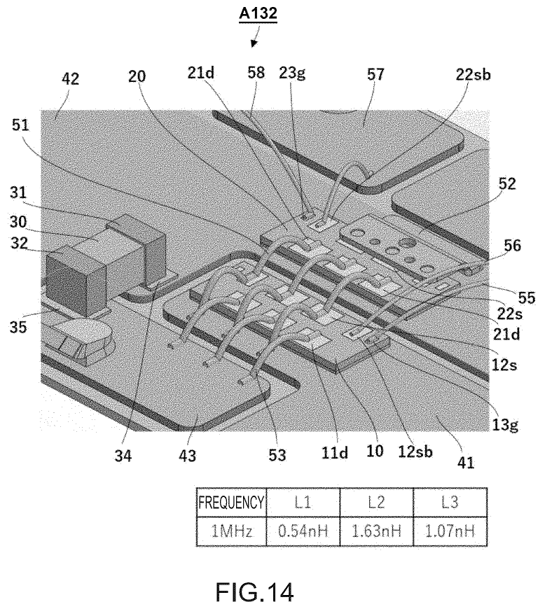

FIG. 14 is a perspective view of an electronic module A132 according to the embodiment 4 illustrating a main part in an enlarged manner. The electronic module A132 according to the embodiment 4 differs from the electronic module A130 according to the embodiment 3 with respect to a point that a second electrically connecting member 52 is formed of a plate-shaped electrically connecting member. Other constitutional elements are same as the corresponding constitutional elements of the electronic module A130 according to the embodiment 3. The second electrically connecting member 52 having a plate shape has an area that covers three source electrodes 22s, and connects the source electrodes 22s and a second wiring pattern 42 to each other.

In the electronic module A132 according to the embodiment 4, the parasitic inductances L1, L2, L3 at the respective portions indicated in the equivalent circuit illustrated in FIG. 4 depend on the shapes of the respective electrically connecting members and the respective wiring patterns illustrated in FIG. 14, and are obtained by simulation. As a result of the simulation performed by taking into account the electrically connecting members and the structures, L1 was 0.54 nH, L2 was 1.63 nH, and L3 was 1.07 nH. With the use of the second electrically connecting member 52 having a plate shape, The value of the inductance in the electronic module A132 according to the embodiment 4 is lower than the value of inductance L3 that is 1.89 nH in the electronic module A130 according to the embodiment by 0.82 nH.

### <Double Pulse Test>

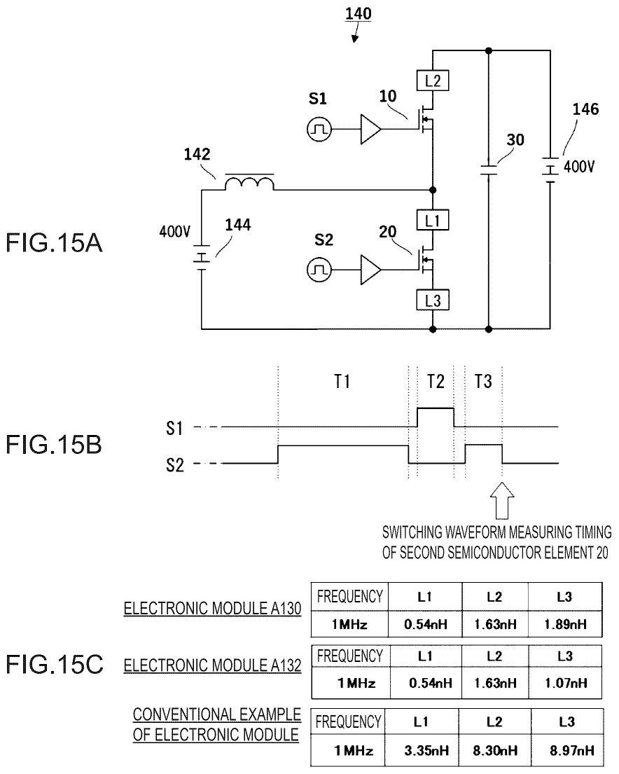

FIG. 15A to FIG. 15C are views for describing a double pulse test. FIG. 15A and FIG. 15B are the same as FIG. 7A and FIG. 7B as described with reference to the present invention (mode 1) and hence, the description is omitted. FIG. 15C is a table in which the parasitic inductances L1, L2, L3 generated in the electronic module A130 according to the embodiment 3, the electronic module A132 according to the embodiment 4, and the conventional-type electronic module are copied.

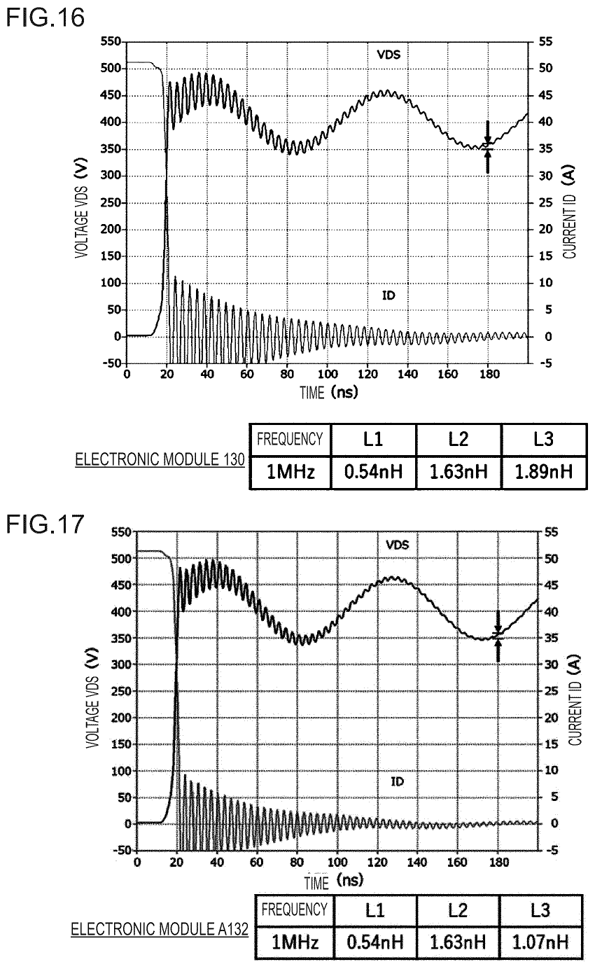

FIG. 16 is a graph where switching waveforms of a drain-source voltage VDS and a drain current ID of a second semiconductor element 20 in the electronic module A130 according to the embodiment 3 are obtained by simulation. In FIG. 16, the inductances L1, L2, L3 (see FIG. 4 described above) in the electronic module A130 according to the embodiment 3 are obtained by simulation, the drain source voltage VDS and the drain current ID of the second semiconductor element 20 that functions as a transistor are simulated by a simulation block 140 of a double pulse test circuit illustrated in FIG. 15A, and switching waveforms are measured at the switching waveform measuring timing. Parasitic inductances L1, L2, L3 of the electronic module 130 obtained by simulation are values describe above, that is, L1 was 0.54 nH, L2 was 1.63 nH, and L3 was 1.89 nH respectively. In the double pulse test circuit illustrated in FIG. 15A, the simulation is performed using these values.

A capacitance of a capacitor 30 mounted in the electronic module A130 is set to 0.01 μF, and a parasitic inductance of a choke coil 142 connected to an outer portion of the electronic module A130 is set to 50 μH.

As illustrated in FIG. 16, in the double pulse test performed using the electronic module A130 according to the embodiment 3, the maximum drain-source voltage is approximately 500 V. Accordingly, in a case where the drain-source absolute maximum rated voltage is 650 V, it is understood that a sufficient margin is secured as the first semiconductor element 10 and the second semiconductor element 20 with respect to a specification rated voltage. Further, a surge voltage is attenuated to approximately 10 Vp-p after a lapse of 180 ns from the switching waveform measuring timing, for example, and hence, it was understood that the electronic module A130 was operationally stable. This was also apparent from the waveform of the drain current ID.

FIG. 17 is a graph where switching waveforms of a drain-source voltage VDS and a drain current ID of a second semiconductor element 20 in the electronic module A132 according to the embodiment 4 are obtained by simulation. In FIG. 17, the inductances L1, L2, L3 (see FIG. 4 described above) in the electronic module A132 according to the embodiment 4 are obtained by simulation, the drain source voltage VDS and the drain current ID of the second semiconductor element 20 that functions as a transistor are simulated by a simulation block 140 of the double pulse test circuit illustrated in FIG. 15A, and switching waveforms are measured at the switching waveform measuring timing. Parasitic inductances L1, L2, L3 of the electronic module 132 obtained by simulation are values described above, that is, L1 was 0.54 nH, L2 was 1.63 nH, and L3 was 1.07 nH respectively. In the double pulse test circuit illustrated in FIG. 15A, the simulation is performed using these values.

In the same manner as the electronic module A130, a capacitance of a capacitor 30 mounted in the electronic module A132 is set to 0.01 μF, and a parasitic inductance of a choke coil 142 connected to an outer portion of the electronic module A132 is set to 50 μH.

As illustrated in FIG. 17, in the double pulse test performed using the electronic module A132 according to the embodiment 4, the maximum drain-source voltage is approximately 500 V that is slightly lower than the corresponding voltage in the electronic module A130. Accordingly, in a case where the drain-electrode absolute maximum rated voltage is 650 V, it is understood that a sufficient margin is secured as the first semiconductor element 10 and the second semiconductor element 20 with respect to a specification rated voltage. Further, a surge voltage is attenuated to approximately 10 Vp-p or below after a lapse of 180 ns from switching waveform measuring timing, for example, and hence, it was understood that the electronic module A130 was operationally stable. This was also apparent from the waveform of the drain current ID.

The comparison example is the same as the comparison example described with reference to the present invention (mode 1). Accordingly, the description of the comparison example is omitted in this embodiment.

As has been described above, according to the present invention (mode 2), the further reduction of the inductance in the electronic module can be realized, and a switching loss, a surge voltage and noises generated in the circuit system that is constituted by using such an electronic module (mode 2) can be reduced. Accordingly, performances such as operation stability and reliability of the circuit system that uses the electronic module can be realized.

Although the embodiment of the present invention (mode 2) has been described heretofore, the present invention (mode 2) is not limited to the above-mentioned embodiment, and is applicable to an electronic module on which a plurality of semiconductor chips are mounted, and various modifications and applications are possible without departing from the gist of the present invention (mode 2).
(1) In the above-mentioned embodiments 3 and 4, the present invention (mode 2) has been described with reference to the electronic module that includes the capacitor. However, the present invention (mode 2) is not limited to such a configuration. For example, an electronic module that does not include a capacitor (for example, an electronic module where a capacitor is eliminated from the electronic module A130 according to the embodiment 3 or the electronic module A132 according to the embodiment 4, and a mold resin is partially removed at a capacitor mounting portion) can be used. In this case, it is possible to constitute an electronic module substantially equal to the electronic module according to the embodiment 3 or 4 by mounting an externally mounting capacitor at a capacitor mounting position.
(2) In the above-mentioned embodiments 3, 4, the present invention (mode 1) has been described by using the half bridge circuit. However, the present invention (mode 1) is not limited to such a configuration. The present invention (mode 1) is applicable to circuits other than a half bridge circuit.
(3) In the above-mentioned embodiments 3 and 4, the present invention (mode 1) is described using a semiconductor element having a rectangle as the first semiconductor element and the second semiconductor element. However, the present invention (mode 1) is not limited to such a semiconductor element. For example, out of the first semiconductor element and the second semiconductor element, both or either one of these semiconductor elements may be formed of a semiconductor element having a square shape.

### Present Invention (Mode 3)

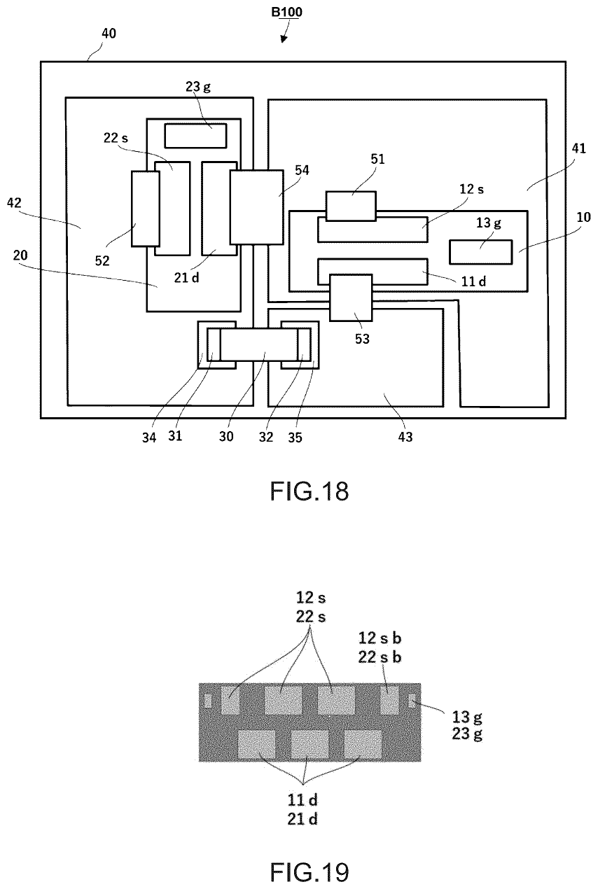

FIG. 18 is a conceptual view of an electronic module B100 according to the present invention (mode 3).

The electronic module B100 according to the present invention (mode 3) is a resin-sealed-type electronic module. As illustrated in FIG. 18, the electronic module B100 according to the present invention (mode 3) includes: a first semiconductor element 10 having a plurality of first electrodes 11d, 12s, 13g; a second semiconductor element 20 having a plurality of second electrodes 21d, 22s, 23g; a capacitor 30; a circuit board 40 having a first wiring pattern 41 on which the first semiconductor element 10 is mounted, a second wiring pattern 42 on which a second semiconductor element 20 is mounted and a third wiring pattern 43, a first electrically connecting member 51, a second electrically connecting member 52, a third electrically connecting member 53, and a fourth electrically connecting member 54.

In the electronic module B100 according to the present invention (mode 3), one portions 12s of the first electrodes 11d, 12s, 13g are connected to the first wiring pattern 41 by the first electrically connecting member 51, and the other portions 21d of the second electrodes 21d, 22s, 23g are connected to the first wiring pattern 41 by the fourth electrically connecting member 54. One portion 22s of the second electrode is connected to the second wiring pattern 42 by the second electrically connecting member 52, and the portion 31 of the capacitor 30 is connected to the second wiring pattern 42, and the other portions 11d of the first electrodes 11d, 12s, 13g are connected to the third wiring pattern 43 and the other portion 32 of the capacitor 30 is connected to the third wiring pattern 43.

In the electronic module B100 according to the present invention (mode 3), the first semiconductor element 10 and the second semiconductor element 20 are disposed in different directions. In this embodiment, “the first semiconductor element 10 and the second semiconductor element 20 are disposed in different directions” means that, with respect to the first semiconductor element 10 and the second semiconductor element 20, the extending direction of one portion 12s of the first electrode, the extending direction of the other portion 13gs of the first electrode, one portion 22s of the second electrode and one portion 12s of the first electrode are directed in different directions. In this embodiment, “extending direction of the electrode” is used as a concept also including “arrangement directions of the individual electrodes” in a case where the electrodes are formed of a plurality of individual electrodes.

In the electronic module B100 according to the present invention (mode 3), the respective semiconductor devices 10, 20, the capacitor 30, the respective wiring patterns 41, 42, 43 and the respective electrically connecting members 51, 52, 53, 54 are disposed as described above and hence, lengths of the respective electrically connecting members 51, 52, 53, 54 can be shortened. Further, the further reduction of inductance in the electronic module B100 that includes portions other than respective electrically connecting members can be realized. Accordingly, the reduction of inductance in the electronic module can be realized and hence, the reduction of a switching loss, a surge voltage and noises in a case where the circuit system is constituted using the electronic module can be realized. Accordingly, performances such as operational stability and reliability of the circuit system that uses the electronic module can be enhanced.

The first semiconductor element 10 corresponds to the first semiconductor element according to the present invention (mode 3). The second semiconductor element 20 corresponds to the second semiconductor element according to the present invention (mode 3). The capacitor 30 corresponds to the capacitor according to the present invention (mode 3). The circuit board 40 corresponds to the circuit board according to the present invention (mode 3). The electrically connecting members 51, 52, 53 and 54 correspond to the electrically connecting members according to the present invention (mode 3). The plurality of first electrodes 11d, 12s, 13g correspond to the plurality of first electrodes according to the present invention (mode 3). The plurality of second electrodes 21d, 22s, 23g correspond to the plurality of second electrodes according to the present invention (mode 3).

The first wiring pattern 41 corresponds to the first wiring pattern according to the present invention (mode 3). The second wiring pattern 42 corresponds to the second wiring pattern according to the present invention (mode 3). The third wiring pattern 43 corresponds to the third wiring pattern according to the present invention (mode 3). One portion 12s of the first electrode corresponds to one portion of the first electrode according to the present invention (mode 3). The other portion 11d of the first electrode corresponds to the other portion of the first electrode according to the present invention (mode 3). One portion 22s of the second electrode corresponds to one portion of the second electrode according to the present invention (mode 3). The other portion 21d of the second electrode corresponds to the other portion of the second electrode according to the present invention (mode 3). One portion 31 of the capacitor corresponds to the one portion of the capacitor according to the present invention (mode 3). The other portion 32 of the capacitor corresponds to the other portion of the capacitor according to the present invention (mode 3).

A demand for increasing a switching frequency from a conventional several hundred kHz to several MHz band region and a demand for also increasing a turn-on/off speed to one digit or more are increasing. Accordingly, the expectation rises for a compound semiconductor that enables a high-speed and a large-current operation. It is necessary to form the first semiconductor element 10 and the second semiconductor element 20 using materials that can cope with such a high speed frequency and a high turn on/off speed.

The first semiconductor element 10 and the second semiconductor element 20 may be formed of a semiconductor using silicon, gallium nitride, silicon carbide or gallium oxide as a material. The first semiconductor element 10 and the second semiconductor element 20 may be semiconductors formed using the same material or different materials respectively.

With such a configuration, the electronic module according to the embodiment 3 is constituted of a semiconductor element having a function selectively suitable for a circuit application (a half bridge circuit, a totem-pole-type power factor improving circuit or the like). Accordingly, in a case where the circuit system is constituted using such an electronic module, a switching loss, a surge voltage and noises can be reduced and hence, operational stability and the reliability of the circuit system that uses the electronic module can be enhanced.

Particularly, in a switching power source system that uses a compound semiconductor capable of being operated at a high speed and with a large current, for example, gallium nitride, silicon carbide or gallium oxide, the electronic module B100 according to the present invention (mode 3) can acquire a particularly outstanding effect with respect to a demand for increasing a switching frequency into a high-speed band of several MHz, a demand for also increasing a turn on/off speed by 1 digit or more, and a demand for reducing a switching loss, a surge voltage and noises at the time of operating the circuit system.

Next, electrodes that are disposed on the surface of the first semiconductor element 10 and the surface of the second semiconductor element 20 are described.

FIG. 19 is a view illustrating an example of a plurality of first electrodes and a plurality of second electrodes disposed on a surface of the first semiconductor element 10 and a surface of the second semiconductor element 20.

The first semiconductor element 10 and the second semiconductor element 20 are each formed of a transistor or a diode. In a case where the first semiconductor element 10 and the second semiconductor element 20 are formed of a transistor, it is preferable that the drain electrodes 11d, 21d be disposed on one side of the same surfaces of the first semiconductor element 10 or the second semiconductor element 20, and the source electrodes 12s, 22s be disposed on the other side of the same surfaces of the first semiconductor element 10 or the second semiconductor element 20. FIG. 19 illustrates the example where the first semiconductor element 10 and the second semiconductor element 20 are formed of a transistor, and the drain electrodes 11d, 21d and the source electrodes 12s, 22s are respectively formed of a plurality of electrodes. For example, in the example illustrated in FIG. 19, the number of drain electrodes 11d, 21d is three and the number of the source electrodes 12s, 22s is three. The gate electrodes 13g, 23g are respectively disposed on a right end portion of the first semiconductor element 10 or the second semiconductor element 20, and the detection-use source electrodes 12sb, 22sb are respectively disposed between the gate electrodes 13g, 23g and the source electrodes 12s, 22s.

In a case where the first semiconductor element 10 and the second semiconductor element 20 are formed of a diode respectively, it is preferable that the cathode electrode be disposed on one side of a same surface of the first semiconductor element 10 or the second semiconductor element 20, and the anode electrode be disposed on the other side of the same surface of the first semiconductor element 10 or the second semiconductor element 20.

With the provision of such lateral configuration, the electronic module is constituted of the semiconductor element having a function selectively suitable for the circuit application (a half bridge circuit, a totem-pole-type power factor improvement circuit, or the like) and hence, a switching loss, a surge voltage and noises that are generated in a case where the circuit system is constituted by using the electronic module can be reduced whereby performances such as the operational stability, the reliability and the like of the circuit system that uses the electronic module can be enhanced.

In the case where the first semiconductor element 10 and the second semiconductor element 20 are formed of a transistor, as illustrated in FIG. 19, the gate electrodes 13g, 23g and the detection-use source electrodes 12sb, 22sb are formed in the vicinity of the source electrodes 12s, 22s. Accordingly, the electronic module B100 of the present invention (mode 3) is preferable with respect to a point that a parasitic inductance of a gate-source wiring loop can be reduced and hence, performances such as the operational stability, the reliability and the like of the circuit system can be enhanced.

As a specific example of the lateral configuration, a case where GaN transistors are formed on a silicon circuit board, a case where GaN transistors are formed on a sapphire circuit board and the like are named.

The drain electrodes 11d, 21d correspond to the drain electrodes in the present invention (mode 3). The source electrodes 12s, 22s correspond to the source electrodes in the present invention (mode 3). The gate electrodes 13g, 23g correspond to the gate electrodes in the present invention (mode 3).

It is preferable that the first semiconductor element 10 and the second semiconductor element 20 be used in the half bridge circuit. With such a configuration, a parasitic inductance of the half bridge circuit can be reduced and hence, it is possible to provide the electronic module B100 having the stable half bridge circuit.

The equivalent circuit of the electronic module B100 is exactly the same as the equivalent circuit described in the present invention (mode 1) and hence, the description of equivalent circuit is omitted (refer to the above-mentioned equivalent circuit 120 illustrated in FIG. 4). The same goes for equivalent circuits of electronic modules B132, B134 described later.

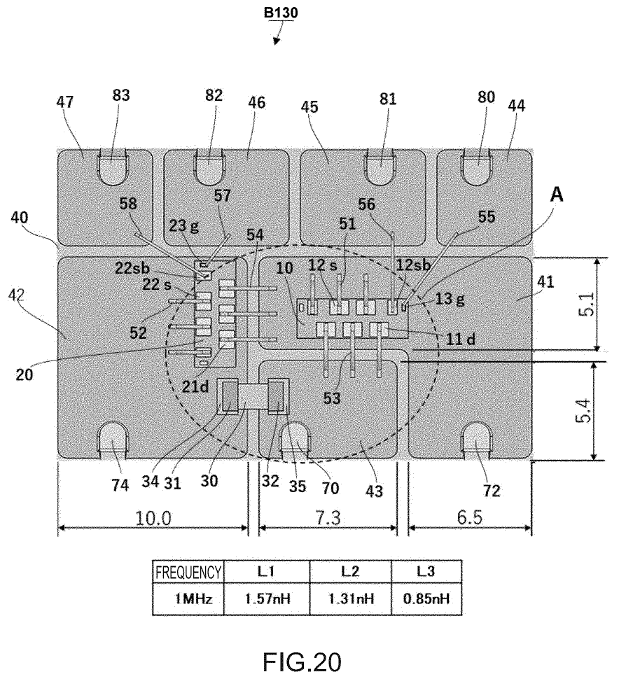

As illustrated in FIG. 20 described later, the second wiring pattern 42 has a first capacitor connecting portion 34 to which one portion 31 of the capacitor is connected, the third wiring pattern 43 has a second capacitor connecting portion 35 to which the other portion 32 of the capacitor is connected. Further, flat surface shapes of the second wiring pattern 42 and the third wiring pattern 43, the position where the second semiconductor element is mounted and the positions where the first capacitor connecting portion 34 and the second capacitor connecting portion 35 are formed are defined such that a wiring route that starts from one portion 22s of the second electrode and reaches the other portion 11d of the first electrode via the second electrically connecting member 52, the second wiring pattern 42, the capacitor 30, the third wiring pattern 43 and the third electrically connecting member 53 becomes the shortest. A resist is formed around the first capacitor connecting portion 34 and the second capacitor connecting portion 35 respectively.

At the portions surrounded by these resists, the portion 31 of the capacitor and the first capacitor connecting portion 34 are connected to each other, and the other portion 32 of the capacitor and the second capacitor connecting portion 35 are connected to each other. By adopting such a configuration, the capacitor 30 is connected to the first semiconductor element 10 and the second semiconductor element 20 at positions closest to the first semiconductor element 10 and the second semiconductor element 20. Accordingly, in a case where the electronic module B130 is applied to the circuit system having a bridge structure such as a half bridge circuit, for example, the electronic module B130 exhibits a snubber effect at maximum and hence, the electronic module B130 can acquire an outstanding effect in reducing a switching loss, a surge voltage, and noises.

### Embodiment 5

FIG. 20 is a view illustrating an electronic module B130 according to the embodiment 5. The embodiment 5 is a specific embodiment of the equivalent circuit 120 illustrated in FIG. 4 described above.

As illustrated in FIG. 20, the electronic module B130 according to the embodiment 5 includes: a first semiconductor element 10 having a plurality of first electrodes 11d, 12s, 13g; a second semiconductor element 20 having a plurality of second electrodes 21d, 22s, 23g; a capacitor 30; a circuit board 40 having a first wiring pattern 41 on which the first semiconductor element 10 is mounted, a second wiring pattern 42 on which a second semiconductor element 20 is mounted and a third wiring pattern 43, a first electrically connecting member 51, a second electrically connecting member 52, a third electrically connecting member 53, and a fourth electrically connecting member 54. As the circuit board 40, a DCB circuit board that is formed by directly joining a copper circuit board to a ceramic substrate, for example is used.

In the electronic module B130 according to the embodiment 5, one portion 12s of the first electrode is connected to the first wiring pattern 41 by the first electrically connecting member 51, and the other portion 21d of the second electrode is connected to the first wiring pattern 41 by the fourth electrically connecting member 54. One portion 22s of the second electrode is connected to the second wiring pattern 42 by the second electrically connecting member 52, and one portion 31 of the capacitor 30 is connected to the second wiring pattern 42, and the other portion 11d of the first electrode is connected to the third wiring pattern 43 by the third electrically connecting member 53 and the other portion 32 of the capacitor 30 is connected to the third wiring pattern 43.

In the electronic module B130 according to the embodiment 5, the first semiconductor element 10 and the second semiconductor element 20 are disposed in different directions. In this embodiment, “the first semiconductor element 10 and the second semiconductor element 20 are disposed in different directions” means, as described above, that “the first semiconductor element 10 and the second semiconductor element 20 are disposed such that the extending direction of one portion 12s of the first electrode, the extending direction of the other portion 11d of the first electrode, one portion 22s of the second electrode and the other portion 11d of the second electrode are directed in different directions. In this embodiment, “extending direction of the electrode” is used as a concept also including “arrangement directions of the individual electrodes” in a case where the electrode is formed of a plurality of individual electrodes.

By adopting the above-mentioned configuration, lengths of the first electrically connecting member 51, the second electrically connecting member 52, the third electrically connecting member 53 and the fourth electrically connecting member 54 can be shortened. In addition, the further reduction of inductance in the electronic module 130 that includes portions other than the first electrically connecting member 51, the second electrically connecting member 52, the third electrically connecting portion, and the fourth electrically connecting member 54 can be realized. Further, in a case where the circuit system is constituted using the electronic module B130, the reduction of a switching loss, a surge voltage and noises can be realized.

The first wiring pattern 41 has a shape based on the letter L, and the second wiring pattern 42 and the third wiring pattern 43 have a shape based on a rectangle. The third wiring pattern 43 is disposed in a state where three sides are surrounded by the first wiring pattern 41 and the second wiring pattern 42. With such a configuration, the second wiring pattern 42 and the third wiring pattern 43 can be disposed adjacently to each other with respect to the first wiring pattern 41. Further, the first wiring pattern 41 has a shape based on the letter L and hence, the first wiring pattern 41 can be directly connected to an output terminal 72 of the electronic module B130.

With reference to a main part A surrounded by a broken line in FIG. 20, the first semiconductor element 10 is disposed in a region of the first wiring pattern 41 disposed adjacently to the second wiring pattern 42 and the third wiring pattern 43, and the other portion 11d of the first electrode is disposed adjacently to and parallel to the third wiring pattern 43. The second semiconductor element 20 is disposed in a region of the second wiring pattern 42 adjacently to the first wiring pattern 41, and the other portion 21d of the second electrode is disposed adjacently to and parallel to the first wiring pattern 41. The capacitor 30 is disposed in a region disposed close to the second semiconductor element 20 in a state where the capacitor 30 connects the second wiring pattern 42 and the third wiring pattern 43.

In the first semiconductor element 10, the other portion 11d of the first electrode is connected to the third wiring pattern 43 by the electrically connecting member 53 and hence, the first semiconductor element 10 is disposed close to the third wiring pattern 43 whereby the third electrically connecting member 53 can be shortened, and a parasitic inductance can be reduced. Further, in the first semiconductor element 10, one portion 12s of the first electrode is connected to the first wiring pattern 41 by the first electrically connecting member 51.

Further, the first wiring pattern 41 is connected to the other portion 21d of the second electrode via the fourth electrically connecting member 54 and hence, by arranging the first semiconductor element 10 at the position close to the second wiring pattern 42, a distance between one portion 12s of the first electrode and the other portion 21d of the second electrode can be made short and hence, a parasitic inductance can be reduced. In this embodiment, “close to” also includes “within a close distance by being disposed adjacently to each other” and “adjacently to” means “a state being disposed next to”.

A power source terminal 70, an output terminal 72 and a ground terminal 74 are disposed at one side of the electronic module B130, and a first control-use signal terminal 80, a first detection-use signal terminal 81, a second control-use signal terminal 82 and a second detection-use signal terminal 83 are disposed on the other side of the electronic module B130.

The first control-use signal terminal 80 is connected to the fourth wiring pattern 44 formed on the surface of the circuit board 40, and the first detection-use signal terminal 81 is connected to the fifth wiring pattern 45 formed on the surface of the circuit board 40 and the second control-use signal terminal 82 is connected to the sixth wiring pattern 46 formed on the surface of the circuit board 40, and the second detection-use signal terminal 83 is connected to the seventh wiring pattern 47 formed on the surface of the circuit board 40.

The first gate electrode 13g is connected to the fourth wiring pattern 44 by the fifth electrically connecting member 55, and the first-detection-use source electrode 12sb is connected to the fifth wiring pattern 45 by the sixth electrically connecting member 56. The second gate electrode 23g is connected to the sixth wiring pattern 46 by the seventh electrically connecting member 57, and the second detection-use source electrode 22sb is connected to the seventh wiring pattern 47 by the eighth electrically connecting member 58.

In the electronic module B130 according to the embodiment 5, the parasitic inductances L1, L2, L3 at the respective portions indicated in the equivalent circuit illustrated in FIG. 4 described above depend on the electrically connecting members and the structures of the wiring patterns illustrated in FIG. 20, and are obtained by simulation.

As illustrated in FIG. 20, the shape of the first wiring pattern 41 is a shape based on the letter L, a width of a mounting region of the first semiconductor element 10 is 5.1 mm and the width of a connecting region of the output terminal 72 is 6.5 mm. The shape of the second wiring pattern 42 is a shape based on a rectangle, and a width of a connecting region of the ground terminal 74 is 10.0 mm. The third wiring pattern 43 has a shape based on a rectangle, and has a size where a lateral length is 7.3 mm and the longitudinal length is 5.4 mm. Further, a wire diameter is 200 μm.

As a result of the simulation performed by taking into account these wiring patterns, the electrically connecting members and the like, L1 was 1.57 nH, L2 was 1.31 nH, and L3 was 0.85 nH. It is understood that these values are lower by one digit or more compared to the above-mentioned prior art (patent literatures 3, 4, 5 and the like).

It is preferable that the first electrically connecting member 51, the second electrically connecting member 52, the third electrically connecting member 53 and the fourth electrically connecting member 54 are each formed of electrically connecting member having a line-shape or a plate-shape. With such a configuration, electrically connecting members each having a small parasitic inductance are applicable and hence, the reduction of parasitic inductance can be realized. In the embodiment 5, the case is described where the electrically connecting members are each formed of a line-shaped member. Next, in an embodiment 6. a case is described where some electrically connecting members are formed of a line-shaped electrically connecting member and the other electrically connecting members are formed of a plate-shaped electrically connecting member.

### Embodiment 6

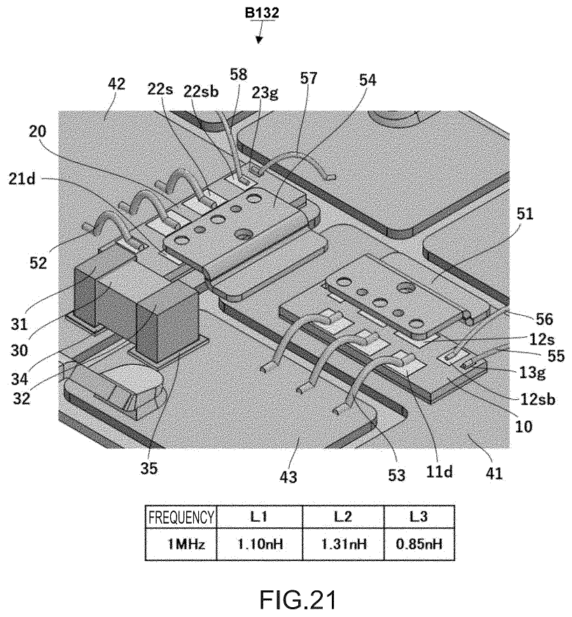

FIG. 21 is a perspective view of an electronic module B132 according to the embodiment 6 illustrating a main part in an enlarged manner. FIG. 21 is a view illustrating a region that corresponds to the region A surrounded by a broken line in FIG. 20 in an enlarged manner. The electronic module B132 according to the embodiment 6, as illustrated in FIG. 21, differs from the electronic module B130 according to the embodiment 5 with respect to a point that a first electrically connecting member 51 and a fourth electrically connecting member 54 are formed of a plate-shaped electrically connecting member. Other constitutional elements are same as the corresponding constitutional elements of the electronic module B130 according to the embodiment 5. The first electrically connecting member 51 having a plate-shape has an area that covers three source electrodes 12s, and connects source electrodes 12s and the first wiring pattern 41 to each other. The fourth electrically connecting member 54 having a plate-shape has an area that covers three drain electrodes 21d, and connects the drain electrodes 21d and the first wiring pattern 41 to each other.

In the electronic module B132 according to the embodiment 6, the parasitic inductances L1, L2, L3 at the respective portions indicated in the equivalent circuit illustrated in FIG. 4 described above depend on the shapes of the electrically connecting members and the wiring patterns illustrated in FIG. 21, and are obtained by simulation. As a result of the simulation performed by taking into account the electrically connecting members and the structures, L1 was 1.10 nH, L2 was 1.31 nH, and L3 was 0.85 nH. With the use of the second electrically connecting member 52 and the third electrically connecting member 53 having a plate-shape, the value of the parasitic inductance L1 in the electronic module B132 according to the embodiment 6 is lower than the parasitic inductance L1 of the 1.57 nH indicated in the electronic module B130 according to the embodiment 5 by 0.47 nH.

### Embodiment 7

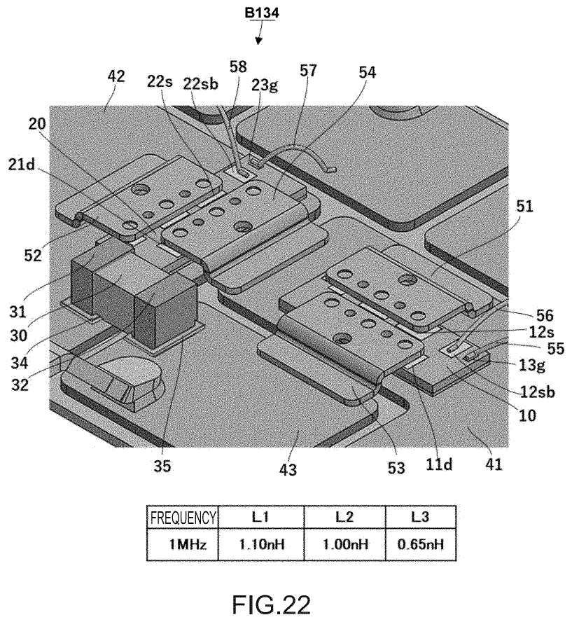

FIG. 22 is a perspective view of an electronic module B134 according to an embodiment 7 illustrating a main part in an enlarged manner. FIG. 22 is a view illustrating a region that corresponds to the region A surrounded by a broken line in FIG. 20 in an enlarged manner. The electronic module B134 according to the embodiment 7, as illustrated in FIG. 22, differs from the electronic module B130 according to the embodiment 5 with respect to a point that a first electrically connecting member 51 to a fourth electrically connecting member 54 are all formed of an electrically connecting member having a plate-shape respectively. Other constitutional elements are same as the corresponding constitutional elements of the electronic module B130 according to the embodiment 5.

The third electrically connecting member 53 having a plate-shape has an area that covers three drain electrodes 11d, and connects the drain electrodes 11d and the third wiring pattern 43 to each other. The first electrically connecting member 51 having a plate-shape has an area that covers three source electrodes 12s, and connects the source electrodes 12s and the first wiring pattern 41 to each other. The fourth electrically connecting member 54 having a plate-shape has an area that covers three drain electrodes 21d, and connects the drain electrodes 21d and the first wiring pattern 41 to each other. The second electrically connecting member 52 having a plate-shape has an area that covers three source electrodes 22s, and connects the source electrodes 22s and the second wiring pattern 42 to each other.

In the electronic module B134 according to the embodiment 7, the parasitic inductances L1, L2, L3 at the respective portions indicated in the equivalent circuit illustrated in FIG. 4 described above depend on the shapes of the electrically connecting members and the wiring patterns illustrated in FIG. 22, and are obtained by simulation. As a result of the simulation performed by taking into account the electrically connecting members and the wiring patterns, L1 was 1.10 nH, L2 was 1.00 nH, and L3 was 0.65 nH. By forming all of the first electrically connecting member 51 to the fourth electrically connecting member 54 using an electrically connecting member having a plate-shape, in the electronic module B134 according to the embodiment 5, the value of the parasitic inductance L1 is set low by 0.47 nH, the value of the parasitic inductance L2 is set low by 0.31 nH, and the value of the parasitic inductance L3 is set low by 0.20 nH compared to the electronic module B130 according to the embodiment 5.

### <Double Pulse Test>

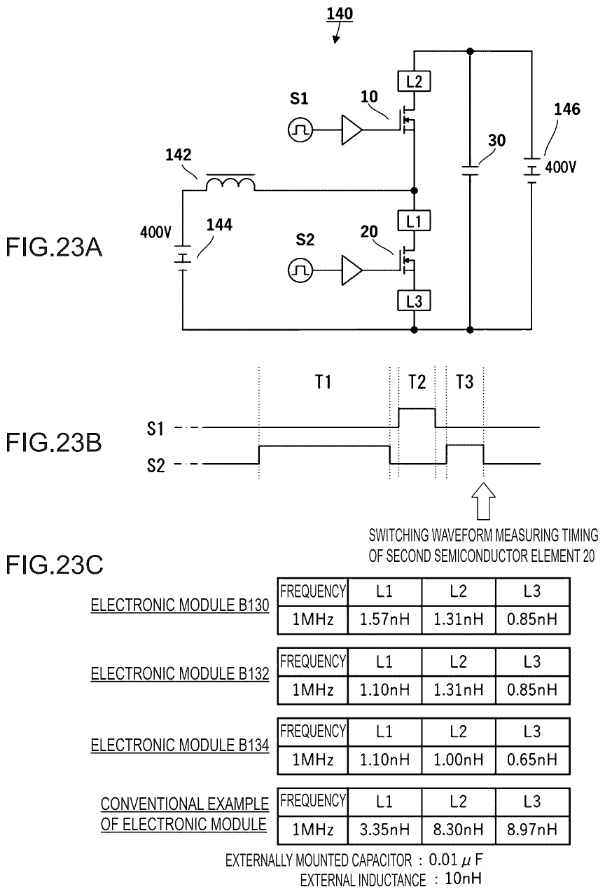

FIG. 23A to FIG. 23C are views for describing a double pulse test. FIG. 23A and FIG. 23B are the same as FIG. 7A and FIG. 7B as described with reference to the present invention (mode 1) and hence, the description is omitted. FIG. 23C is a table in which the parasitic inductances L1, L2, L3 generated in the electronic module B130 according to the embodiment 5, the electronic module B132 according to the embodiment 6, the electronic module B134 according to the embodiment 7 and the conventional-type electronic module are copied.

With respect to the parasitic inductances L1, L2, L3 in the electronic module B130, by performing simulation, L1 of 1.57 nH, L2 of 1.31 nH and L3 of 0.85 nH were obtained. With respect to the parasitic inductances L1, L2, L3 in the electronic module B132, by performing simulation, L1 of 1.10 nH, L2 of 1.31 nH, and L3 of 0.85 nH were obtained. With respect to the parasitic inductances L1, L2, L3 in the electronic module B134, by performing simulation, L1 of 1.10 nH, L2 of 1.00 nH, and L3 of 0.65 nH were obtained. Further, with respect to the parasitic inductances of the conventional-type electronic module described above, L1 of 3.35 nH, L2 of 8.30 nH, and L3 of 8.97 nH were obtained.

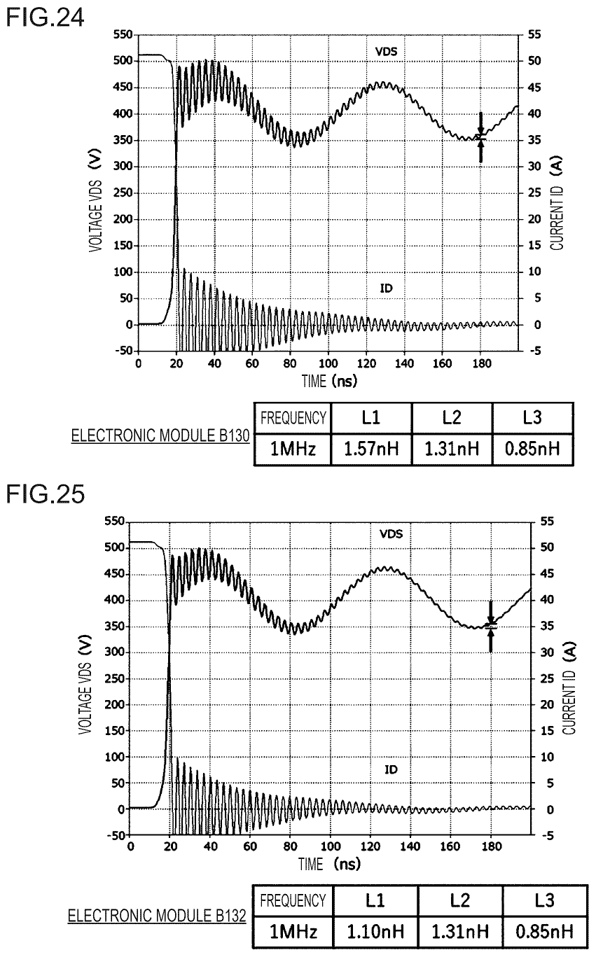

FIG. 24 is a graph where switching waveforms of a drain-source voltage VDS and a drain current ID of a second semiconductor element 20 in the electronic module B130 according to the embodiment 5 are obtained by simulation. In FIG. 24, the inductances L1, L2, L3 (see FIG. 4 described above) in the electronic module B130 according to the embodiment 5 are obtained by simulation, the drain source voltage VDS and the drain current ID of the second semiconductor element 20 that functions as a transistor are simulated by a simulation block 140 of the double pulse test circuit illustrated in FIG. 23A, and switching waveforms are measured at the switching waveform measuring timing. Parasitic inductances L1, L2, L3 of the electronic module B130 obtained by simulation are values described above, that is, L1 was 1.57 nH, L2 was 1.31 nH, and L3 was 0.85 nH respectively. In the double pulse test circuit illustrated in FIG. 23A, the simulation is performed using these values.

A capacitance of a capacitor 30 mounted in the electronic module B130 is set to 0.01 μF, and a parasitic inductance of a choke coil 142 connected to an outer portion of the electronic module B130 is set to 50 μH.

As illustrated in FIG. 24, in the double pulse test performed using the electronic module B130 according to the embodiment 5, the maximum drain-source voltage is approximately 500 V. Accordingly, in a case where the drain-electrode absolute maximum rated voltage is 650 V, it is understood that a sufficient margin is secured as the first semiconductor element 10 and the second semiconductor element 20 with respect to a specification rated voltage. Further, a surge voltage is attenuated to approximately 10 Vp-p or below after a lapse of 180 ns from switching waveform measuring timing, for example, and hence, it was understood that the electronic module B130 was operationally stable. This was also apparent from the waveform of the drain current ID.

FIG. 25 is a graph where switching waveforms of a drain-source voltage VDS and a drain current ID of the second semiconductor element 20 in the electronic module B132 according to the embodiment 6 were obtained by simulation. In FIG. 25, the inductances L1, L2, L3 (see FIG. 4 described above) in the electronic module B132 according to the embodiment 6 were obtained by simulation, the drain source voltage VDS and the drain current ID of the second semiconductor element 20 that functions as a transistor were simulated by a simulation block 140 of the double pulse test circuit illustrated in FIG. 23A, and switching waveforms were measured at the switching waveform measuring timing. Parasitic inductances L1, L2, L3 of the electronic module B132 obtained by simulation are values described above, that is, L1 was 1.10 nH, L2 was 1.31 nH, and L3 was 0.85 nH respectively. In the double pulse test circuit illustrated in FIG. 23A, the simulation was performed using these values.

A capacitance of a capacitor 30 mounted in the electronic module B132 is set to 0.01 μF, and a parasitic inductance of a choke coil 142 connected to an outer portion of the electronic module B132 is set to 50 μH.

As illustrated in FIG. 25, in the double pulse test that was performed using the electronic module B132 according to the embodiment 6, the maximum drain-source voltage was approximately 500 V or below that is slightly lower than the maximum drain-source voltage in the electronic module B130. Accordingly, in a case where the drain-source absolute maximum rated voltage was 650 V, it is understood that a sufficient margin was secured as the first semiconductor element 10 and the second semiconductor element 20 with respect to a specification rated voltage. Further, a surge voltage was attenuated to approximately 10 Vp-p or below after a lapse of 180 ns from switching waveform measuring timing, for example, and hence, it was understood that the electronic module B132 was operationally stable. This was also apparent from the waveform of the drain current ID.

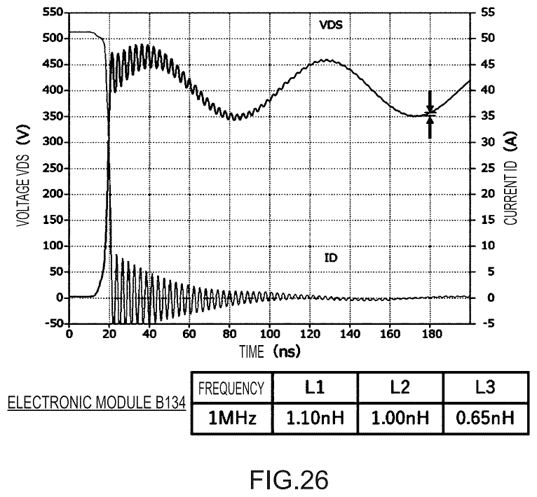

FIG. 26 is a graph where switching waveforms of a drain-source voltage VDS and a drain current ID of the second semiconductor element 20 in the electronic module B134 according to the embodiment 7 were obtained by simulation. In FIG. 26, the inductances L1, L2, L3 (see FIG. 4 described above) in the electronic module B134 according to the embodiment 7 were obtained by simulation, the drain source voltage VDS and the drain current ID of the second semiconductor element 20 that functions as a transistor were simulated by a simulation block 140 of the double pulse test circuit illustrated in FIG. 23A, and switching waveforms were measured at the switching waveform measuring timing. Parasitic inductances L1, L2, L3 of the electronic module B134 obtained by simulation were values described above, that is, L1 was 1.10 nH, L2 was 1.00 nH, and L3 was 0.65 nH respectively. In the double pulse test circuit illustrated in FIG. 23A, the simulation was performed using these values.

A capacitance of a capacitor 30 mounted in the electronic module B134 was set to 0.01 μF, and a parasitic inductance of a choke coil 142 connected to an outer portion of the electronic module B134 was set to 50 μH.

As illustrated in FIG. 26, in the double pulse test performed using the electronic module B134 according to the embodiment 7, the maximum drain-source voltage was approximately 500 V or below that is slightly lower than the maximum drain-source voltage in the electronic module B130. Accordingly, in a case where the drain-source absolute maximum rated voltage was 650 V, it is understood that a sufficient margin was secured as the first semiconductor element 10 and the second semiconductor element 20 with respect to a specification rated voltage. Further, a surge voltage was attenuated to approximately 10 Vp-p or below after a lapse of 180 ns from switching waveform measuring timing, for example, and hence, it was understood that the electronic module B134 was operationally stable. This was also apparent from the waveform of the drain current ID.

The comparison example is the same as the comparison example described with reference to the present invention (mode 1). Accordingly, the description of the comparison example is omitted in this embodiment.

As has been described above, according to the present invention (mode 3), the further reduction of the inductance in the electronic module can be realized, and a switching loss, a surge voltage and noises generated in the circuit system that is constituted by using such an electronic module of the present invention (mode 3) can be reduced. Accordingly, performances such as operational stability and reliability of the circuit system that uses the electronic module can be enhanced.

Although the embodiment of the present invention (mode 3) has been described heretofore, the present invention (mode 3) is not limited to the above-mentioned embodiment, and is applicable to an electronic module on which a plurality of semiconductor chips are mounted, and various modifications and applications are possible without departing from the gist of the present invention (mode 3).
(1) In the above-mentioned respective embodiments, the present invention has been described with reference to the electronic module that includes the capacitor. However, the present invention (mode 3) is not limited to such a configuration. For example, it is also possible to use an electronic module that does not include a capacitor (for example, an electronic module where a capacitor is eliminated from the electronic module B130 according to the embodiment 5, and a mold resin is partially removed at a capacitor mounting portion). In this case, it is possible to constitute an electronic module substantially equal to the electronic module according to the embodiment 1 by mounting an externally mounting capacitor at a capacitor mounting position.
(2) In the above-mentioned respective embodiments, the present invention (mode 3) has been made by using the half bridge circuit. However, the present invention (mode 3) is not limited to such a configuration. The present invention (mode 3) is applicable to circuits other than a half bridge circuit.
(3) In the above-mentioned respective embodiments, the present invention (mode 3) is described using a semiconductor element having a rectangle as the first semiconductor element and the second semiconductor element. However, the present invention (mode 3) is not limited to such a semiconductor element. For example, out of the first semiconductor element and the second semiconductor element, both or either one of these semiconductor elements a be formed of semiconductor element having a square shape.

### Present Invention (Mode 4)

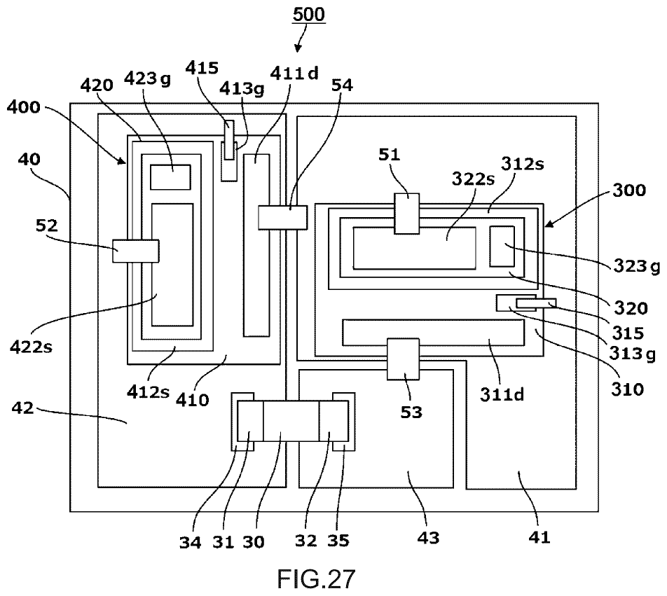

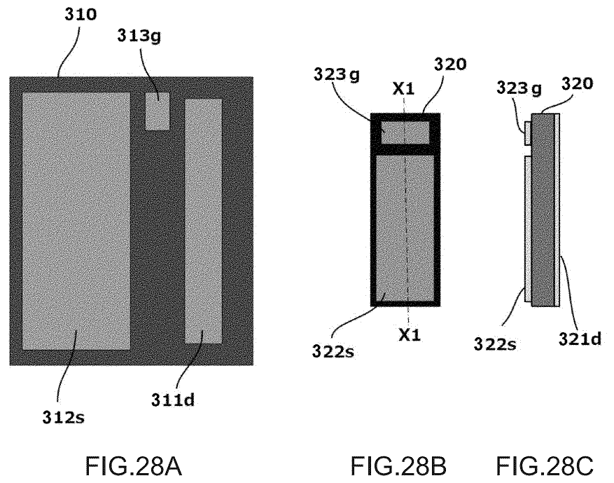

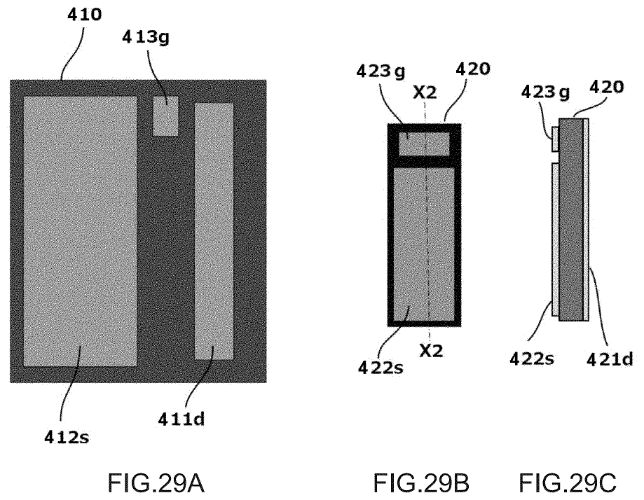

FIG. 27 is a conceptual view of an electronic module 500 according to the present invention (mode 4). FIG. 28A to FIG. 28C are views illustrating the electrode structure of a first switch element 310 and a second switch element 320. FIG. 28A is a plan view of the first switch element 310, FIG. 2(B) is a plan view of the second switch element 320, and FIG. 28C is a cross-sectional view of the second switch element 320 taken along a line X1-X1 in FIG. 28B. FIG. 29A to FIG. 29C are views illustrating the electrode structure of a third switch element 410 and a fourth switch element 420. FIG. 29A is a plan view of the third switch element 410, FIG. 29B is a plan view of the fourth switch element 420, and FIG. 29C is a cross-sectional view of the fourth switch element 420 taken along a line X2-X2 in FIG. 29B.

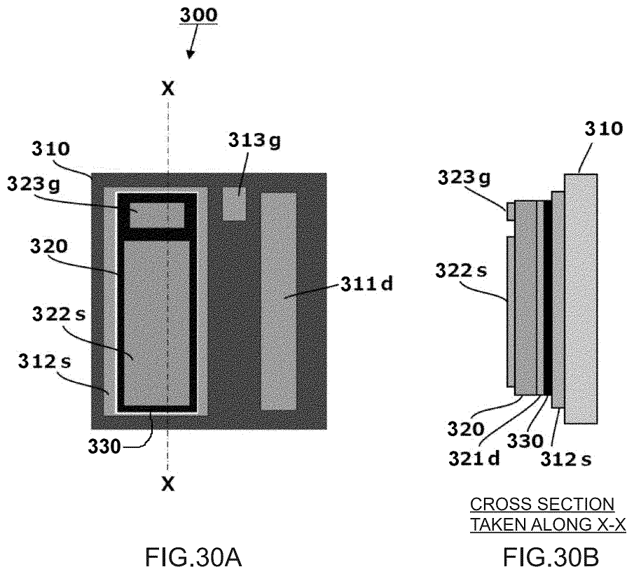

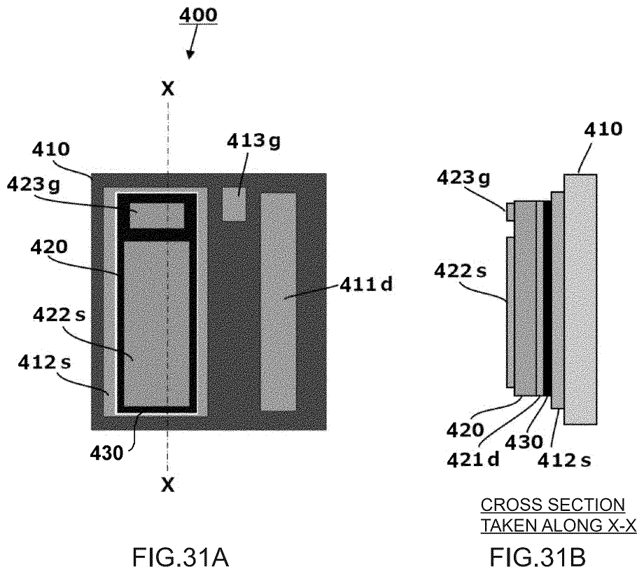

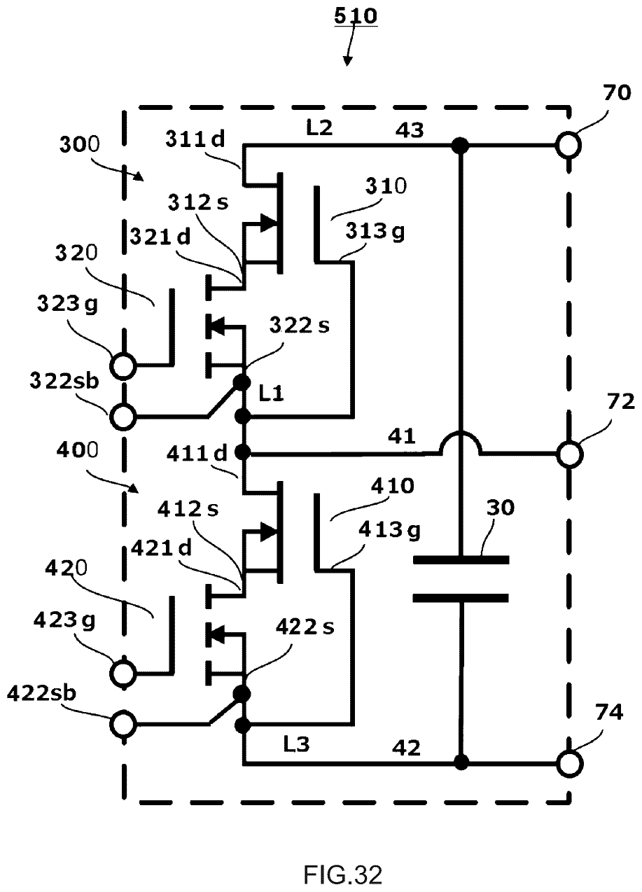

FIG. 30A and FIG. 30B are views for describing a first cascode switch element 300. FIG. 30A is a plan view of the first cascode switch element 300, and FIG. 30B is a cross-sectional view of the first cascode switch element 300. FIG. 31A and FIG. 31B are views for describing a second cascode switch element 400. FIG. 31A is a plan view of the second cascode switch element 400, and FIG. 31B is a cross-sectional view of the second cascode switch element 400. FIG. 32 is a view illustrating an equivalent circuit 510 of the electronic module 500. With respect to the first cascode switch element 300 illustrated in FIG. 30A and FIG. 30B, a first gate electrode 313g and a second source electrode 322s are in a non-connection state and hence, the first cascode switch element 300 is not called as a cascode switch element originally. However, the term “the first cascode switch element” is used in this specification. Further, with respect to the second cascode switch element 400 illustrated in FIG. 31A and FIG. 31B, a third gate electrode 413g and a fourth source electrode 422s are in a non-connection state and hence, the second cascode switch element 400 is not called as a cascode switch element originally. However, in this specification, the term “the second cascode switch element” is used.

The electronic module 500 according to the present invention (mode 4) is the resin-sealed-type electronic module. As illustrated in FIG. 1A and FIG. 1B, the electronic module 500 includes: the first cascode switch element 300, the second cascode switch element 400, a capacitor 30, and a circuit board having a first wiring pattern 41 on which the first cascode switch element 300 is mounted, a second wiring pattern 42 on which the second cascode switch element 400 is mounted, and a third wiring pattern 43.

In the electronic module 500 according to the present invention (mode 4), the first cascode switch element 300 is constituted of: first switch element 310 having a first drain electrode 311d, a first source electrode 312s and a first gate electrode 313g and formed of a normally-on-type semiconductor element; and a second switch element 320 having a second drain electrode 321d (see FIG. 28C), a second source electrode 322s and a second gate electrode 323g and formed of a normally-off type semiconductor element. The second switch element 320 is stacked on the first switch element 310 in a state where the second drain electrode 321d and the first source electrode 312s are jointed to each other by a conductive joining material 330 (see FIG. 30A and FIG. 30B). The first gate electrode 313g and the second source electrode 322s are connected to each other. The connection between the first gate electrode 313g and the second source electrode 322s is performed, as described in FIG. 27, the first gate electrode 313g and the second source electrode 322s are connected to each other via a first cascode electrically connecting member 315, the first wiring pattern 41 and the first electrically connecting member 51.

In the electronic module 500 according to the present invention (mode 4), the second cascode switch element 400 is constituted of: a third switch element 410 having a third source electrode 412s and a third gate electrode 413g and formed of a normally-on-type semiconductor element; and a fourth drain switch element 420 having a fourth drain electrode 321d (see FIG. 29C), a fourth source electrode 422s and a fourth gate electrode 423g and formed of a normally-off type semiconductor element. The fourth switch element 420 is stacked on the third switch element 410 in a state where the fourth drain electrode 421d and the third source electrode 412s are jointed to each other by a conductive joining material 430 (see FIG. 31A and FIG. 31B). The third gate electrode 413g and the fourth source electrode 422s are connected to each other. The connection between the third gate electrode 413g and the fourth source electrode 422s is performed, as illustrated in FIG. 27, via a second cascode electrically connecting member 415, the second wiring pattern 42 and the second electrically connecting member 52.

In the electronic module 500 according to the present invention (mode 4), as illustrated in FIG. 27, the second source electrode 322s is connected to the first wiring pattern 41 by the first electrically connecting member 51, and the third drain electrode 411d is connected to the first wiring pattern by the fourth electrically connecting member 54. The fourth source electrode 422s is connected to the second wiring pattern 42 by the second electrically connecting member 52, and one portion 31 of the capacitor 30 is connected to the second wiring pattern 42. The first drain electrode 311d is connected to the third wiring pattern 43 by the third electrically connecting member 53 and the other portion 32 of the capacitor 30 is connected to the third wiring pattern 43.

In the electronic module 500 according to the present invention (mode 4), as illustrated in FIG. 27, the first cascode switch element 300 and the second cascode switch element 400 are disposed in different directions. In this embodiment, “the first cascode switch element 300 and the second cascode switch element 400 are disposed in different directions” means that “the first cascode switch element 300 and the second cascode switch element 400 are disposed such that the extending direction of the first drain electrode 311d, the extending direction of the first source electrode 312s, the extending direction of the second drain electrode 321d, the extending direction of the second source electrode 322s, the extending direction of the third drain electrode 411d, the extending direction of the third source electrode 412s, and the extending direction of the fourth drain electrode 421d, and the extending direction of the fourth source electrode 422s are disposed at different directions from each other. In this embodiment, in a case where the electrode is constituted of a plurality of individual electrodes, “extending direction of the electrode” is used as a concept that includes “arrangement directions of individual electrodes”. As an example where the first cascode switch element 300 and the second cascode switch element 400 are disposed in different directions, a perpendicular direction is considered.

The electronic module 500 according to the present invention (mode 4) is an electronic module that includes: the first cascode switch element 300 constituted of the first switch element 310 that is formed of a normally-on-type semiconductor element and a second switch element 320 that is formed of a normally-off-type semiconductor element; and the second cascode switch element 400 constituted of the third switch element 410 that is formed of a normally-on-type semiconductor element and a fourth switch element 420 that is formed of a normally-off-type semiconductor element. With such configuration, according to the electronic module 300 of the present invention (mode 4), by using a normally-on-type power semiconductor element (the first switch element 310, the third switch element 410) formed of a wide band gap semiconductor element (for example, GaN) capable of performing high frequency driving at a high withstand voltage together with the normally-off-type power semiconductor element (the second switch element 320, the fourth switch element 420) formed of a conventional power semiconductor element (for example, silicon) in cascode connection thus forming the normally-off-type switching element and hence, the switching frequency can be increased to several MHz order and, at the same time, a turn on/off speed be increased than that of a conventional can electronic module by one digit and hence, high-frequency driving of the power source system can be realized.

Further, according to the electronic module 500 of the present invention, the respective switch elements 310, 320, 410, 420, the capacitor 30, the respective wiring patterns 41, 42, 43 and the respective electrically connecting members 51, 52, 53, 54 are arranged as described above (particularly, the first cascode switch element 300 and the second cascode switch element 400 are disposed in different directions) and hence, the lengths of the respective electrically connecting members 51, 52, 53, 54 can be shortened. Further, the further reduction of inductance in the electronic module 500 including portions other than the respective electrically connecting members 51, 52, 53 can be realized. Accordingly, the further reduction of inductance of the electronic module 500 can be realized and hence, in a case where the circuit system is constituted using the electronic module 500, the reduction of a switching loss, a surge voltage and noises can be realized. Accordingly, for example, by using a wideband gap semiconductor element (for example, GaN) as the first switch element 310 and the third switch element 410 as described above, the switching frequency can be increased to a high speed of several MHz order and hence, a turn on/off speed can be increased to a high speed by one digit or more than that of a conventional electronic module. Accordingly, performances such as operational stability and reliability of the circuit system that uses the electronic module can be enhanced.

As a result, even in a case where the electronic module 500 of the present invention (mode 4) is a high-frequency-driven electronic module that uses a wideband gap semiconductor element, it is possible to provide an electronic module that satisfies demands from a viewpoint of operational stability and reliability.

In the electronic module 500 of the present invention (mode 4), the first switch element 310 includes: as illustrated in FIG. 28A, a first drain electrode 311d, a first source electrode 312s and a first gate electrode 313g on one surface of the electronic module 500. The first drain electrode 311d and the first source electrode 312s are disposed parallel to each other. Further, the second switch element 320 includes, as illustrated in FIG. 28B and FIG. 28C, the second gate electrode 323g and the second source electrode 322s on one surface, and the second drain electrode 321d on the other surface. Further, the third switch element 410 includes, as illustrated in FIG. 29A, the third drain electrode 411d, the third source electrode 412s and the third gate electrode 413g on one surface. The third drain electrode 411d and the third source electrode 412s are disposed parallel to each other. Further, the fourth switch element 420 includes, as illustrated in FIG. 29B and FIG. 29C, the fourth gate electrode 423gg and the fourth source electrode 422s on one surface thereof, and include the fourth drain electrode 421d on the other surface thereof.

In this manner, by allowing the first switch element 310 to have the lateral configuration and the second switch element 320 to have the vertical configuration, by simply stacking the second switch element 320 on the first switch element 310 via the conductive joining material 330, the first source electrode 312s and the second drain electrode 321d can be electrically connected to each other (see FIG. 30A and FIG. 30B). Further, by allowing the third switch element 410 to have the lateral configuration and the fourth switch element 420 to have the vertical configuration, by simply stacking the fourth switch element 420 on the third switch element 410 via the conductive joining material 430, the third source electrode 412s and the fourth drain electrode 421d can be electrically connected to each other (see FIG. 31A and FIG. 31B). With such a configuration, the connection becomes easy and the electrically connecting paths can be shortened and hence, a cascode switch element having a small parasitic inductance can be formed.

In the electronic module 500 of the present invention (mode 4), the electrode arrangement illustrated in FIG. 28A to FIG. 29C are provided as an exemplifying purpose. For example, the electrode arrangement of the first switch element 310 and the third switch element 410 can be changed without departing from the gist of the present invention, and the both side arrangement may be adopted where the first gate electrode 313g and the third gate electrode 413g are disposed on a back surface. As a specific example of the lateral configuration of the normally-on-type first switch element 310 and the third switch element 410, a case where a GaN transistor is formed on a silicon substrate, a case where a GaN transistor is formed on a sapphire substrate and the like are named. Further, as a specific example of the normally-off-type second switch element 320 and fourth switch element 420, an LV-MOSFET and the like are named.

In the first cascode switch element 300, the connection between the first gate electrode 313g and the second source electrode 322s is performed, as illustrated in FIG. 27, both members are connected by way of the first cascode electrically connecting member 315, the first wiring pattern 41 and the first electrically connecting member 51. With such a configuration, the cascode connection is configured. Further, in the second cascode switch element 400, the connection between the third gate electrode 413g and the fourth source electrode 422s is performed, as illustrated in FIG. 27, by connecting both members via a second cascode electrically connecting member 215, the second wiring pattern 42 and the second electrically connecting member 52. With such a configuration, the cascode connection is configured.

The first gate electrode 313g and the second source electrode 322s may be connected to each other by wire bonding or the like. Further, the third gate electrode 413g and the fourth source electrode 422s may be connected to each other by wire bonding or the like.

In this manner, the electronic module 500 according to the present invention (mode 4) uses the cascode switch elements having the above-mentioned configuration and hence, a normally-on-type semiconductor element formed of a wideband gap semiconductor and capable of being driven at a high frequency can be used in the same manner as a normally-off-type semiconductor element whereby the electronic module 500 according to the present invention (mode 4) can realize functions suitable for applications (a half bridge circuit, a totem-pole-type power factor improvement circuit and the like). Accordingly, the electronic module 500 according to the present invention (mode4) becomes an electronic module that can satisfy demands with respect to operational stability and reliability although the electronic module 500 is an electronic module driven at a high frequency that uses a wideband gap semiconductor element.

In the electronic module 500 of the present invention (mode 4), the first gate electrode 313g and the first wiring pattern 41 are, as illustrated in FIG. 27, connected to each other by the first cascode electrically connecting member 315, and the third gate electrode 413g and the second wiring pattern 42 are connected to each other by the second cascode electrically connecting member 415. In the first cascode switch element 300, the first gate electrode 313g and the second source electrode 322s are connected to each other by the first cascode electrically connecting member 315, the first wiring pattern 41 and the first electrically connecting member 51. In the second cascode switch element 400. The third gate electrode 413g and the fourth source electrode 422s are connected to each other via the second cascode electrically connecting member 415, the second wiring pattern 42 and the second electrically connecting member 52. With such a configuration, the reduction of an inductance in the module and the reduction of a mounting space in the electronic module can be realized.

In the electronic module 500 according to the present invention (mode 4), as illustrated in FIG. 27, the first wiring pattern 41 has a shape based on the letter L, and the second wiring pattern 42 and the third wiring pattern 43 has a shape based on a rectangle. The third wiring pattern 43 is disposed in a state where three sides are surrounded by the first wiring pattern 41 and the second wiring pattern 42. With such a configuration, the reduction of inductance in the electronic module and the reduction of a mounting space in the electronic module can be realized.

In the electronic module 500 of the present invention (mode 4), as illustrated in FIG. 27, the first cascode switch element 300 is disposed in a region of the first wiring pattern 41 disposed adjacently to the second wiring pattern 42 and the third wiring pattern 43, and the first drain electrode 311d is disposed close to and parallel to the third wiring pattern 43. Further, the second cascode switch element 400 is disposed in a region adjacently to the first wiring pattern 41 in the second wiring pattern 42, and the third drain electrode 411d is disposed close to and parallel to the first wiring pattern 41. The capacitor 30 is disposed in a region close to the second cascode switch element 400, and is connected with the second wiring pattern 42 and the third wiring pattern 43. With such a configuration, the reduction of the inductance of the electronic module and the reduction of a mounting space in the electronic module can be realized.

In the electronic module 500 of the present invention (mode 4), as illustrated in FIG. 27, the second wiring pattern 42 has a first capacitor connecting portion 34 to which the portion 31 of the capacitor 30 is connected, the third wiring pattern 43 has a second capacitor connecting portion 35 to which the other portion 32 of the capacitor 30 is connected. Further, flat surface shapes of the second wiring pattern 42 and the third wiring pattern 43 and position where the second cascode switch element 400 is mounted and the positions where the first capacitor connecting portion 34 and the second capacitor connecting portion 35 are formed are defined such that a wiring route that starts from the second wiring pattern 42 and reaches the first drain electrode 311d via the second electrically connecting member 52, the second wiring pattern 42, the capacitor 30, the third wiring pattern 43 and the third electrically connecting member 53 becomes the shortest. With such a configuration, an inductance in the above-mentioned wiring route portion can be minimized.

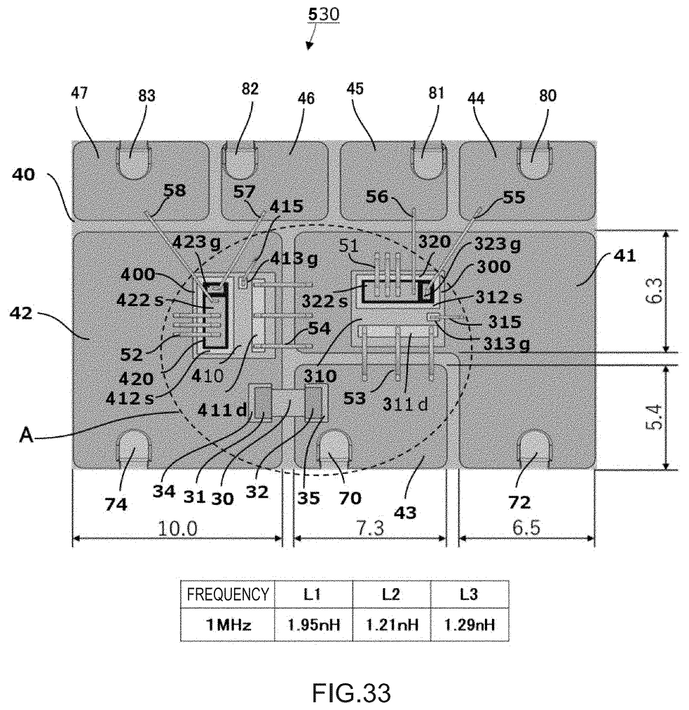

In the electronic module 500 of the present invention (mode 4), the first electrically connecting member 51, the second electrically connecting member 52, the third electrically connecting member 53, and the fourth electrically connecting member 54 can be formed of an electrically connecting member having a line-shaped or a plate-shaped (see FIG. 33 to FIG. 35 described later.)

In the electronic module 500 of the present invention (mode 4), the first switch element 310 and the third switch element 410 are formed using a wideband gap semiconductor material such as gallium nitride, silicon carbide, gallium oxide, diamond or the like. accordingly, the first switch element 310 and the third switch element 410 are formed of a semiconductor element having a higher withstand voltage than the second switch element 320 and the fourth switch element 420. Accordingly, the switching frequency can be increased to a high speed of several MHz order and hence, a turn on/off speed can be increased to a high speed by one digit or more compared to the prior art. Further, high frequency driving of the power source system can be realized. As a result, in the circuit system that is formed using the electronic module formed of the semiconductor element having functions suitable for circuit application (a half bridge circuit, a totem-pole type power factor improvement circuit or the like), the reduction of a switching loss, a surge voltage, and noises can be realized. Accordingly, performances such as operational stability and reliability of the circuit system that uses the electronic module can be enhanced.

In the electronic module 500 according to the present invention (mode 4), it is preferable that a ground terminal 74, a power source terminal 70 and an output terminal 72 be arranged at one side of the electronic module 500, control signal terminals 80, 82 be arranged on the other side of the electronic module 500, the capacitor 30 be disposed in the vicinity of the ground terminal 74 and the power source terminal 70, and the first cascode switch element 300 and the second cascode switch element 400 be disposed close to the capacitor 30 (see FIG. 33). With such a configuration, the reduction of an inductance of the electronic module and the reduction of a mounting space in the electronic module can be realized.

In the electronic module 500 of the present invention (mode 4), as indicated by the electronic module equivalent circuit 510 of the present invention (mode 4) illustrated in FIG. 32, the first cascode switch element 300 and the second cascode switch element 400 can be used in the half bridge circuit.

### Embodiment 8

FIG. 33 is a plan view illustrating an electronic module 530 according to the embodiment 8.

The electronic module 530 according to the embodiment 8 is constituted of a first cascode switch element 300 a second cascode switch element 400, a capacitor 30, a first wiring pattern 41, a second wiring pattern 42, a third wiring pattern 43 and a circuit board 40. The configuration of the first cascode switch element 300, the second cascode switch element 400, the capacitor 30, the first wiring pattern 41, the second wiring pattern 42, the third wiring pattern 43 and the circuit board 40 are basically equal to the corresponding configurations described with reference to the electronic module 500 of the present invention (mode 4) described above.

In the electronic module 530 according to the embodiment 8, as illustrated in FIG. 32 and FIG. 33, the first cascode switch element 300 and the second cascode switch element 400 form a half bridge circuit. The first gate electrode 313g and the second source electrode 322s of the first cascode switch element 300 are connected to each other, and the third gate electrode 413g and the fourth source electrode 422s of the second cascode switch element 400 are connected to each other.

A first drain electrode 311d of the first cascode switch element 300 is connected to the power source terminal 70 via the third electrically connecting member 53 and the third wiring pattern 43. The second source electrode 322s of the first cascode switch element 300 is connected to the third drain electrode 411d via the first electrically connecting member 51, the first wiring pattern 41 and the fourth electrically connecting member 54, and is connected to the output terminal 72 via the electrically connecting member 51 and the first wiring pattern 41. The first gate electrode 313g is connected to the second source electrode 322s via the first cascode electrically connecting member 315, the first wiring pattern 41 and the first electrically connecting member 51.

The fourth source electrode 422s of the second cascode switch element 400 is connected to the ground terminal 74 via the second electrically connecting member 52 and the second wiring pattern 42. The third gate electrode 413g is connected to the fourth source electrode 442s via the second cascode electrically connecting member 215, the second wiring pattern 42 and the second electrically connecting member 52. The capacitor 30 is connected to the power source terminal 70 and the ground terminal 74 via the third wiring pattern 43 and the second wiring pattern 42.

The electronic module 500 has the circuit configuration where the capacitor 30 is connected in parallel to the first cascode switch element 300 and the second cascode switch element 400 that are connected in series. As the circuit board 40, for example, a DCB circuit board formed by directly joining a copper circuit board on a ceramic board, for example.

In the electronic module 530 according to the embodiment 8, with respect to the first electrically connecting member 51, the electrically connecting member 52, the third electrically connecting member 53 and the fourth electrically connecting member 54, as illustrated in FIG. 33, each electrically connecting member uses three wires respectively as illustrated in FIG. 33. However, the number of the wires that constitute each electrically connecting member is not limited to three, and each electrically connecting member may be constituted of two or less wires, or may be constituted of four or more (for example, six) wires.

With respect to the electronic module 530 of the embodiment 8, the power source terminal 70, the output terminal 72 and the ground terminal 74 are disposed on one side of the electronic module 530 and a first control-use signal terminal 80, a first detection-use signal terminal 81, a second control-use signal terminal 82, and a second detection-use signal terminal 83 are disposed on the other side of the electronic module 530.

The first control-use signal terminal 80 is connected to the fourth wiring pattern 44 formed on the circuit board 40, and the first detection-use signal terminal 81 is connected to the fifth wiring pattern 45 formed on the surface of the circuit board 40. The second control-use signal terminal 82 is connected to the sixth wiring pattern 46 formed on the circuit board 40, and the second detection-use signal terminal 83 is connected to the seventh wiring pattern 47 formed on the surface of the circuit board 40.

The second gate electrode 323g of the first cascode switch element 300 is connected to the fourth wiring pattern 44 by the fifth electrically connecting member 55. The second source electrode 322s of the first cascode switch element 300 is connected to the fifth wiring pattern 45 by the sixth electrically connecting member 56. The fourth gate electrode 423g of the second cascode switch element 400 is connected to the sixth wiring pattern 46 by the seventh electrically connecting member 57. The fourth source electrode 422s of the second cascode switch element 400 is connected to the seventh wiring pattern 47 via the eighth electrically connecting member 58.

In the electronic module 530 according to the embodiment 8, as illustrated in FIG. 32, a parasitic inductance L1 exists at a portion where the second source electrode 322s of the first cascode switch element 300 and the third drain electrode 411d of the second cascode switch element 400 are connected to each other; a parasitic inductance L2 exists at a portion where the drain electrode 111d of the first cascode switch element 300 and the capacitor 30 are connected to each other; a parasitic inductance L3 exists at a portion where the fourth source electrode 422s of the second cascode switch element 400 and the capacitor 30 are connected to each other.

The ground terminal 74, the power source terminal 70 and the output terminal 72 are arranged on one side of the electronic module 530, and the control-use signal terminals are arranged on the other side of the electronic module 530. The capacitor 30 is disposed in the vicinity of the ground terminal 74 and the power source terminal 70. The first cascode switch element 300 and the second cascode switch element 400 are disposed close to the capacitor 30. With such a configuration, noises can be effectively removed at an inlet of the high voltage source and, at the same time, the electrically connecting members in a region that becomes a high voltage can be shortened and hence, the reduction of a parasitic inductance can be realized.

In the electronic module 5 according to the embodiment 8, the parasitic inductances L1, L2, L3 at the respective portions indicated in the equivalent circuit illustrated in FIG. 32 depend on the electrically connecting members and the structures of the wiring patterns illustrated in FIG. 33, and are obtained by simulation.

As illustrated in FIG. 33, with respect to the size of the first wiring pattern 41, the first wiring pattern 41 has a shape based on a letter L. A width of a mounting region for the first cascode switch element 300 is 6.3 mm, a width of the output terminal connecting region is 6.5 mm. The second wiring pattern 42 has a rectangle where a width of a mounting region for the second cascode switch 200 is approximately 12 mm, and a width of the ground terminal connecting region is 10.0 mm. With respect to the size of the third wiring pattern 43, the third wiring pattern 43 has a rectangle having a lateral length of 7.3 mm and a longitudinal length of 5.4 mm. Further, wire diameters ϕ are respectively 200 μm.

When a simulation is performed by taking into account these structures of the electrical connecting members it was found that L1 was 1.95 nH, L2 was 1.21 nH, and L3 was 1.29 nH. It is understood that these values are low by one digit or more compared to the corresponding inductances in the prior art (patent literatures 3, 4 and the like) described above.

### Embodiment 9

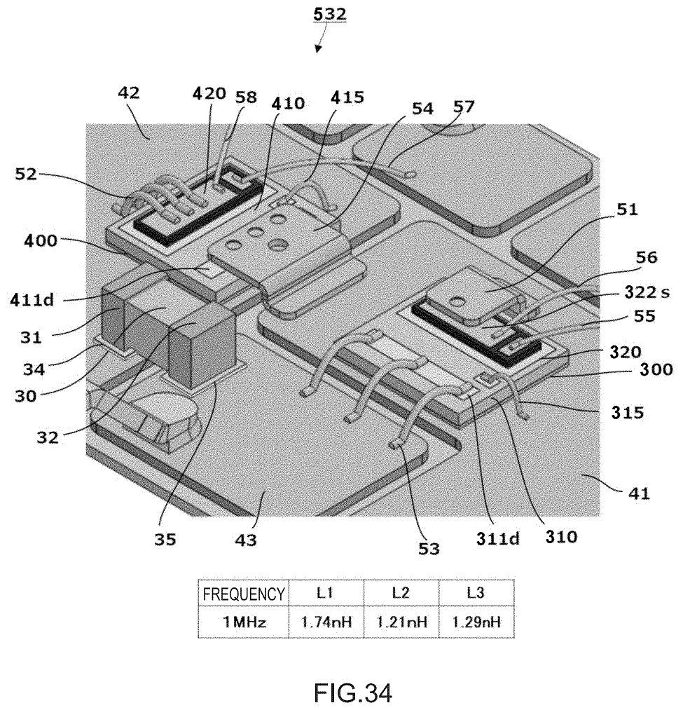

FIG. 34 is a perspective view of a main part of an electronic module 532 according to an embodiment 9 in an enlarged manner. FIG. 34 illustrates a region that corresponds to a region surrounded by a broken line in FIG. 33 in an enlarged manner. The electronic module 532 according to the embodiment 9 is, as illustrated in FIG. 34, unlike the electronic module 530 according to the embodiment 8, a first electrically connecting member 51 and a fourth electrically connecting member 54 are formed of an electrically connecting member having a plate shape. Other configurations of the electronic module 532 are equal to the corresponding configurations of the electronic module 530 according the eighth embodiment. The first electrically connecting member 51 having a plate shape has an area that covers a second source electrode 322s of the first cascode switch element 300, and connects the second source electrode 322s and a first wiring pattern 41. The fourth electrically connecting member 54 having a plate shape has an area that covers a third drain electrode 411d of a second cascode switch element 400, and connects the third drain electrodes 411d and the first wiring pattern 41.

In the electronic module 532 according to the embodiment 9, parasitic inductances L1, L2, L3 of the respective portions indicated in an equivalent circuit illustrated in FIG. 32 depend on shapes of the electrically connecting members and the structures of the wiring patterns illustrated in FIG. 34, and are obtained by simulation. As a result of simulation performed by taking into account these factors, L1 was 1.74 nH, L2 was 1.21 nH, and L3 was 1.29 nH. With the use of the first electrically connecting member 51 and the fourth electrically connecting member 54 having a plate shape, the value of L1 became lower than the corresponding value of L1 in the case of the electronic module 530 of the embodiment 8 by 0.21 nH.

### Embodiment 10

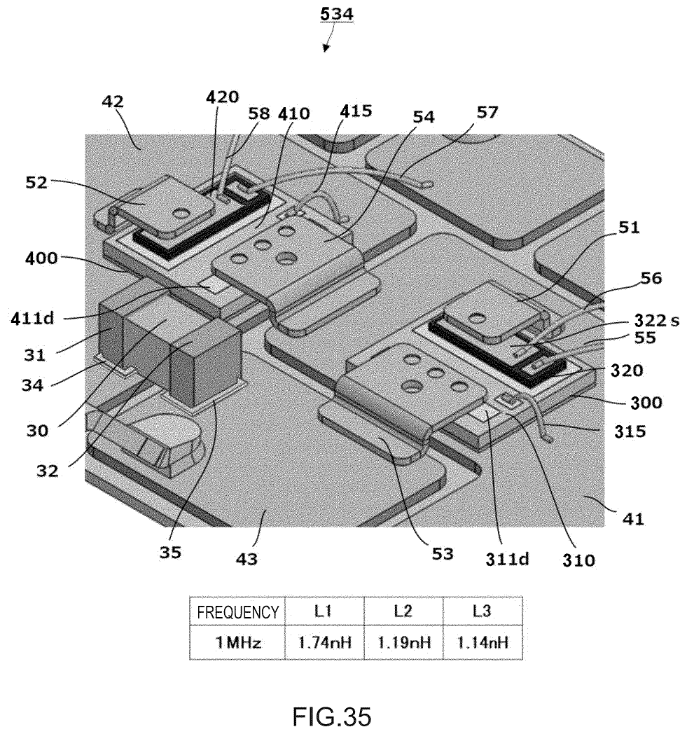

FIG. 35 is a perspective view of an essential part of an electronic module 534 according to an embodiment 10 in an enlarged manner. FIG. 10 illustrates a region corresponding to a region surrounded by a broken line in FIG. 33 in an enlarged manner. As illustrated in FIG. 35, the electronic module 534 according to the embodiment 10, unlike the electronic module 530 according to the embodiment 8, all electrically connecting members are formed of an electrically connecting member having a plate-shape. Other configurations are equal to the corresponding configurations of the electronic module 530 according to the embodiment 8.

A first electrically connecting member 51 having a plate-shape has an area that covers a second source electrode 322s of a first cascode switch element 300, and connects a second source electrode 322s and a first wiring pattern 41 to each other. A second electrically connecting member 52 having a plate-shape has an area that covers a fourth source electrode 422s of a second cascode switch element 400, and the second electrically connecting member 52 connects a fourth source electrode 422s and a second wiring pattern 42. A third electrically connecting member 53 having a plate-shape has an area that covers a first drain electrode 311d of the first cascode switch element 300, and connects the first drain electrode 311d and the third wiring pattern 43 to each other. The fourth electrically connecting member 54 having a plate-shape has an area that covers a third drain electrode 411d of the second cascode switch element 400, and connects the third drain electrode 411d and the first wiring pattern 41.

In the electronic module 534 according to the embodiment 10, parasitic inductances L1, L2. L3 of the respective portions indicated in the equivalent circuit illustrated in FIG. 32, depending on the electrically connecting members and the shapes of the wiring patterns illustrated in FIG. 35, and are obtained by simulation. As a result of simulation performed by taking into account these factors, L1 was 1.74 nH, L2 was 1.19 nH, and L3 was 1.14 nH. With the use of the first electrically connecting member 51 having a plate-shape, the second electrically connecting member 52 having a plate-shape, the third electrically connecting member 53 having a plate-shape and the fourth electrically connecting member 54 having a plate-shape, the value of L1 became lower than the corresponding value of L1 in the case of the electronic module 530 according to the embodiment 1 by 0.21 nH, the value of L2 became lower than the corresponding value of L2 in the case of the electronic module 530 according to the embodiment 1 by 0.02 nH, and the value of L3 became lower than the corresponding value of L3 in the case of the electronic module 530 according to the embodiment 1 by 0.15 nH.

### <Double-Pulse Test>

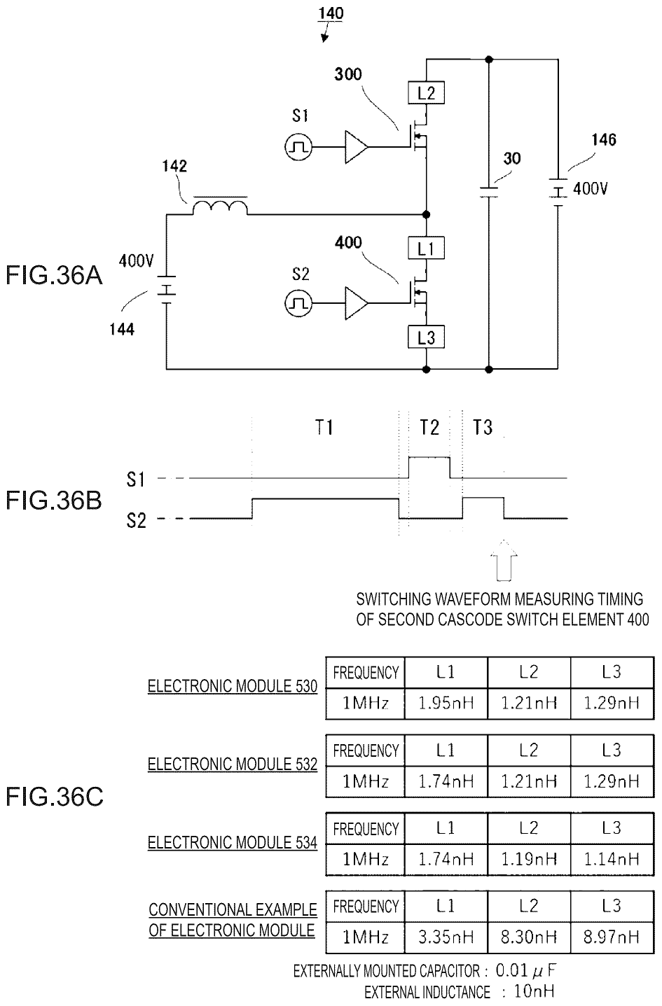

FIG. 36A to FIG. 36C are views provided for describing a double-pulse test. FIG. 36A is a view illustrating a simulation block 140 of a double-pulse test circuit in a case where a first cascode switch element 300 and a second cascode switch element 400 are used. A drain-source voltage VDS and a drain current ID after turning off switches are simulated in switching waveforms in the double pulse test.

The circuit configuration adopts the configuration of a half bridge boosting circuit. As illustrated in FIG. 36A, the first cascode switch element 300 and the second cascode switch element 400 are connected in series, and a capacitor 30 is connected parallel to a series circuit constituted of the first cascode switch element 300 and the second cascode switch element 400. A choke coil 142 is connected to an input power source 144 of 400 V, and the other end of the choke coil 142 is connected to an intermediate point between the first cascode switch element 300 and the second cascode switch element 400. A boosted voltage is clamped by an output power source 146 of 400 V.

A fourth source electrode 422s of the second cascode switch element 400 is connected to an input power source 144 and a ground wire that connects the capacitor 30 and the output power source 146. A signal is applied between the second gate electrode 323g and the second source electrode 322s of the first cascode switch element 300 and between the fourth gate electrode 423g and the fourth source electrode 422s of the second cascode switch element 400 so that a switching control is performed. Hereinafter, “between the second gate electrode 323g and the second source electrode 322s of the first cascode switch element 300”, and “the fourth gate electrode 423g and the fourth source electrode 422s of the second cascode switch element 400” are each referred to as “between gate-source”.

In the double pulse test, as illustrated in FIG. 36B, a first control-use signal S1 and a second control-use signal S2 are applied to the respective “between gate-source” of the first cascode switch element 300 and the second cascode switch element 400. First, the second cascode switch element 400 is turned on in response to the second control-use signal S2, and is turned off after a lapse of time T1. After a predetermined dead time elapses from this timing, the first cascode switch element 300 is turned on in response to the first control-use signal S1, and is turned off after a lapse of time T2.

After a lapse of a predetermined dead time from this timing, the second cascode switch element 400 is tuned on in response to the second control-use signal S2 and is turned-off after a lapse of time T3. This point of time becomes switching waveform measuring timing at which waveforms of a drain-source voltage VDS and a drain current ID of the second cascode switch element 400 are measured. Hereinafter, “between the first drain electrode 311d and the second source electrode 322s of the first cascode switch element 300”, and “between the third drain electrode 411d and the fourth source electrode 422s of the second cascode switch element 400” are referred to as “between drain-source”.

FIG. 36C indicates values of parasitic inductances L1, L2, L3 in the electronic module 530, the electronic module 532, the electronic module 534 and a conventional-type electronic module described later. The waveforms of the drain-source voltage VDS and the drain current ID are obtained as the values L1, L2, L3.

The parasitic inductances L1, L2, L3 of the electronic module 530 according to the embodiment 8 are obtained by simulation. That is, L1 was 1.95 nH, L2 of 1.21 nH and L3 of 1.29 nH are obtained. The parasitic inductances L1, L2, L3 of the electronic module 532 according to the embodiment 9 were obtained by simulation. That is, L1 was 1.74 nH, L2 was 1.21 nH and L3 was 1.29 nH. The parasitic inductances L1, L2, L3 of the electronic module 534 according to the embodiment 10 are obtained by simulation. That is, L1 of 1.74 nH, L2 of 1.19 nH and L3 of 1.14 nH are obtained. Further, the parasitic inductances of the conventional-type electronic module described above are as follows, that is, L1 was 3.35 nH, L2 was 8.30 nH, and L3 was 8.97 nH.

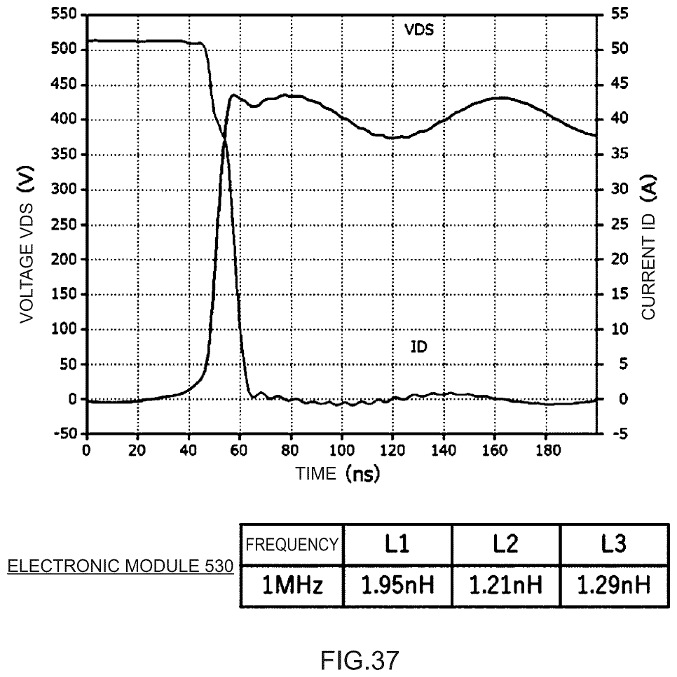

FIG. 37 is a view where, in the electronic module 530 according to the embodiment 8, the parasitic inductances L1, L2, L3 in the equivalent circuit 530 illustrated in FIG. 32 are obtained by simulation, the drain-source voltage VDS and the drain current ID of the second cascode switch element 400 are simulated by the simulation block 140 of the double pulse test circuit illustrated in FIG. 36A, and the waveforms obtained by measurement at switching waveform measuring timing are indicated.

The capacitor 30 mounted in the electronic module 530 is set to 0.01 μF and the inductance of the choke coil 142 connected to the outside of the electronic module 530 is set to 50 μH.

As illustrated in FIG. 37, in the double pulse test that uses the electronic module 530 according to the embodiment 8, the maximum drain-source voltage is approximately 450V, and in the first cascode switch element 300 and the second cascode switch element 400, the drain-source absolute maximum rated voltage is 650 V. Accordingly, it is understood that a sufficient margin is secured in the first cascode switch 300 and the second cascode switch 400 with respect to a specification rated voltage. Further, it is understood that, also with respect to a surge voltage, for example, there is no occurrence of an excessively large surge voltage after a lapse of 180 ns from switching waveform measuring timing and hence, the electronic module 530 is operationally stable. This is also apparent from the waveform of the drain current ID. The substantially the same result was obtained with respect to the electronic module 532 according to the embodiment 9 and the electronic module 534 according to the embodiment 10.

The comparison example is the same as the comparison example that is described in the present invention (mode 1) and hence, the description of the comparison example is omitted here.

As has been described heretofore, according to the electronic module of the present invention (mode 4), the further reduction of the inductance in the electronic module can be realized. As a result, the electronic module of the present invention (mode 4) is an electronic module that can satisfy demands with respect to operational stability and reliability while being an electronic module of high frequency driving using a wideband gap semiconductor element.

Heretofore, the embodiment of the present invention (mode 4) has been described. However, the present invention (mode 4) is not limited to the above-mentioned embodiment, and the present invention (mode 4) is also applicable to an electronic module on which a plurality of semiconductor chips are mounted, and the various modifications and applications are conceivable without departing from the gist of the present invention.
(1) In the above-mentioned respective embodiments, the present invention (mode 4) has been described using the electronic module that includes a capacitor. However, the present invention (mode 4) is not limited to such an electronic module. For example, it is possible to use an electronic module that does not include a capacitor (for example, an electronic module where a capacitor is eliminated from the electronic module 530 according to the embodiment 1, and a mold resin is partially removed at a capacitor mounting portion). In this case, it is possible to constitute an electronic module substantially equal to the electronic modules according to the respective embodiments by mounting an externally mounting capacitor at a capacitor mounting position.
(2) In the above-mentioned respective embodiments, the present invention (mode 4) has been described using the half bridge circuit. However, the present invention (mode 4) is not limited to such a configuration. The present invention is applicable to a circuit other than a half bridge circuit.

1. An electronic module comprising:
a first semiconductor element having a plurality of first electrodes;
a second semiconductor element having a plurality of second electrodes;
a capacitor;
a circuit board having a first wiring pattern on which the first semiconductor element is mounted, a second wiring pattern on which the second semiconductor element is mounted and a third wiring pattern; and
a plurality of electrically connecting members, wherein
the first wiring pattern is configured such that one portion of the first electrode and an other portion of the second electrode are connected to the first wiring pattern, the second wiring pattern is configured such that one portion of the second electrode and one portion of the capacitor are connected to the second wiring pattern, and the third wiring pattern is configured such that an other portion of the first electrode and an other portion of the capacitor are connected to the third wiring pattern, and
a surface of the first electrode and a surface of the second electrode are disposed at positions that differ in height from each other, and the one portion of the first electrode, the other portion of the second electrode, and the first wiring pattern are connected to each other by one electrically connecting member out of the plurality of electrically connecting members.

2. The electronic module according to claim 1, wherein
a position adjusting member that adjusts height positions of the surfaces of the second electrodes or the surfaces of the first electrodes is disposed between the second wiring pattern and the second semiconductor element or between the first wiring pattern and the first semiconductor element.

3. The electronic module according to claim 1, wherein
a height of the first semiconductor element and a height of the second conductor element differ from each other.

4. The electronic module according to claim 1, wherein
the surface of the first electrode is at a position lower than the surface of the second electrode, and
the first wiring pattern is at a position lower than the surface of the first electrode.

5. The electronic module according to claim 1, wherein
a first semiconductor element mounting region on the first wiring pattern, a second semiconductor element mounting region on the second wiring pattern, and a portion of the third wiring pattern are formed parallel to each other.

6. The electronic module according to claim 1, wherein
the plurality of electrically connecting members are used for connection among the first semiconductor element, the second semiconductor element, the first wiring pattern, the second wiring pattern, and the third wiring pattern, and
the first semiconductor element, the second semiconductor element, the first wiring pattern, the second wiring pattern, and the third wiring pattern are formed such that connection distances of the plurality of electrically connecting members respectively become the shortest.

7. The electronic module according to claim 1, wherein
the second wiring pattern has a first capacitor connecting portion to which the one portion of the capacitor is connected, and the third wiring pattern has a second capacitor connecting portion to which the other portion of the capacitor is connected, and
planar shapes of the second wiring pattern and the third wiring pattern, and a position at which the first capacitor connecting portion and the second capacitor connecting portion are defined such that a wiring route that starts from the one portion of the second electrode and reaches the other portion of the first electrode via the second wiring pattern, the capacitor and the third wiring pattern becomes the shortest.

8. The electronic module according to claim 1, further comprising: a power source terminal, an output terminal and a ground terminal disposed on one side thereof; and a control signal-use terminal disposed on an other side thereof, wherein
the capacitor is disposed on the one side.

9. (canceled)

10. The electronic module according to claim 1, wherein
the plurality of electrically connecting members are each formed of an electrically connecting member having a line shape, and
assuming a higher surface out of the surface of the first electrode and the surface of the second electrode as a first surface and a lower surface out of the surface of the first electrode and the surface of the second electrode as a second surface, a height position of a peak point of the electrically connecting member in a first loop portion that connects an electrode that corresponds to the first surface and an electrode that corresponds to the second surface to each other is higher than a height position of a peak point of the electrically connecting member in a second loop portion that connects the electrode that corresponds to the second surface and the first wiring pattern.

11. The electronic module according to claim 10 wherein,
a flat surface position of the peak point of the electrically connecting member at the first loop portion is disposed at a position more offset toward an electrically-connecting-member mounting position side on the first surface than an intermediate position between an electrically-connecting-member mounting position on the first surface and an electrically-connecting-member mounting position on the second surface, and a flat surface position of the peak point of the electrically connecting member at the second loop portion is disposed at a position more offset toward an electrically-connecting-member mounting position side on the second surface than an intermediate position between the electrically-connecting-member mounting position on the second surface and the electrically-connecting-member mounting position on the first wiring pattern.

12. The electronic module according to claim 1, wherein
a parasitic inductance at a portion where the first semiconductor element and the second semiconductor element are connected to each other is smaller than a parasitic inductance at a portion where the first semiconductor element and the capacitor are connected to each other, and a parasitic inductance at a portion where the second semiconductor element and the capacitor are connected to each other.

13.-16. (canceled)

17. An electronic module comprising:
a first semiconductor element having a plurality of first electrodes;
a second semiconductor element having a plurality of second electrodes;
a capacitor;
a circuit board having a first wiring pattern on which the first semiconductor element is mounted, a second wiring pattern on which a second semiconductor element is mounted and a third wiring pattern; and
a plurality of electrically connecting members, wherein
the first wiring pattern is configured such that one portion of the first electrode and an other portion of the second electrode are connected to the first wiring pattern, the second wiring pattern is configured such that one portion of the second electrode and one portion of the capacitor are connected to the second wiring pattern, and the third wiring pattern is configured such that an other portion of the first electrode and an other portion of the capacitor are connected to the third wiring pattern,
the one portion of the first electrode, the other portion of the second electrode and the first wiring pattern are connected to each other by one electrically connecting member out of the plurality of electrically connecting members, and
the first semiconductor element and the second semiconductor element are disposed such that an extending direction of the one portion of the first electrode and an extending direction of the other portion of the second electrode are directed in the same direction.

18. The electronic module according to claim 17, wherein
a first semiconductor element mounting region of the first wiring pattern, a second semiconductor element mounting region of the second wiring pattern, and a portion of the third wiring pattern are disposed parallel to each other.

19. The electronic module according to claim 17, wherein
the second wiring pattern has a first capacitor connecting portion to which the one portion of the capacitor is connected, and the third wiring pattern has a second capacitor connecting portion to which the other portion of the capacitor is connected, and
planar shapes of the second wiring pattern and the third wiring pattern, a forming position of the first capacitor connecting portion and a forming position of the second capacitor connecting portion are defined such that a wiring route that starts from the one portion of the second electrode and reaches the other portion of the first electrode via the second wiring pattern, the capacitor and the third wiring pattern becomes the shortest.

20. The electronic module according to claim 17, wherein
the electronic module includes a power source terminal, an output terminal and a ground terminal one side thereof and a control signal-use terminal on an other side thereof, and the capacitor is disposed on the one side.

21.-22. (canceled)

23. The electronic module according to claim 17, wherein
a parasitic inductance at a portion where the first semiconductor element and the second semiconductor element are connected to each other is smaller than a parasitic inductance at a portion where the first semiconductor element and the capacitor are connected to each other, and a parasitic inductance at a portion where the second semiconductor element and the capacitor are connected to each other.

24.-26. (canceled)

27. An electronic module comprising:
a first semiconductor element having a plurality of first electrodes;
a second semiconductor element having a plurality of second electrodes;
a capacitor;
a circuit board having a first wiring pattern on which the first semiconductor element is mounted, a second wiring pattern on which a second semiconductor element is mounted and a third wiring pattern;
a first electrically connecting member;
a second electrically connecting member;
a third electrically connecting member; and
a fourth electrically connecting member, wherein
the first wiring pattern is configured such that one portion of the first electrode is connected to the first wiring pattern via the first electrically connecting member, and an other portion of the second electrode is connected to the first wiring pattern via the fourth electrically connecting member,
the second wiring pattern is configured such that one portion of the second electrode is connected to the second wiring pattern via the second electrically connecting member, and one portion of the capacitor is connected to the second wiring pattern,
the third wiring pattern is configured such that an other portion of the first electrode is connected to the third wiring pattern via the third electrically connecting member, and the other portion of the capacitor is connected to the third wiring pattern, and
the first semiconductor element and the second semiconductor element are disposed in different directions from each other.

28. The electronic module according to claim 27, wherein,
the first wiring pattern has a shape based on a letter L,
the second wiring pattern and a third wiring pattern have a shape based on a rectangle, and
the third wiring pattern is formed so as to surround from three sides together with the first wiring pattern and the second wiring pattern.

29. The electronic module according to claim 27, wherein
the first semiconductor element is disposed in a region of the first wiring pattern adjacently to the second wiring pattern and the third wiring pattern, and the other portion of the first electrode is disposed close to and parallel to the third wiring pattern,
the second semiconductor element is disposed in a region of the second wiring pattern adjacently to the first wiring pattern, and the other portion of the second electrode is disposed close to and parallel to the first wiring pattern, and
the capacitor is disposed in a region close to the second semiconductor element in a state where the capacitor is connected to the second wiring pattern and the third wiring pattern.

30. The electronic module according to claim 27, wherein
the second wiring pattern has a capacitor connecting portion to which the one portion of the capacitor is connected, and the third wiring pattern has a second capacitor connecting portion to which the other portion of the capacitor is connected, and
planar shapes of the second wiring pattern and the third wiring pattern, a mounting position of the second semiconductor element, and forming positions of the first capacitor connecting portion and the second capacitor connecting portion are defined such that a wiring route that starts from the one portion of the second electrode and reaches the other portion of the first electrode via the second electrically connecting member, the second wiring pattern, the capacitor, the third wiring pattern and the third electrically connecting member becomes the shortest.

31.-47. (canceled)
